(19) United States
(12) Patent Application Publication
(10) Pub. No.: US 2024/0377849 A1
(43) Pub. Date: Nov. 14, 2024

(54) DRIVE SENSE CIRCUIT

(71) Applicant: SigmaSense, LLC., Austin, TX (US)

(72) Inventors: Richard Stuart Seger, JR., Belton, TX (US); Michael Shawn Gray, Elgin, TX (US); Patrick Troy Gray, Cedar Park, TX (US); Daniel Keith Van Ostrand, Leander, TX (US)

(73) Assignee: SigmaSense, LLC., Austin, TX (US)

(21) Appl. No.: 18/783,633

(22) Filed: Jul. 25, 2024

Related U.S. Application Data
(63) Continuation-in-part of application No. 18/049,238, filed on Oct. 24, 2022.
Application No. 18/049,238 is a continuation of application No. 17/301,346, filed on Mar. 31, 2021, now Pat. No. 11,513,543.
Application No. 17/301,346 is a continuation-in-part of application No. 16/113,379, filed on Aug. 27, 2018, now Pat. No. 11,099,032.
(60) Provisional application No. 63/528,939, filed on Jul. 26, 2023.

(51) Int. Cl. G05F 1/46; G01D 5/20; G01D 5/24; G06F 3/041; H03K 5/24

(52) U.S. Cl. CPC G05F 1/46; G01D 5/20; G01D 5/24; G06F 3/0416; H03K 5/24

(57) ABSTRACT

A drive sense circuit (DSC) includes an analog front end (AFE) circuit, a filter circuit, and a data processing circuit. The AFE circuit includes a signal source circuit and a comparison circuit. The signal source circuit, when enabled and coupled to a sensor, provides an analog drive signal to the sensor, which affects an electrical property of the analog drive signal. The comparison circuit compares the analog drive signal as effected by the sensor to a reference signal and produces an analog sensed signal that represents the effected electrical property of the analog drive signal. The filter filters the analog sensed signal to produce a filtered sensed signal. The data processing circuit operably generates a digital value representative of sensed characteristic of the sensor based on the filtered sensed signal.

### CROSS-REFERENCE TO RELATED APPLICATIONS

The present U.S. Utility Patent Application claims priority pursuant to 35 U.S.C. § 120 as a continuation-in-part of U.S. Utility application Ser. No. 18/049,238, entitled “SINGLE LINE HIGH IMPEDANCE DRIVE AND LOW IMPEDANCE SENSE CIRCUIT”, filed Oct. 24, 2022, which claims priority pursuant to 35 U.S.C. § 120 as a continuation of U.S. Utility application Ser. No. 17/301,346, entitled “IMPEDANCE DETECT DRIVE SENSE CIRCUIT”, filed Mar. 31, 2021, now U.S. Pat. No. 11,513,543 issued on Nov. 29, 2022, which claims priority pursuant to 35 U.S.C. § 120 as a continuation-in-part of U.S. Utility application Ser. No. 16/113,379, entitled “DRIVE SENSE CIRCUIT WITH DRIVE-SENSE LINE”, filed Aug. 27, 2018, now U.S. Pat. No. 11,099,032 issued on Aug. 24, 2021, each of which are hereby incorporated herein by reference in their entirety and made part of the present U.S. Utility Patent Application for all purposes.

The present U.S. Utility Patent Application also claims priority pursuant to 35 U.S.C. § 119(e) to U.S. Provisional Application No. 63/528,939, entitled “DRIVE SENSE CIRCUIT”, filed Jul. 26, 2023, which is hereby incorporated herein by reference in its entirety and made part of the present U.S. Utility Patent Application for all purposes.

### STATEMENT REGARDING FEDERALLY SPONSORED RESEARCH OR DEVELOPMENT

Not Applicable.

### INCORPORATION-BY-REFERENCE OF MATERIAL SUBMITTED ON A COMPACT DISC

Not Applicable.

### BACKGROUND OF THE INVENTION

### Technical Field of the Invention

The disclosed subject matter relates to generally to data communication systems and more particularly to sensed data collection and/or communication.

### Description of Related Art

Sensors are used in a wide variety of applications ranging from in-home automation to industrial systems, to healthcare, to transportation, and so on. For example, sensors are placed in bodies, automobiles, airplanes, boats, ships, trucks, motorcycles, cell phones, televisions, touch-screens, industrial plants, appliances, motors, checkout counters, etc. for the variety of applications.

In general, a sensor converts a physical quantity into an electrical or optical signal. For example, a sensor converts a physical phenomenon, such as a biological condition, a chemical condition, an electric condition, an electromagnetic condition, a temperature, a magnetic condition, mechanical motion (position, velocity, acceleration, force, pressure), an optical condition, and/or a radioactivity condition, into an electrical signal.

A sensor includes a transducer, which functions to convert one form of energy (e.g., force) into another form of energy (e.g., electrical signal). There are a variety of transducers to support the various applications of sensors. For example, a transducer is capacitor, a piezoelectric transducer, a piezoresistive transducer, a thermal transducer, a thermal-couple, a photoconductive transducer such as a photoresistor, a photodiode, and/or phototransistor.

A sensor circuit is coupled to a sensor to provide the sensor with power and to receive the signal representing the physical phenomenon from the sensor. The sensor circuit includes at least three electrical connections to the sensor: one for a power supply; another for a common voltage reference (e.g., ground); and a third for receiving the signal representing the physical phenomenon. The signal representing the physical phenomenon will vary from the power supply voltage to ground as the physical phenomenon changes from one extreme to another (for the range of sensing the physical phenomenon).

The sensor circuits provide the received sensor signals to one or more computing devices for processing. A computing device is known to communicate data, process data, and/or store data. The computing device may be a cellular phone, a laptop, a tablet, a personal computer (PC), a workstation, a video game device, a server, and/or a data center that supports millions of web searches, stock trades, or on-line purchases every hour.

The computing device processes the sensor signals for a variety of applications. For example, the computing device processes sensor signals to determine temperatures of a variety of items in a refrigerated truck during transit. As another example, the computing device processes the sensor signals to determine a touch on a touch screen. As yet another example, the computing device processes the sensor signals to determine various data points in a production line of a product.

### BRIEF DESCRIPTION OF THE SEVERAL VIEWS OF THE DRAWING(S)

FIG. 1A is a schematic block diagram of an embodiment of a computing network;

FIGS. 1B through 1F are schematic block diagram of embodiments of computing entities that are part of an improved computer for technology;

FIGS. 1G through 1M are schematic block diagram of embodiments of computing devices that form at least a portion of a computing entity;

FIG. 1N is a schematic block diagram of an embodiment of a database;

FIG. 1O is a schematic block diagram of an embodiment of a touch sense device;

FIG. 2 is a schematic block diagram of an embodiment of a drive sense circuit;

FIG. 3 is a schematic block diagram of an embodiment of an unregulated analog front end of a drive sense circuit;

FIG. 4 is a schematic block diagram of another embodiment of an unregulated analog front end of a drive sense circuit;

FIG. 5 is a schematic block diagram of another embodiment of an unregulated analog front end of a drive sense circuit;

FIG. 6 is a schematic block diagram of another embodiment of an unregulated analog front end of a drive sense circuit;

FIG. 7 is a schematic block diagram of another embodiment of an unregulated analog front end of a drive sense circuit;

FIG. 8 is a schematic block diagram of another embodiment of an unregulated analog front end of a drive sense circuit;

FIG. 9 is a schematic block diagram of another embodiment of an unregulated analog front end of a drive sense circuit;

FIG. 10 is a schematic block diagram of another embodiment of an unregulated analog front end of a drive sense circuit;

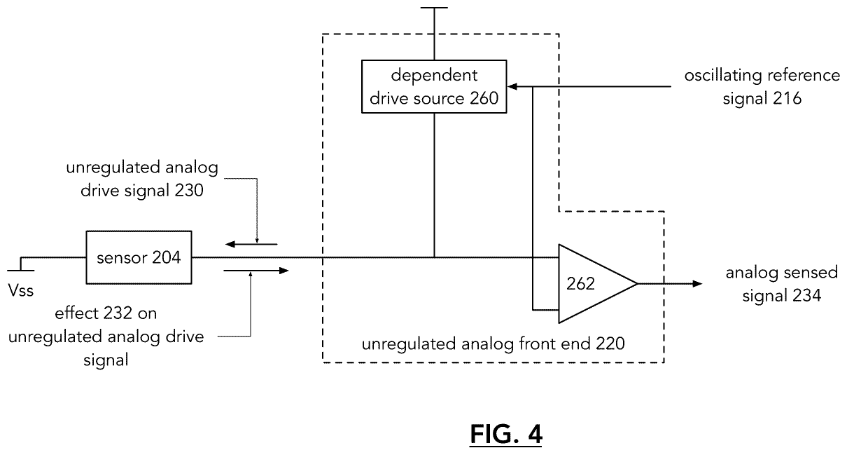

FIG. 11 is a schematic block diagram of another embodiment of an unregulated analog front end of a drive sense circuit;

FIG. 12 is a schematic block diagram of another embodiment of an unregulated analog front end of a drive sense circuit;

FIG. 13 is a schematic block diagram of an embodiment of a dependent oscillating voltage source of an unregulated analog front end of a drive sense circuit;

FIG. 14 is a schematic block diagram of another embodiment of an unregulated analog front end of a drive sense circuit;

FIG. 15 is a schematic block diagram of another embodiment of an unregulated analog front end of a drive sense circuit;

FIG. 16 is a schematic block diagram of another embodiment of an unregulated analog front end of a drive sense circuit;

FIG. 17 is a schematic block diagram of another embodiment of an unregulated analog front end of a drive sense circuit;

FIG. 18 is a schematic block diagram of another embodiment of an unregulated analog front end of a drive sense circuit;

FIG. 19 is a schematic block diagram of another embodiment of an unregulated analog front end of a drive sense circuit;

FIG. 20 is a schematic block diagram of another embodiment of an unregulated analog front end of a drive sense circuit;

FIG. 21 is a schematic block diagram of another embodiment of an unregulated analog front end of a drive sense circuit;

FIG. 22 is a schematic block diagram of another embodiment of an unregulated analog front end of a drive sense circuit;

FIG. 23 is a schematic block diagram of another embodiment of an unregulated analog front end of a drive sense circuit;

FIG. 24 is a schematic block diagram of another embodiment of an unregulated analog front end of a drive sense circuit;

FIG. 25 is a schematic block diagram of another embodiment of an unregulated analog front end of a drive sense circuit;

FIG. 26 is a schematic block diagram of another embodiment of an unregulated analog front end of a drive sense circuit;

FIG. 27 is a schematic block diagram of another embodiment of an unregulated analog front end of a drive sense circuit;

FIG. 28 is a schematic block diagram of another embodiment of an unregulated analog front end of a drive sense circuit;

FIG. 29 is a schematic block diagram of another embodiment of an unregulated analog front end of a drive sense circuit;

FIG. 30 is a schematic block diagram of another embodiment of an unregulated analog front end of a drive sense circuit;

FIG. 31 is a schematic block diagram of another embodiment of an unregulated analog front end of a drive sense circuit;

FIG. 32 is a schematic block diagram of another embodiment of an unregulated analog front end of a drive sense circuit;

FIG. 33 is a schematic block diagram of another embodiment of an unregulated analog front end of a drive sense circuit;

FIG. 34 is a schematic block diagram of another embodiment of an unregulated analog front end of a drive sense circuit;

FIG. 35 is a schematic block diagram of another embodiment of an unregulated analog front end of a drive sense circuit;

FIG. 36 is a schematic block diagram of another embodiment of an unregulated analog front end of a drive sense circuit;

FIG. 37 is a schematic block diagram of another embodiment of an unregulated analog front end of a drive sense circuit;

FIG. 38 is a schematic block diagram of another embodiment of an unregulated analog front end of a drive sense circuit;

FIG. 39 is a schematic block diagram of another embodiment of an unregulated analog front end of a drive sense circuit;

FIG. 40 is a schematic block diagram of another embodiment of an unregulated analog front end of a drive sense circuit;

FIG. 41 is a schematic block diagram of another embodiment of an unregulated analog front end of a drive sense circuit;

FIG. 42 is a schematic block diagram of another embodiment of a drive sense circuit;

FIG. 43 is a schematic block diagram of another embodiment of a regulated analog front end of a drive sense circuit;

FIG. 44 is a schematic block diagram of another embodiment of a regulated analog front end of a drive sense circuit;

FIG. 45 is a schematic block diagram of another embodiment of a regulated analog front end of a drive sense circuit;

FIG. 46 is a schematic block diagram of another embodiment of a regulated analog front end of a drive sense circuit;

FIG. 47 is a schematic block diagram of another embodiment of a regulated analog front end of a drive sense circuit;

FIG. 48 is a schematic block diagram of another embodiment of a regulated analog front end of a drive sense circuit;

FIG. 49 is a schematic block diagram of another embodiment of a regulated analog front end of a drive sense circuit;

FIG. 50 is a schematic block diagram of another embodiment of a regulated analog front end of a drive sense circuit;

FIG. 51 is a schematic block diagram of another embodiment of a regulated analog front end of a drive sense circuit;

FIG. 52 is a schematic block diagram of another embodiment of a regulated analog front end of a drive sense circuit;

FIG. 53 is a schematic block diagram of another embodiment of a regulated analog front end of a drive sense circuit;

FIG. 54 is a functional diagram of an embodiment of a digital filter of a drive sense circuit;

FIG. 55 is a schematic block diagram of another embodiment of a digital filter of a drive sense circuit;

FIG. 56 is a schematic block diagram of another embodiment of a digital filter of a drive sense circuit;

FIG. 57 is a schematic block diagram of another embodiment of a digital filter of a drive sense circuit;

FIG. 58 is a schematic block diagram of another embodiment of a digital filter of a drive sense circuit;

FIG. 59 is a schematic block diagram of another embodiment of a digital filter of a drive sense circuit;

FIG. 60 is a schematic block diagram of another embodiment of a digital filter of a drive sense circuit;

FIG. 61 is a functional diagram of an embodiment of a data processing unit of a drive sense circuit;

FIG. 62 is another functional diagram of an embodiment of a data processing unit of a drive sense circuit;

FIG. 63 is a logic diagram of an example of a method executed by a data processing unit of a drive sense circuit;

FIG. 64 is a schematic block diagram of an embodiment of a data processing unit of a drive sense circuit;

FIG. 65 is a logic diagram of another example of a method executed by a data processing unit of a drive sense circuit;

FIG. 66 is a schematic block diagram of another embodiment of a data processing unit of a drive sense circuit;

FIG. 67 is a schematic block diagram of another embodiment of a data processing unit of a drive sense circuit;

FIG. 68 is a logic diagram of another example of a method executed by a data processing unit of a drive sense circuit;

FIG. 69 is a schematic block diagram of another embodiment of a data processing unit of a drive sense circuit;

FIG. 70 is a logic diagram of another example of a method executed by a data processing unit of a drive sense circuit;

FIG. 71 is a schematic block diagram of another embodiment of a data processing unit of a drive sense circuit;

FIG. 72 is a schematic block diagram of another embodiment of a data processing unit of a drive sense circuit;

FIG. 73 is a logic diagram of another example of a method executed by a data processing unit of a drive sense circuit;

FIG. 74 is a logic diagram of another example of a method executed by a data processing unit of a drive sense circuit;

FIG. 75 is a logic diagram of another example of a method executed by a data processing unit of a drive sense circuit;

FIG. 76 is a logic diagram of another example of a method executed by a data processing unit of a drive sense circuit;

FIG. 77 is a functional diagram of another embodiment of a data processing unit of a drive sense circuit;

FIG. 78 is a functional diagram of another embodiment of a data processing unit of a drive sense circuit;

FIG. 79 is a functional diagram of another embodiment of a data processing unit of a drive sense circuit;

FIG. 80 is a functional diagram of another embodiment of a data processing unit of a drive sense circuit;

FIG. 81 is a functional diagram of another embodiment of a data processing unit of a drive sense circuit; and

FIG. 82 is a functional diagram of another embodiment of a data processing unit of a drive sense circuit.

### DETAILED DESCRIPTION OF THE INVENTION

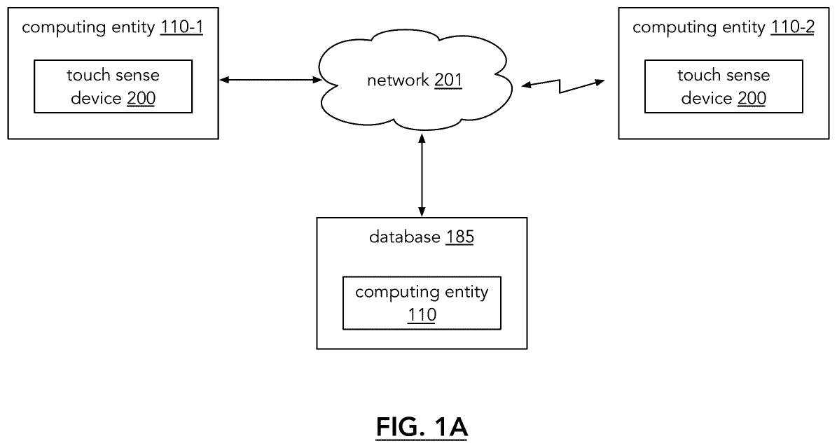

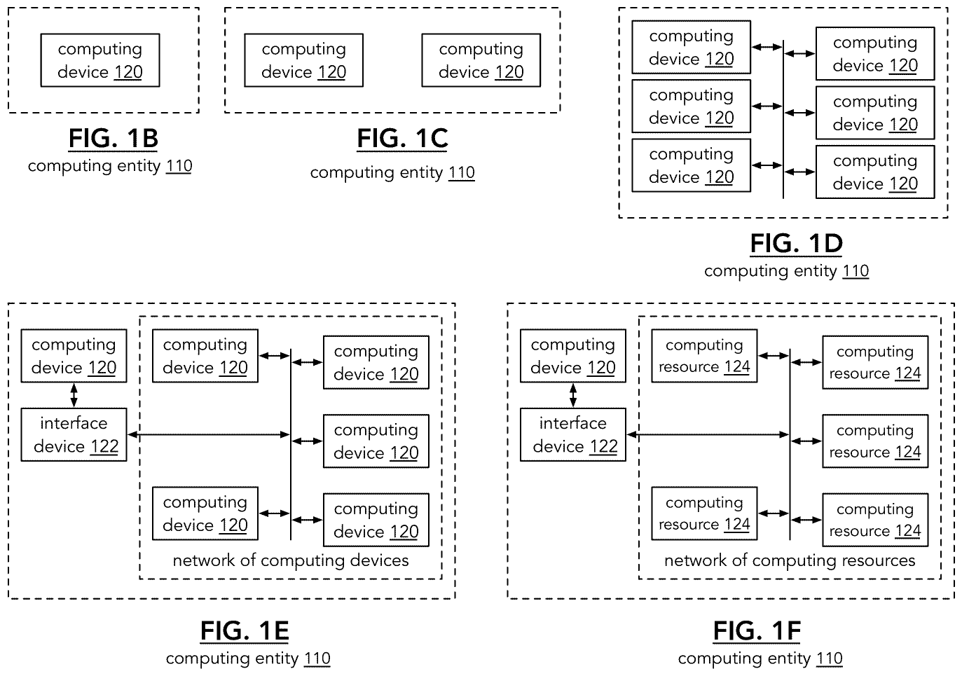

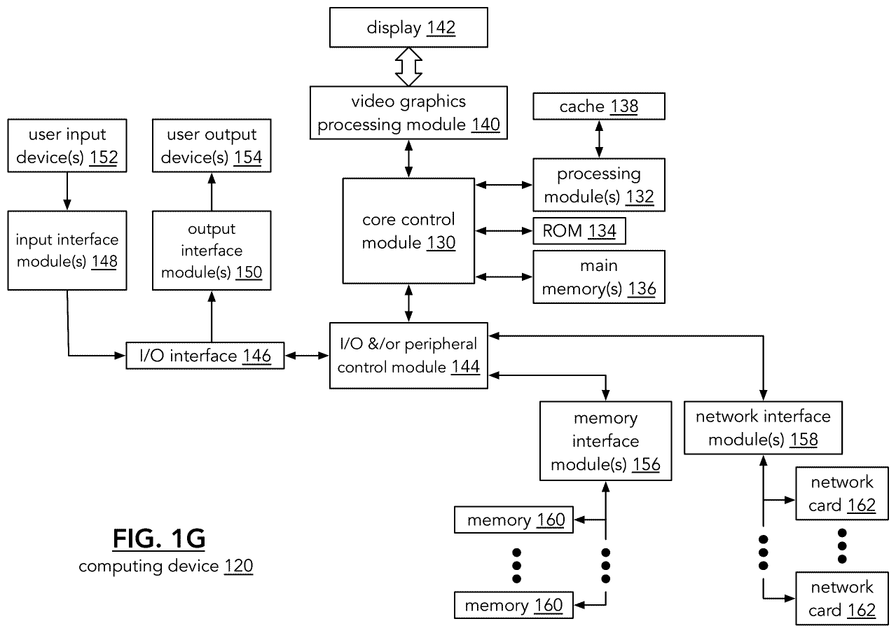

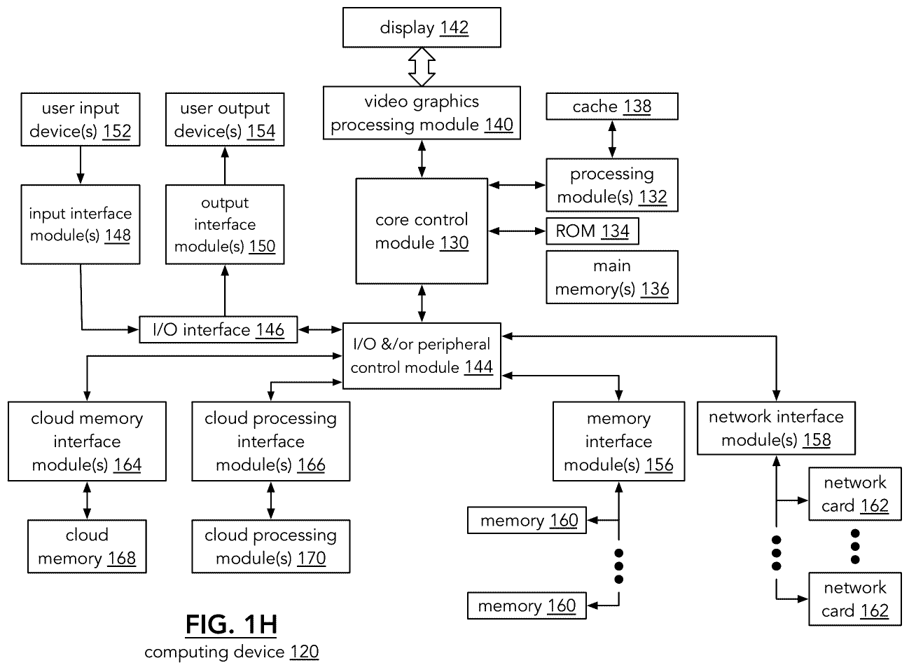

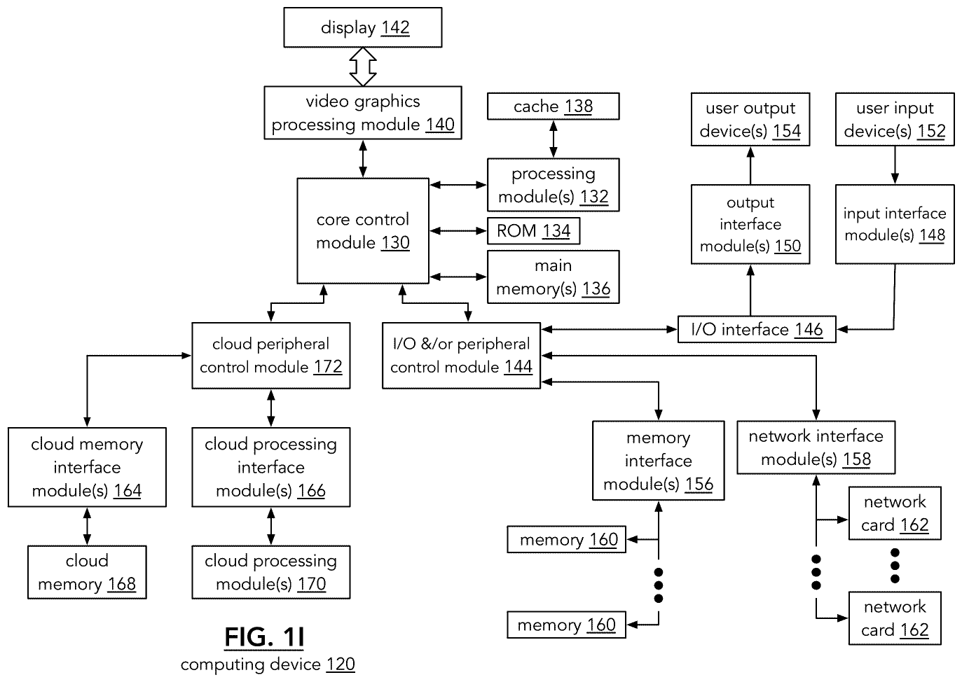

FIG. 1A is a schematic block diagram of an embodiment of a computing network that includes a plurality of computing entities 110-1 and 110-2, a network 201, and may further include a database 185 (which will be described in greater detail with reference to FIG. 1N). The network 201 includes one or more of, but is not limited to, the internet, a cellular data network, a cellular voice network, a local area network (LAN), a wireless LAN (WLAN), a wide area network (WAN), a virtual private network (VPN), a personal area network (PAN), a storage area network (SAN), a campus area network (CAN), a metropolitan area network (MAN), a passive optical local area network, an enterprise private network, and a system area network.

A computing entity 110-1, 110-2 includes one or more computing devices and a touch sense device 200, which, in general, provides a touch-based input mechanism for the computing entity. In this example, computing entity 110-1 communicates with the network 201 via a wired connection and computing entities 110-2 communicates with the network 201 via a wireless connection. Note that a computing entity may include wired and wireless network communication circuitry (e.g., a wired network card and a wireless network card). Further note that an embodiment of the touch sense device 200 is discussed in greater detail with reference to FIG. 1O. Still further note variety of embodiments of a computing entity is discussed with reference to FIGS. 1B through 1F.

FIG. 1B is schematic block diagram of an embodiment of a computing entity 110 that includes a computing device 120 (e.g., one or more of the embodiments of FIGS. 1G-1M). A computing device may function as a user computing device, a server, a system computing device, a data storage device, a data security device, a networking device, a user access device, a cell phone, a tablet, a laptop, a printer, a game console, a satellite control box, a cable box, etc.

FIG. 1C is schematic block diagram of an embodiment of a computing entity 110 that includes two or more computing devices 120 (e.g., two or more from any combination of the embodiments of FIGS. 1G-1M). The computing devices 120 perform the functions of a computing entity in a peer processing manner (e.g., coordinate together to perform the functions), in a master-slave manner (e.g., one computing device coordinates and the other support it), and/or in another manner.

FIG. 1D is schematic block diagram of an embodiment of a computing entity 110 that includes a network of computing devices 120 (e.g., two or more from any combination of the embodiments of FIGS. 1G-1M). The computing devices are coupled together via one or more network connections (e.g., WAN, LAN, cellular data, WLAN, etc.) and perform the functions of the computing entity.

FIG. 1E is schematic block diagram of an embodiment of a computing entity 110 that includes a primary computing device (e.g., any one of the computing devices of FIGS. 1G-1M), an interface device (e.g., a network connection), and a network of computing devices 120 (e.g., one or more from any combination of the embodiments of FIGS. 1G-1M). The primary computing device utilizes the other computing devices as co-processors to execute one or more the functions of the computing entity, as storage for data, for other data processing functions, and/or storage purposes.

FIG. 1F is schematic block diagram of an embodiment of a computing entity 110 that includes a primary computing device (e.g., any one of the computing devices of FIGS. 1G-1M), an interface device (e.g., a network connection) 122, and a network of computing resources 124 (e.g., two or more resources from any combination of the embodiments of FIGS. 1G-1M). The primary computing device utilizes the computing resources as co-processors to execute one or more the functions of the computing entity, as storage for data, for other data processing functions, and/or storage purposes.

FIGS. 1G-1M are schematic block diagram of embodiments of computing devices that form at least a portion of a computing entity. FIG. 1G is a schematic block diagram of an embodiment of a computing device 120 that includes a plurality of computing resources. The computing resources, which form a computing core, include one or more core control modules 130, one or more processing modules 132, one or more main memories 136, a read only memory (ROM) 134 for a boot up sequence, cache memory 138, one or more video graphics processing modules 140, one or more displays 142 (optional), an Input-Output (I/O) peripheral control module 144, an I/O interface module 146 (which could be omitted if direct connect IO is implemented), one or more input interface modules 148, one or more output interface modules 150, one or more network interface modules 158, and one or more memory interface modules 156.

A processing module 132 is described in greater detail at the end of the detailed description section and, in an alternative embodiment, has a direction connection to the main memory 136. In an alternate embodiment, the core control module 130 and the I/O and/or peripheral control module 144 are one module, such as a chipset, a quick path interconnect (QPI), and/or an ultra-path interconnect (UPI).

The processing module 132, the core module 130, and/or the video graphics processing module 140 form a processing core for a computer computing. Additional combinations of processing modules 132, core modules 130, and/or video graphics processing modules 140 form co-processors for the improved computer for technology. Computing resources 124 of FIG. 1F include one more of the components shown in this Figure and/or in or more of FIGS. 1G-1M.

Each of the main memories 136 includes one or more Random Access Memory (RAM) integrated circuits, or chips. In general, the main memory 136 stores data and operational instructions most relevant for the processing module 132. For example, the core control module 130 coordinates the transfer of data and/or operational instructions between the main memory 136 and the secondary memory device(s) 160. The data and/or operational instructions retrieve from secondary memory 160 are the data and/or operational instructions requested by the processing module or will most likely be needed by the processing module. When the processing module is done with the data and/or operational instructions in main memory, the core control module 130 coordinates sending updated data to the secondary memory 160 for storage.

The secondary memory 160 includes one or more hard drives, one or more solid state memory chips, and/or one or more other large capacity storage devices that, in comparison to cache memory and main memory devices, is/are relatively inexpensive with respect to cost per amount of data stored. The secondary memory 160 is coupled to the core control module 130 via the I/O and/or peripheral control module 144 and via one or more memory interface modules 156. In an embodiment, the I/O and/or peripheral control module 144 includes one or more Peripheral Component Interface (PCI) buses to which peripheral components connect to the core control module 130. A memory interface module 156 includes a software driver and a hardware connector for coupling a memory device to the I/O and/or peripheral control module 144. For example, a memory interface 156 is in accordance with a Serial Advanced Technology Attachment (SATA) port.

The core control module 130 coordinates data communications between the processing module(s) 132 and network(s) via the I/O and/or peripheral control module 144, the network interface module(s) 158, and one or more network cards 162. A network card 160 includes a wireless communication unit or a wired communication unit. For example, a wireless communication unit includes a wireless local area network (WLAN) communication device, a cellular communication device, a Bluetooth device, and/or a ZigBee communication device. For example, a wired communication unit includes a Gigabit LAN connection, a Firewire connection, and/or a proprietary computer wired connection. A network interface module 158 includes a software driver and a hardware connector for coupling the network card to the I/O and/or peripheral control module 144. For example, the network interface module 158 is in accordance with one or more versions of IEEE 802.11, cellular telephone protocols, 10/100/1000 Gigabit LAN protocols, etc.

The core control module 130 coordinates data communications between the processing module(s) 132 and input device(s) 152 via the input interface module(s) 148, the I/O interface 146, and the I/O and/or peripheral control module 144. An input device 152 includes a keypad, a keyboard, control switches, a touchpad, a microphone, a camera, etc. An input interface module 148 includes a software driver and a hardware connector for coupling an input device to the I/O and/or peripheral control module 144. In an embodiment, an input interface module 148 is in accordance with one or more Universal Serial Bus (USB) protocols.

The core control module 130 coordinates data communications between the processing module(s) 132 and output device(s) 154 via the output interface module(s) 150 and the I/O and/or peripheral control module 144. An output device 154 includes a speaker, auxiliary memory, headphones, etc. An output interface module 150 includes a software driver and a hardware connector for coupling an output device to the I/O and/or peripheral control module 144. In an embodiment, an output interface module 150 is in accordance with one or more audio codec protocols.

The processing module 132 communicates directly with a video graphics processing module 140 to display data on the display 142. The display 142 includes an LED (light emitting diode) display, an LCD (liquid crystal display), and/or other type of display technology. The display has a resolution, an aspect ratio, and other features that affect the quality of the display. The video graphics processing module 140 receives data from the processing module 132, processes the data to produce rendered data in accordance with the characteristics of the display, and provides the rendered data to the display 142.

FIG. 1H is a schematic block diagram of an embodiment of a computing device 120 that includes a plurality of computing resources similar to the computing resources of FIG. 1G with the addition of one or more cloud memory interface modules 164, one or more cloud processing interface modules 166, cloud memory 168, and one or more cloud processing modules 170. The cloud memory 168 includes one or more tiers of memory (e.g., ROM, volatile (RAM, main, etc.), non-volatile (hard drive, solid-state, etc.) and/or backup (hard drive, tape, etc.)) that is remoted from the core control module and is accessed via a network (WAN and/or LAN). The cloud processing module 170 is similar to processing module 132 but is remoted from the core control module and is accessed via a network.

FIG. 1I is a schematic block diagram of an embodiment of a computing device 120 that includes a plurality of computing resources similar to the computing resources of FIG. 1H with a change in how the cloud memory interface module(s) 164 and the cloud processing interface module(s) 166 are coupled to the core control module 130. In this embodiment, the interface modules 164 and 166 are coupled to a cloud peripheral control module 172 that directly couples to the core control module 130.

FIG. 1J is a schematic block diagram of an embodiment of a computing device 120 that includes a plurality of computing resources, which includes include a core control module 130, a boot up processing module 176, boot up RAM 174, a read only memory (ROM) 134, a one or more video graphics processing modules 140, one or more displays 48 (optional), an Input-Output (I/O) peripheral control module 144, one or more input interface modules 148, one or more output interface modules 150, one or more cloud memory interface modules 164, one or more cloud processing interface modules 166, cloud memory 168, and cloud processing module(s) 170.

In this embodiment, the computing device 120 includes enough processing resources (e.g., module 176, ROM 134, and RAM 174) to boot up. Once booted up, the cloud memory 168 and the cloud processing module(s) 170 function as the computing device's memory (e.g., main and hard drive) and processing module.

FIG. 1K is a schematic block diagram of another embodiment of a computing device 120 that includes a hardware section 180 and a software program section 182. The hardware section 180 includes the hardware functions of power management, processing, memory, communications, and input/output. FIG. 1M illustrates the hardware section 180 in greater detail.

The software program section 182 includes an operating system 184, system and/or utilities applications, and user applications. The software program section further includes APIs and HWIs. APIs (application programming interface) are the interfaces between the system and/or utilities applications and the operating system and the interfaces between the user applications and the operating system 184. HWIs (hardware interface) are the interfaces between the hardware components and the operating system. For some hardware components, the HWI is a software driver. The functions of the operating system 184 are discussed in greater detail with reference to FIG. 1L.

FIG. 1L is a diagram of an example of the functions of the operating system of a computing device 120. In general, the operating system functions to identify and route input data to the right places within the computer and to identify and route output data to the right places within the computer. Input data is with respect to the processing module and includes data received from the input devices, data retrieved from main memory, data retrieved from secondary memory, and/or data received via a network card. Output data is with respect to the processing module and includes data to be written into main memory, data to be written into secondary memory, data to be displayed via the display and/or an output device, and data to be communicated via a network care.

The operating system 184 includes the OS functions of process management, command interpreter system, I/O device management, main memory management, file management, secondary storage management, error detection & correction management, and security management. The process management OS function manages processes of the software section operating on the hardware section, where a process is a program or portion thereof.

The process management OS function includes a plurality of specific functions to manage the interaction of software and hardware. The specific functions include:
load a process for execution;
enable at least partial execution of a process;
suspend execution of a process;
resume execution of a process;
terminate execution of a process;
load operational instructions and/or data into main memory for a process;
provide communication between two or more active processes;
avoid deadlock of a process and/or interdependent processes; and
control access to shared hardware components.

The I/O Device Management OS function coordinates translation of input data into programming language data and/or into machine language data used by the hardware components and translation of machine language data and/or programming language data into output data. Typically, input devices and/or output devices have an associated driver that provides at least a portion of the data translation. For example, a microphone captures analog audible signals and converts them into digital audio signals per an audio encoding format. An audio input driver converts, if needed, the digital audio signals into a format that is readily usable by a hardware component.

The File Management OS function coordinates the storage and retrieval of data as files in a file directory system, which is stored in memory of the computing device. In general, the file management OS function includes the specific functions of:
File creation, editing, deletion, and/or archiving;
Directory creation, editing, deletion, and/or archiving;
Memory mapping files and/or directors to memory locations of secondary memory; and
Backing up of files and/or directories.

The Network Management OS function manages access to a network by the computing device. Network management includes
Network fault analysis;
Network maintenance for quality of service;
Network access control among multiple clients; and
Network security upkeep.

The Main Memory Management OS function manages access to the main memory of a computing device. This includes keeping track of memory space usage and which processes are using it; allocating available memory space to requesting processes; and deallocating memory space from terminated processes.

The Secondary Storage Management OS function manages access to the secondary memory of a computing device. This includes free memory space management, storage allocation, disk scheduling, and memory defragmentation.

The Security Management OS function protects the computing device from internal and external issues that could adversely affect the operations of the computing device. With respect to internal issues, the OS function ensures that processes negligibly interfere with each other; ensures that processes are accessing the appropriate hardware components, the appropriate files, etc.; and ensures that processes execute within appropriate memory spaces (e.g., user memory space for user applications, system memory space for system applications, etc.).

The security management OS function also protects the computing device from external issues, such as, but not limited to, hack attempts, phishing attacks, denial of service attacks, bait and switch attacks, cookie theft, a virus, a trojan horse, a worm, click jacking attacks, keylogger attacks, eavesdropping, waterhole attacks, SQL injection attacks, and DNS spoofing attacks.

FIG. 1M is a schematic block diagram of the hardware components of the hardware section 180 of a computing device. The memory portion of the hardware section includes the ROM 134, the main memory 136, the cache memory 138, the cloud memory 168, and the secondary memory 160. The processing portion of the hardware section includes the core control module 130, the processing module 132, the video graphics processing module 140, and the cloud processing module 170.

The input/output portion of the hardware section includes the cloud peripheral control module 172, the I/O and/or peripheral control module 144, the network interface module 158, the I/O interface module 146, the output device interface 150, the input device interface 148, the cloud memory interface module 164, the cloud processing interface module 166, and the secondary memory interface module 156. The IO portion further includes input devices such as a touch screen, a microphone, and switches. The IO portion also includes output devices such as speakers and a display.

The communication portion includes an ethernet transceiver network card (NC), a WLAN network card, a cellular transceiver, a Bluetooth transceiver, and/or any other device for wired and/or wireless network communication.

FIG. 1N is a schematic block diagram of an embodiment of a database 185 that includes a data input computing entity 190, a data organizing computing entity 191, a data query processing computing entity 192, and a data storage computing entity 193. Each of the computing entities is implemented in accordance with one or more of the embodiments of FIGS. 1G through 1M.

The data input computing entity 190 is operable to receive an input data set 195. The input data set 195 is a collection of related data that can be represented in a tabular form of columns and rows, and/or other tabular structure. In an example, the columns represent different data elements of data for a particular source and the rows corresponds to the different sources (e.g., employees, licenses, email communications, etc.).

If the data set 195 is in a desired tabular format, the data input computing entity 190 provides the data set to the data organizing computing entity 191. If not, the data input computing entity 190 reformats the data set to put it into the desired tabular format.

The data organizing computing entity 191 organizes the data set 195 in accordance with a data organizing input 197. In an example, the input 197 is regarding a particular query and requests that the data be organized for efficient analysis of the data for the query. In another example, the input 197 instructions the data organizing computing entity 191 to organize the data in a time-based manner. The organized data is provided to the data storage computing entity for storage.

When the data query processing computing entity 192 receives a query 196, it accesses the data storage computing entity 193 regarding a data set for the query. If the data set is stored in a desired format for the query, the data query processing computing entity 192 retrieves the data set and executes the query to produce a query response 198. If the data set is not stored in the desired format, the data query processing computing entity 192 communicates with the data organizing computing entity 191, which re-organizes the data set into the desired format and stores the re-organized data in the data storage computing entity 193.

FIG. 1O is a schematic block diagram of an embodiment of a touch sense device 200 that includes a touch sense controller 202, one or more touch sensors 204, and a touch sense host processing module 206. The touch sense controller 202 includes a plurality of drive sense circuits (DSC) 208, a touch sense processing module 210, a touch sense oscillating reference signal generating circuit 214, and a touch sense host interface 212.

A touch sensor 204 may be implemented in a variety of ways but functions to provide an indication of a condition being sensed. In general, variances of an electrical property or of a physical property of a sensor are used to indicate the condition being sensed. As used herein, an electrical property of a sensor includes one or more of voltage, current, resistance, capacitance, impedance, reactance, inductance, phase response, frequency response, etc. As also used herein, a physical property of a sensor includes one or more of vibration, expansion, contraction, heat, etc.

As a specific example, the touch sensor 204 is an electrode of a touch sensor array, wherein the capacitance of the electrode is used to determine a touch (e.g., user's finger physically touches the device 200) or a hover (e.g., user's finger is physically proximal to, but is not touching the device 200). As other specific examples, the touch sensor 204 is a capacitance sensor, a resistive sensor, an inductance sensor, a pressure sensor, a temperature sensor, a heart rate sensor, etc.

In general, the touch sense device 200 is an input device of a computing device and/or computing entity. For example, the touch sense device 200 is a touch screen display for use in handheld computing devices (e.g., cell phones, tablets, etc.), in portable computing devices (e.g., laptop computers), in fixed computing devices (e.g., personal computer, server, etc.), in televisions, in computer monitors, etc.

As another example, the touch sense device 200 is a biometric touch sensor. As another example, the touch sense device 200 is a touch-based remote control. As another example, the touch sense device 200 is a touch-based switch or series of switches. As another example, the touch sense device 200 is a gesture recognition device.

In an alternate embodiment, the touch sense device 200 is configured to sense environmental conditions (e.g., temperature, moisture, humidity, altitude, etc.) and/or physical conditions (e.g., pressure, flow rate, expansion and/or contraction, etc.) instead of human touch. For example, the touch sense device 200 functions as an analog to digital sensing device for a variety of Internet of Things (IoT) applications. As another example, the touch sense device 200 functions as a human to machine interface (HMI) device for a variety of HMI applications.

In an example of operation, the touch sense processing unit 210 instructs the touch sense oscillating reference signal generating circuit 214 to generate one or more oscillating reference signals 216. In general, an oscillating reference signal includes a DC component (e.g., a voltage centered between the positive and negative power supply rails of the touch sense controller) and one or more an oscillating components (e.g., a sinusoid signal at a frequency, a square wave signal at a frequency, a triangle waveform signal at a frequency, a sawtooth signal at a frequency, etc.). As a specific example, the sense oscillating reference signal generating circuit 214 generates a self-capacitance sensing reference signal having a sinusoidal signal at a first frequency and a plurality of mutual-capacitance sensing reference signals, each having a sinusoidal signal at a different frequency.

As described in greater detail with reference to one or more subsequent figures, a drive sense circuit (DSC) generates a drive signal based on an oscillating reference signal and senses how it is affected by the corresponding sensor. The effect on the drive signal corresponds to an electrical property or physical property of the sensor. The DSC converts effect on the drive signal into a digital value that represents the electrical property or physical property of the sensor.

The touch sense processing module 210 processes the digital values to generate meaningful touch data. For example, the touch sense processing module 210 determines a physical position of a touch on the touch sense device. The touch sense host interface 212 provides the meaningful touch data to the touch host processing module 206, which executes one or more host software applications on the meaningful touch data.

For example, the touch host processing module 206 generates video display data regarding the meaningful touch data. As other examples, the touch host processing module 206 adjusts audio volume, the brightness of a light, starts a phone call, ends a phone call, and so on based on the meaningful touch data.

The touch sense controller addresses one or more limitations of conventional digital signal sensing, which include:
have separate lines for drive & sense of a sensor;
touch screen controllers are susceptible to noise, thus cannot concurrently operate touch & video; higher resolution video and higher refresh rate, leaves less time for touch;
sample a single row of touch electrodes at a time;
need to use large digital signaling to provide adequate SNR for touch sense electrodes;
very difficult to have an adequate SNR & large digital signaling for long touch sense electrodes (e.g., >18 inches); and
power consumption is an issue, especially as magnitude of digital sense signal increases.

The DSC based touch sense controller provides one or more benefits, which include:
an analog front end (AFE) that has low impedance output and a high impedance input coupled to a single line for concurrent drive and sense of a sensor via a single line;
an AFE that uses an analog sinusoidal current drive signal, which is based on an analog sinusoidal voltage reference signal to sample a sensor's impedance to improve noise immunity, reduce power consumption, and/or enable sensing long electrodes;
the AFE generates a regulated or unregulated analog drive signal, which, when affected by the sensor, provides a representation of an electrical property of the sensor;
the AFE includes an ADC with very high clock rate (e.g., sigma delta 1-bit ADC at 39.32 MHz) to produce a digital representation of impedance (Z), which supports full screen touch sensing that can be done concurrently with video display due to the improved noise immunity;
the AFE senses the sensor in the analog domain and frequency domain using, in an embodiment, current-based signals;
the DSC includes decimation & bandpass digital filtering to produce a filtered digital representation of Z, which support noise immunity & full screen touch sensing concurrent with video display;
the DSC includes digital data processing to convert the filtered digital rep of Z into a digital value representative of a characteristic of the sensor.

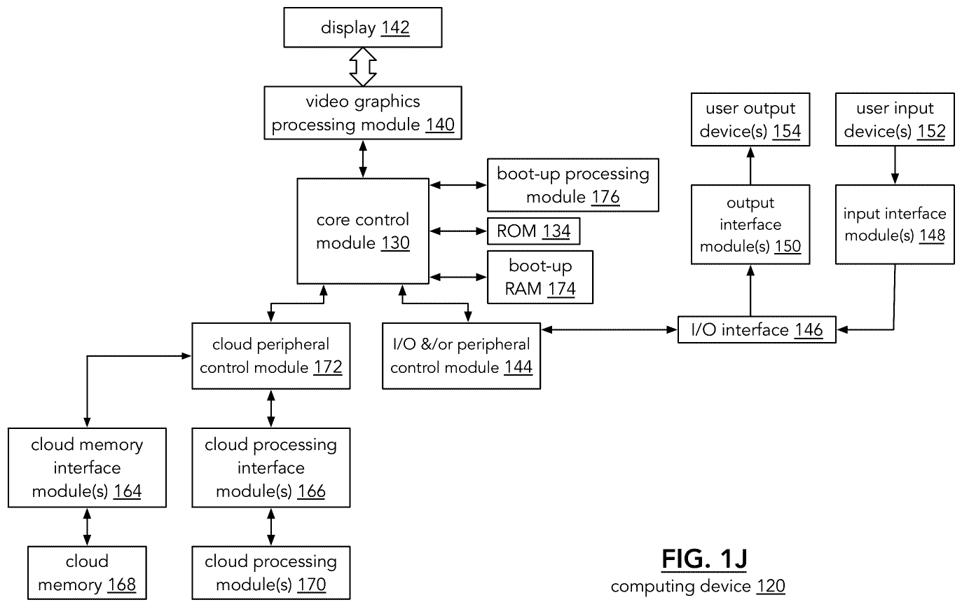

FIG. 2 is a schematic block diagram of an embodiment of a drive sense circuit 208 that includes an unregulated analog front end 220, an analog to digital converter (ADC) 222, a digital filter circuit 224, and a data processing unit 226. The unregulated analog front end 220 receives an oscillating reference signal 216 from the oscillating reference signal generator 214 and generates therefrom an unregulated analog drive signal 230.

The unregulated analog front end 220 provides the unregulated analog drive signal 230 to the sensor 204 and senses, via the same connection, the effect 232 the sensor has on the drive signal 230 to produce an analog sensed signal 234. As discussed with reference to subsequent figures, there is a plurality of embodiments of the analog drive signal 230 and a variety of effects on it, which include, but are not limited to, an effect on the AC magnitude of the drive signal, an effect on the DC magnitude of the drive signal, an effect on the phase of the drive signal, and an effect on the frequency of the drive signal.

The ADC converts the analog sensed signal 234 into a digital sensed signal 236. The digital filter circuit 224 digitally filters the digital sensed signal 236 to produce a filtered digital sensed signal 238. The data processing unit 226 generates a digital value 240 that represents a sensed characteristic of the sensor based on the filtered digital sensed signal 238. The characteristics include one or more of inductance, detected light, capacitance, reactance, resistance, phase response, frequency response, impedance, an environmental condition (e.g., temperature, moisture, humidity, etc.), and a physical condition (e.g., pressure, heat, expansion, contraction, etc.). Note that the digital filter circuit 224 and the data processing unit 226 will be described in greater detail with reference to one or more subsequent figures.

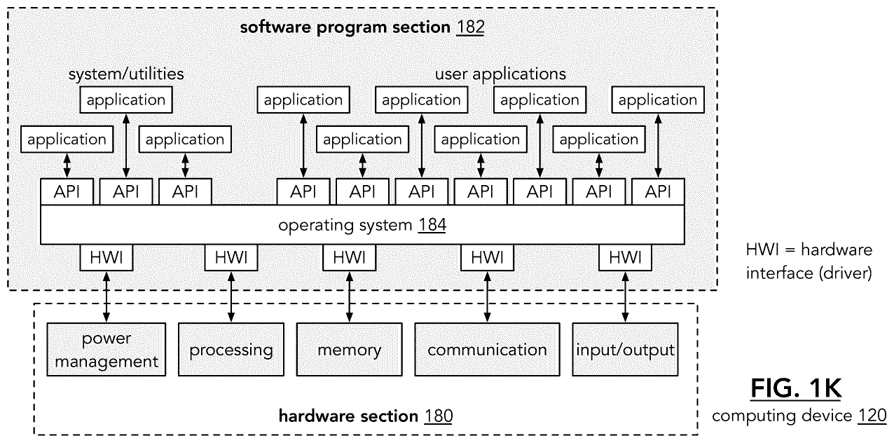

FIG. 3 is a schematic block diagram of an embodiment of an unregulated analog front end 220 of a drive sense circuit coupled to a sensor 204. The analog front end 220 includes a power source circuit 252 and a power signal change detection circuit 254. The sensor 254 includes one or more transducers (or other type of sensor structure) that have varying electrical properties (e.g., capacitance, inductance, impedance, current, voltage, phase, frequency, etc.) based on varying environmental and/or physical conditions 114 (e.g., pressure, temperature, biological, chemical, etc.).

The power source circuit 252 is operably coupled to the sensor 204 and, when enabled (e.g., from a control signal from the processing unit 210, power is applied, a switch is closed, a reference signal is received, etc.) provides an analog drive signal 230 to the sensor 204. The power source circuit 252 may be a voltage supply circuit (e.g., a battery, a linear regulator, an unregulated DC-to-DC converter, etc.) to produce a voltage-based power signal, a current supply circuit (e.g., a current source circuit, a current mirror circuit, etc.) to produce a current-based power signal, or a circuit that provide a desired power level to the sensor and substantially matches impedance of the sensor. The power source circuit 252 generates the analog drive signal 230 to include a DC (direct current) component and/or an oscillating component.

When receiving the analog drive signal 230, an electrical property of the sensor affects 232 the signal 230. When the power signal change detection circuit 254 is enabled, it detects the effect 232 on the signal 230 as a result of the electrical property of the sensor. For example, the drive signal is a 1.5 voltage signal, and, under a first condition, the sensor draws 1 milliamp of current, which corresponds to an impedance of 1.5 K Ohms. Under a second condition, the drive signal remains at 1.5 volts and the current increases to 1.5 milliamps. As such, from condition 1 to condition 2, the impedance of the sensor changed from 1.5 K Ohms to 1 K Ohms. The power signal change detection circuit 254 determines this change and generates a representative signal 120 of the change to the power signal.

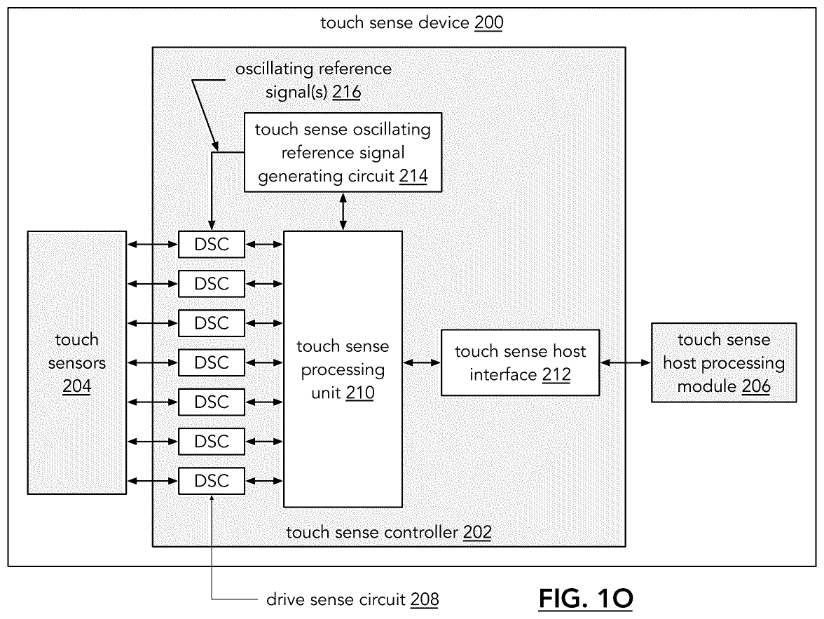

The drive signal 232 includes a DC component and/or an oscillating component as shown in FIG. 7 of the parent patent application reference above. The oscillating component includes a sinusoidal signal, a square wave signal, a triangular wave signal, a multiple level signal (e.g., has varying magnitude over time with respect to the DC component), and/or a polygonal signal (e.g., has a symmetrical or asymmetrical polygonal shape with respect to the DC component).

In an embodiment, power generating circuit 252 varies frequency of the oscillating component of the drive signal 230 so that it can be tuned to the impedance of the sensor and/or to be off-set in frequency from other drive signals in a touch sense device. For example, a capacitance sensor's impedance decreases with frequency. As such, if the frequency of the oscillating component is too high with respect to the capacitance, the capacitor looks like a short and variances in capacitances will be missed. Similarly, if the frequency of the oscillating component is too low with respect to the capacitance, the capacitor looks like an open and variances in capacitances will be missed.

In an embodiment, the power generating circuit 252 varies magnitude of the DC component and/or the oscillating component to improve resolution of sensing and/or to adjust power consumption of sensing. In addition, the power generating circuit 252 generates the drive signal 230 such that the magnitude of the oscillating component is less than magnitude of the DC component.

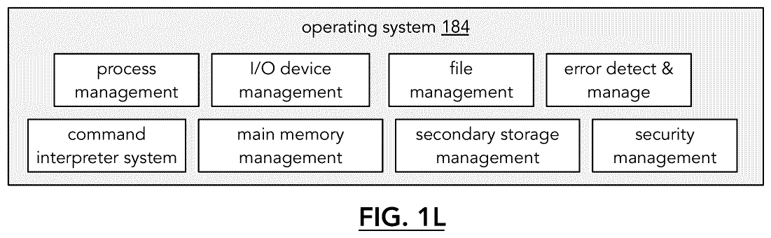

FIG. 4 is a schematic block diagram of another embodiment of an unregulated analog front end 220 of a drive sense circuit. In this embodiment, the analog front end 220 includes a dependent drive source 260 and an operational amplifier (op amp) or comparator 262. The dependent drive source 260 is a dependent current source, a dependent voltage source, or a dependent impedance source; each of which will be discussed in greater detail with reference to one or more subsequent figures.

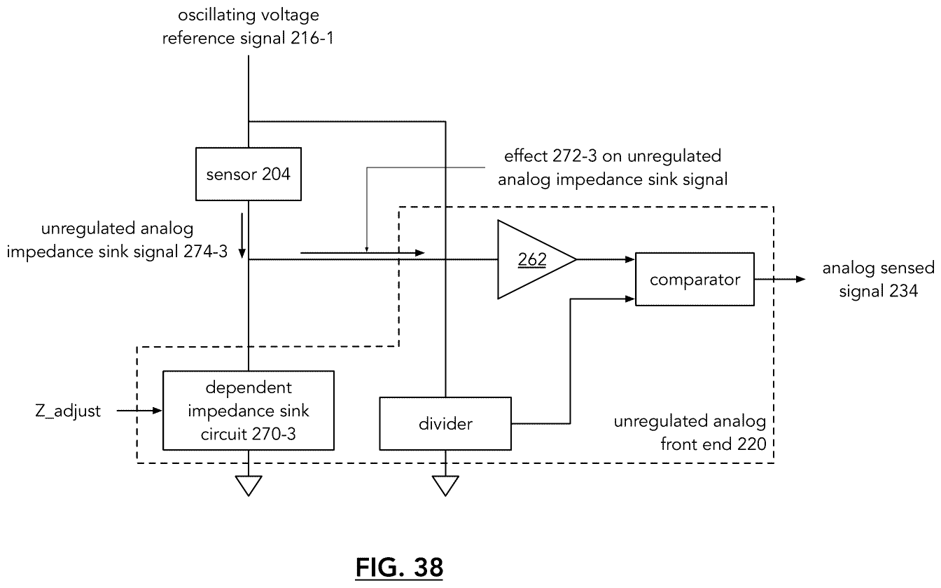

The dependent drive source 260 generates the unregulated analog drive signal 230 based on the oscillating reference signal 216. The dependent drive source 260 has a low output impedance, which provides the unregulated analog drive signal 230 to the sensor. Note that the analog drive signal 230 includes the “unregulated” in its name. As used herein, unregulated is in reference to the op amp or comparator being open loop with reference to generating the analog drive signal 230 as compared to the closed loop as shown in FIG. 43.

The op amp or comparator 262, which has a high input impedance, compares the oscillating reference signal 216 with the unregulated analog drive signal 230 to detect the effect 232 the sensor has on the signal. The op amp or comparator 262 generates an analog sensed signal 234, which represents the effect 232.

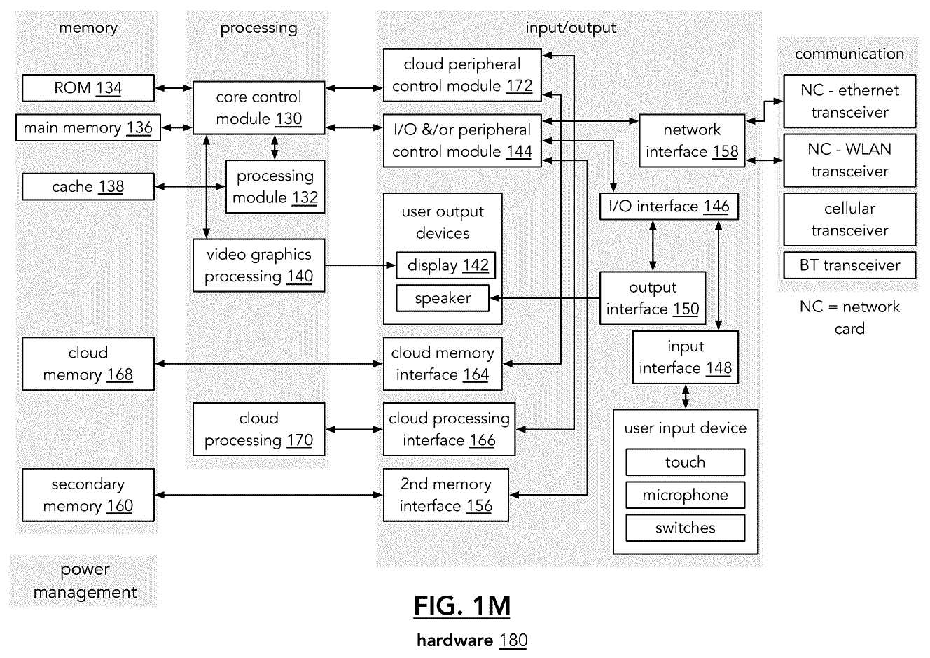

FIG. 5 is a schematic block diagram of another embodiment of an unregulated analog front end (AFE) 220 of a drive sense circuit. In this embodiment, the analog front end 220 includes a dependent current source 260-1 and an op amp or comparator 262. The dependent current source 260-1 generates an unregulated analog current drive signal 230-1 (iₛ) based on an oscillating voltage reference signal 216-1 (v_{ref}).

The dependent current source 260-1 is constructed to have a current-to-voltage conversion ratio (e.g., 10 micro-Amps to 1 Volt, ranging from 1 micro-Amp to 20 micro-Amps). As such, for a 0.5 volt sinusoidal reference signal, the dependent current source 260-1 generates a 5 micro-Amp sinusoidal analog current drive signal 230-1.

Based on the impedance (Zs) of the sensor and the current drive signal 230-1, a sensor voltage (vₛ) is created, which includes the effect the sensor had on the drive signal (vₛ=Z*iₛ). The op amp or comparator 262 generates the analog sensed signal 234 (vₒ) as a difference between the reference voltage signal (v_{ref}) and the sensor voltage (vₛ). As such, in this embodiment, the AFE 220 is configured to drive a current (I) based on a reference voltage (V) to sense impedance of the sensor (Z), where V=I*Z.

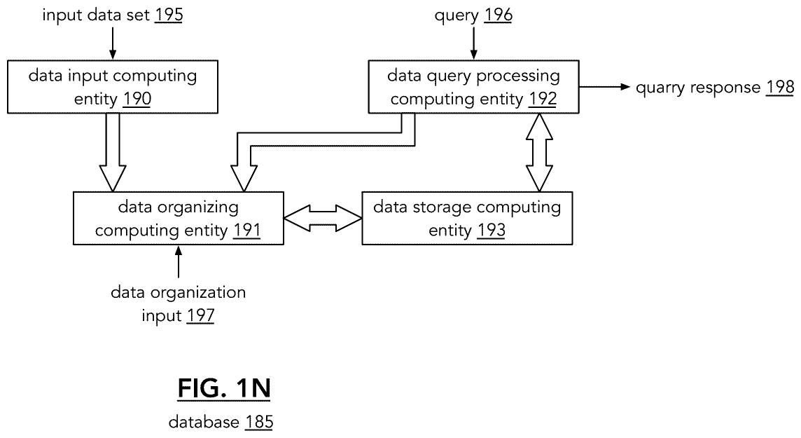

FIG. 6 is a schematic block diagram of another embodiment of an unregulated analog front end (AFE) 220 of a drive sense circuit. In this embodiment, the analog front end 220 includes a dependent current source 260-1 and a non-inverting unity gain operational amplifier circuit (as is known). The dependent current source 260-1 generates an unregulated analog current drive signal 230-1 (iₛ) based on an oscillating voltage reference signal 216-1 (v_{ref}).

Based on the impedance (Zs) of the sensor and the current drive signal 230-1, a sensor voltage (vₛ) is created, which includes the effect the sensor had on the drive signal (vₛ=Z*iₛ). The non-inverting unity gain operational amplifier outputs the sensor voltage (vₛ) as the analog sensed signal 234. As such, in this embodiment, the AFE 220 is configured to drive a current (I) based on a reference voltage (V) to sense impedance of the sensor (Z), where V=I*Z.

FIG. 7 is a schematic block diagram of another embodiment of an unregulated analog front end (AFE) 220 of a drive sense circuit. In this embodiment, the analog front end 220 includes a dependent current source 260-1 and an op amp or comparator 262. The dependent current source 260-1 generates an unregulated analog current drive signal 230-1 (iₛ) based on an oscillating impedance reference signal 216-2 (Z_{ref}).

The oscillating impedance reference signal 216-2 is a voltage signal that represents a specific impedance for a specific voltage, a specific current, and a specific frequency for a capacitance sensor. Manipulating the equations Z=1/(2*π*f*C) and Z=V/I, a specific voltage (v_{ref}) corresponds to a specific impedance of a capacitor.

Based on the impedance (Zs) of the sensor and the current drive signal 230-1, a sensor voltage (vₛ) is created, which includes the effect the sensor had on the drive signal (vₛ=Z*iₛ). The op amp or comparator 262 generates the analog sensed signal 234 (vₒ) as a difference between the specific voltage (v_{ref}) and the sensor voltage (vₛ). As such, in this embodiment, the AFE 220 is configured to drive a current (I) based on a reference impedance (Z) to sense voltage of the sensor (V), where V=I*Z.

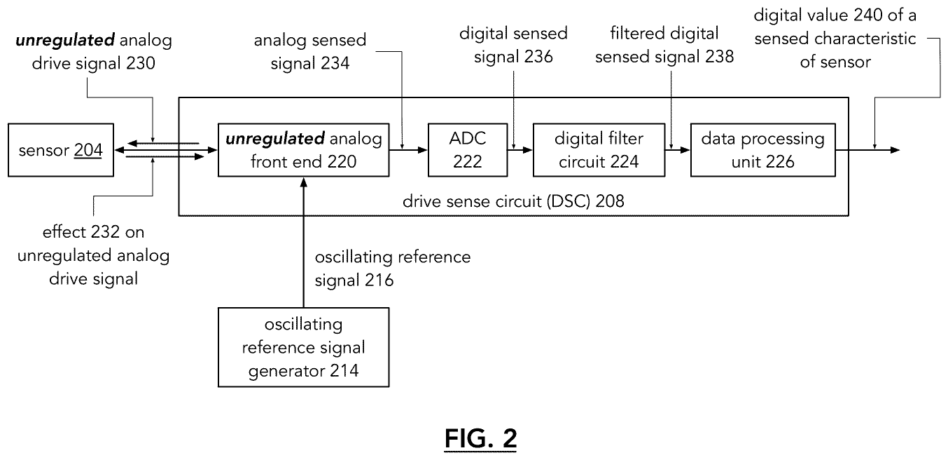

FIG. 8 is a schematic block diagram of a specific embodiment of the unregulated analog front end 220 of FIG. 7. In this embodiment, the analog front end includes the dependent current source 260-1, a non-inverting op amp, a gain adjust circuit, and a comparator. The oscillating impedance reference signal 216-2 is generated by an impedance reference circuit (Zref) and a dependent current source.

Zref is chosen to be in a range of the impedance of the sensor. For example, if the sensor is a capacitance sensor that ranges from 10 pico-Farads (pF) to 30 pF, then Zref is a capacitor having a capacitance of 10 pF. As another example, of the sensor is a resistance sensor that ranges from 100 K-Ohms to 200 K-Ohms, then Zref is a resistor having a resistance of 150 K-Ohms.

The dependent current source of the reference signal generator produces a fixed current [i(t)=A sin ω(t)] based on a voltage to current setting (V to I_ref). With a known impedance and a known current, the voltage across the reference impedance is calculated as Z_ref*I_ref, which is represented as V of Z_ref. This effective is comparing the impedance of the sensor to the reference impedance.

The dependent current source 260-1 provides a current to the sensor, which affects the signal. The non-inverting op amp outputs the voltage of the sensor (vs). The gain adjust circuit adjusts the gain of the op-amp. For example, the gain adjust circuit provides unity gain. As another example, the gain adjust circuit provides a gain of 10 such that the voltage outputted by the op amp is 10 times the voltage at its input. The comparator compares vs with V of Z_ref to produce the analog sensed signal.

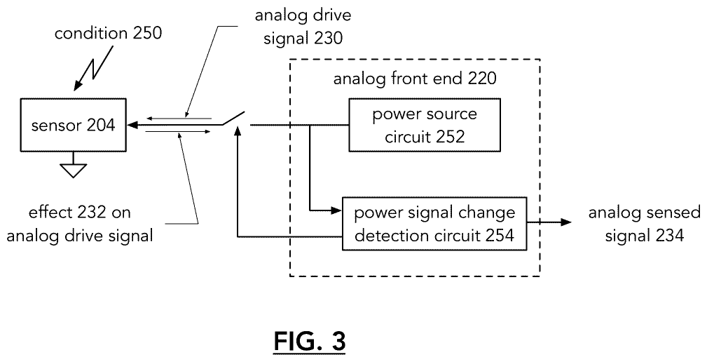

FIG. 9 is a schematic block diagram of another embodiment of an unregulated analog front end (AFE) of a drive sense circuit. In this embodiment, the analog front end 220 includes a dependent current source 260-1 and a non-inverting unity gain op-amp. The dependent current source 260-1 generates an unregulated current drive signal 230-1 (iₛ) based on an oscillating impedance reference signal 216-2.

Based on the impedance (Zs) of the sensor and the current drive signal 230-1, a sensor voltage (vₛ) is created, which includes the effect the sensor had on the drive signal (vₛ=Z*iₛ). The non-inverting unity gain operational amplifier outputs the sensor voltage (vₛ) as the analog sensed signal 234. As such, in this embodiment, the AFE 220 is configured to drive a current (I) based on a reference impedance (Z) to sense voltage of the sensor (V), where V=I*Z.

FIG. 1O is a schematic block diagram of another embodiment of an unregulated analog front end (AFE) of a drive sense circuit. In this embodiment, the analog front end 220 includes a dependent voltage source 260-2 and a trans-impedance amplifier circuit 264 (as is known). The dependent voltage source 260-2 generates an unregulated analog voltage drive signal 230-2 based on an oscillating current reference signal 216-3.

Based on the impedance (Zs) of the sensor and the voltage drive signal 230-2, a sensor current (iₛ) is created, which includes the effect the sensor had on the drive signal (iₛ=vₛ/Z). The trans-impedance amplifier 264 generates the analog sensed signal 234 as a difference between the current reference signal (i_{ref}) and the sensor current (iₛ). As such, in this embodiment, the AFE 220 is configured to drive a Voltage (V) based on a reference current (I) to sense impedance of the sensor, where Z=V/I.

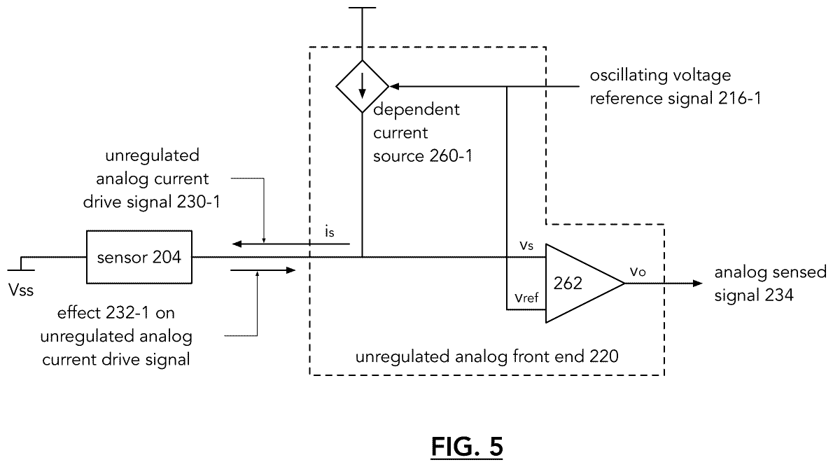

FIG. 11 is a schematic block diagram of another embodiment of an unregulated analog front end (AFE) of a drive sense circuit. In this embodiment, the analog front end 220 includes a dependent voltage source 260-2 and a trans-impedance amplifier circuit 264. The dependent voltage source 260-2 generates an unregulated analog voltage drive signal 230-2 based on an oscillating current reference signal 216-3.

Based on the impedance (Zs) of the sensor and the voltage drive signal 230-2, a sensor current (iₛ) is created, which includes the effect the sensor had on the drive signal (iₛ=vₛ/Z). The trans-impedance amplifier 264 generates the analog sensed signal 234 as a difference between a direct current reference signal (i_{DC}) and the sensor current (iₛ). As such, in this embodiment, the AFE 220 is configured to drive a Voltage (V) based on a reference current (I) to sense impedance of the sensor, where Z=V/I.

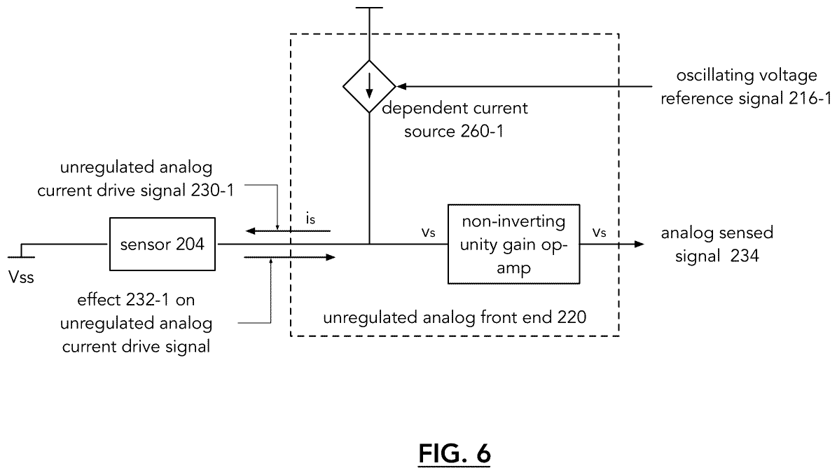

FIG. 12 is a schematic block diagram of another embodiment of an unregulated analog front end (AFE) of a drive sense circuit. In this embodiment, the analog front end 220 includes a dependent voltage source 260-2, a trans-impedance amplifier circuit 264, and a comparator. The dependent voltage source 260-2 generates an unregulated analog voltage drive signal 230-2 based on an oscillating impedance reference signal 216-2.

In this embodiment, the oscillating impedance reference signal 216-2 is an impedance signal that represents a specific impedance for a specific voltage, a specific current, and a specific frequency for a capacitance sensor. Manipulating the equations Z=1/(2*π*f*C) and Z=V/I, a specific current (Iref) corresponds to a specific impedance of a capacitor.

Based on the impedance (Zₛ) of the sensor and the voltage drive signal 230-2, a sensor current (iₛ) is created, which represents the effect the sensor had on the drive signal (iₛ=vₛ/Z). The trans-impedance amplifier 264 generates a voltage representation of the sensor current (is). The comparator compares the voltage of the sensed current with a voltage representation of the oscillating impedance reference signal to produce the analog sensed signal 234. As such, in this embodiment, the AFE 220 is configured to drive a Voltage (V) based on a reference impedance (Z) to sense current through the sensor, where I=Z*V.

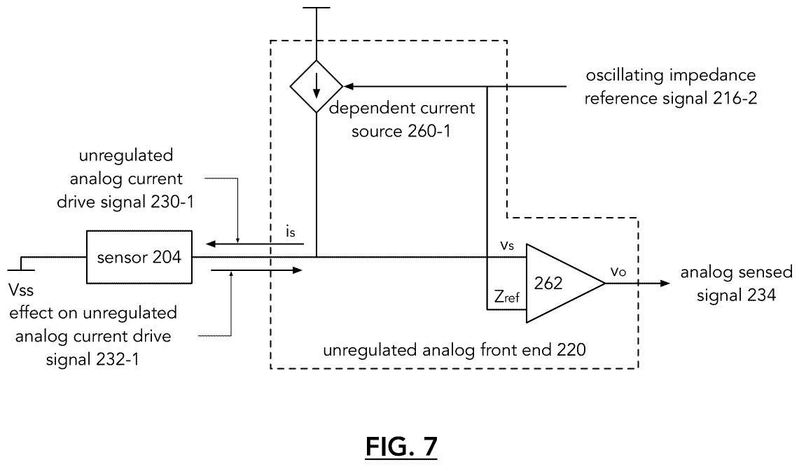

FIG. 13 is a schematic block diagram of a functional example of the unregulated AFE 220 of FIG. 12. In this example, the oscillating impedance reference signal 216-2 is a voltage signal V of Z_ref, which is produced by a dependent current source and a known impedance Z_ref. As such, Z_ref=V of Z_ref/I_ref.

The dependent voltage source 260-2, which, in this example, is a voltage driver, provides the known voltage of V of Z_ref to the sensor. The current (I_load) is measured, which allows Z_sensor to be calculated as V of Z_ref/I_load.

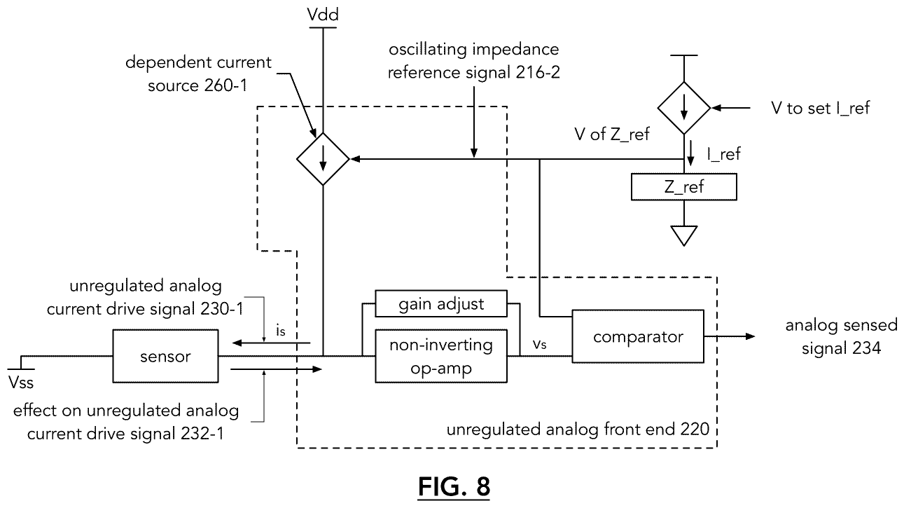

FIG. 14 is a schematic block diagram of another embodiment of an unregulated analog front end (AFE) of a drive sense circuit. In this embodiment, the analog front end 220 includes a dependent voltage source 260-2, a trans-impedance amplifier circuit 264, and a voltage to current converter 263. The dependent voltage source 260-2 generates an unregulated analog voltage drive signal 230-2 based on an oscillating impedance reference signal 216-2.

Based on the impedance (Zs) of the sensor and the voltage drive signal 230-2, a sensor current (iₛ) is created, which includes the effect the sensor had on the drive signal (iₛ=vₛ/Z). The trans-impedance amplifier 264 generates the analog sensed signal 234 as a difference between the direct current reference signal (i_{DC}) and the sensor current (iₛ). As such, in this embodiment, the AFE 220 is configured to drive a Voltage (V) based on an impedance reference (Z) to sense current (I) of the sensor, where I=V/Z.

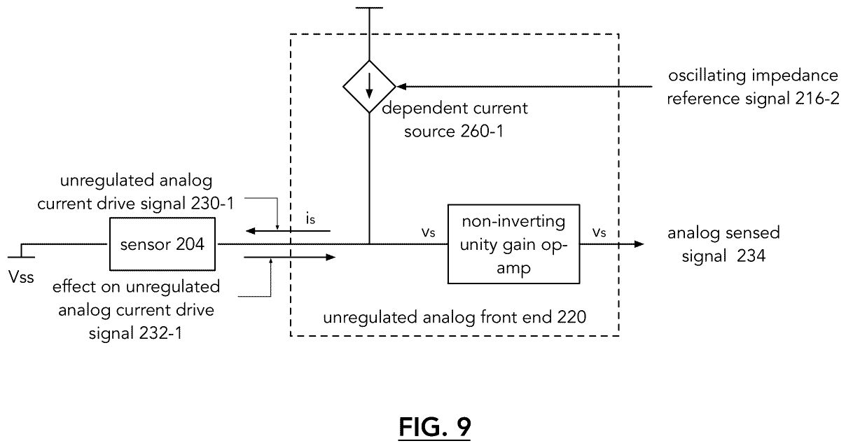

FIG. 15 is a schematic block diagram of another embodiment of an unregulated analog front end (AFE) of a drive sense circuit. In this embodiment, the analog front end 220 includes a dependent impedance source 260-3 (e.g., a variable impedance circuit such as a varactor or capacitor bank), an op amp or comparator 262, a divider, and a comparator. The dependent impedance source 260-3 generates an unregulated analog impedance drive signal 230-3 based on an oscillating voltage reference signal 216-1.

Based on the impedance of the sensor and the impedance drive signal 230-3, a sensor voltage (vₛ) is created, which includes the effect the sensor had on the drive signal (vₛ=Zₛ*I). The amplifier 262 amplifies (e.g., unity gain to 10× gain) the sensed voltage to produce a sensed voltage. The comparator compares the sensed voltage with a divider version of the oscillating voltage reference signal to produce the analog sensed signal 234.

The analog front end (AFE) of a drive sense circuit. In this embodiment, the analog front end 220 includes a dependent impedance source 260-3 and a trans-impedance non-inverting unity gain operational amplifier circuit. The dependent impedance source 260-3 generates an unregulated analog impedance drive signal 230-3 based on an oscillating voltage reference signal 216-1. Note that when the voltage of the sensor equals ½ of the reference voltage 216-1 (assuming a 50/50 divider), the impedance of the sensor equals the impedance of the dependent impedance source 260-3. When the voltage of the sensor is not equal to ½ of the reference voltage, the impedance of the dependent impedance source is determined based on Z_adjust and the impedance of the sensor is determined based on the difference in voltages. Alternatively, the dependent impedance source is adjusted until the voltage of the sensor equals ½ of the reference voltage 216-1. The impedance of the dependent impedance source is determined based on Z_adjust, which equals the impedance of the sensor under this condition.

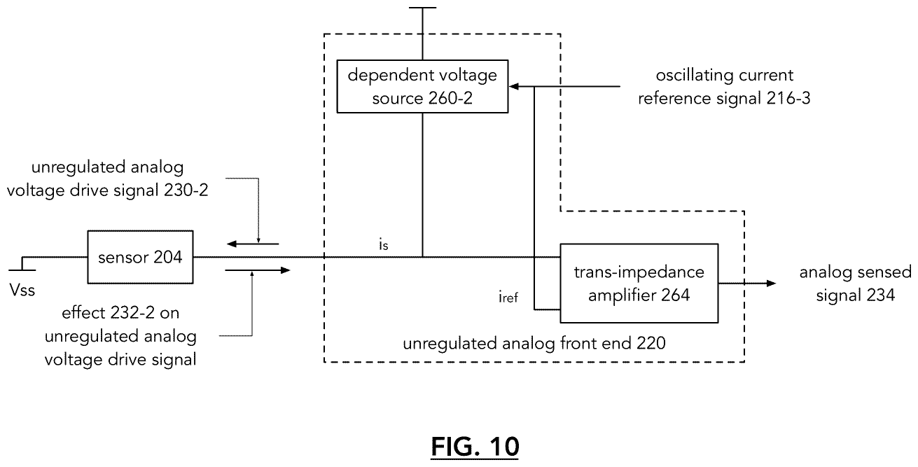

FIG. 16 is a schematic block diagram of another embodiment of an unregulated analog front end (AFE) of a drive sense circuit. In this embodiment, the analog front end 220 includes a dependent impedance source 260-3 (e.g., a variable impedance circuit such as a varactor or capacitor bank), and an op amp or comparator 262. The dependent impedance source 260-3 generates an unregulated analog impedance drive signal 230-3 based on an oscillating voltage reference signal 216-1, which includes a current component.

Based on the impedance (Zs) of the sensor and the current component of the impedance drive signal 230-3, a sensor voltage (vₛ) is created, which includes the effect the sensor had on the drive signal (iₛ=vₛ/Z). The amplifier 262 generates the analog sensed signal.

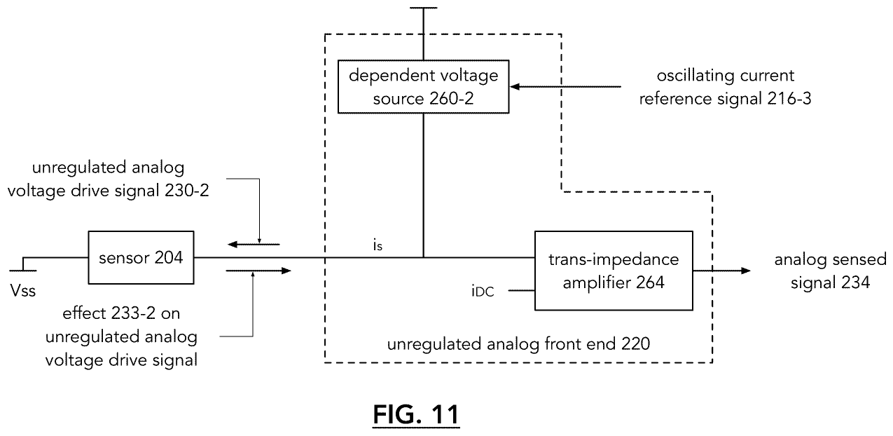

FIG. 17 is a schematic block diagram of another embodiment of an unregulated analog front end 220 of a drive sense circuit. The unregulated AFE 220 includes an amplifier 262 and a dependent impedance source 260-3 (e.g., a variable impedance). An oscillating current reference signal 216-3 is provided to the sensor and to the dependent impedance source 260-3.

The amplifier 262 compares the voltage of sensor (Vs) to the voltage of dependent impedance source (Vz_ref) to produce the analog sensed signal 234. In this manner, the impedances of the sensor and the dependent impedance source are being compared. The comparison is used to determine the impedance of the sensor based on the known impedance of the dependent impedance source 260-3.

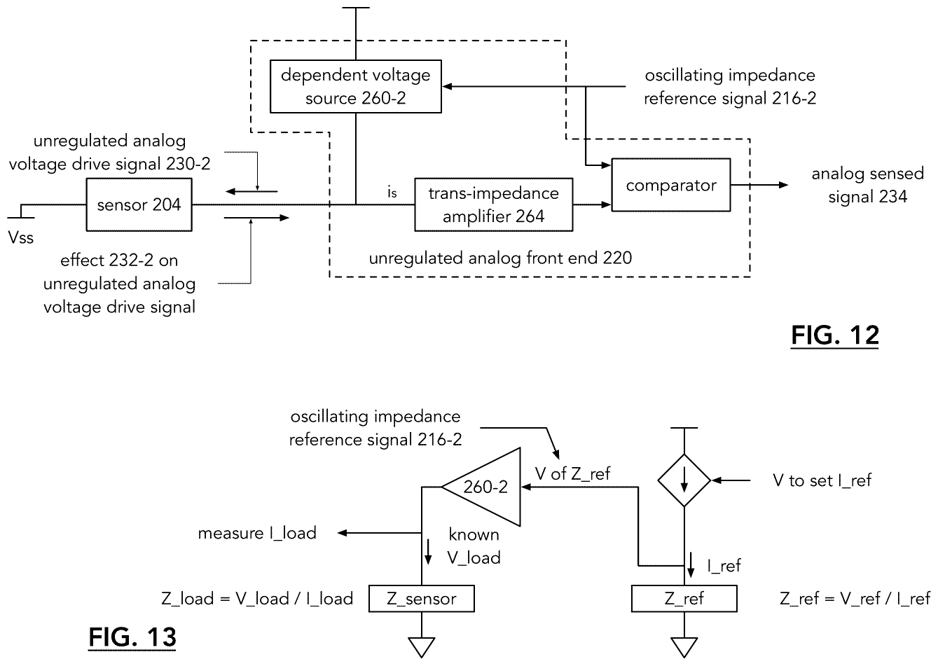

FIG. 18 is a schematic block diagram of another embodiment of an unregulated analog front end (AFE) of a drive sense circuit. In this embodiment, the analog front end 220 includes a dependent impedance source 260-3 and an operational amplifier circuit. An oscillating current reference signal 216-3 is provided to the parallel combination of the sensor and the dependent impedance source 260-3.

The voltage (Vs) of the parallel combination of the sensor and dependent impedance source 260-3 (vₛ) is amplified (e.g., 1× to 10×) by the amplifier to produce the analog sensed signal 234. In this embodiment, the impedance of the sensor is determined based on V=Z*I, where Z is the parallel combination of the sensor and the impedance reference. Since the impedance of the impedance reference is known, V is known, and I is known, the impedance of sensor is calculable.

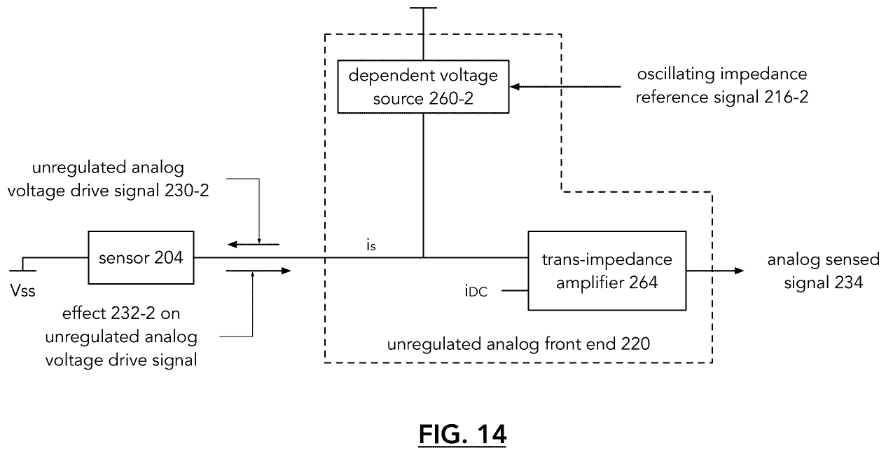

FIG. 19 is a schematic block diagram of another embodiment of an unregulated analog front end (AFE) of a drive sense circuit. In this embodiment, the analog front end 220 includes a dependent drive source 260, an operational amplifier (op amp) and a gain feedback circuit. The dependent drive source 260 is a dependent current source, a dependent voltage source, or a dependent impedance source.

The dependent drive source 260 generates the unregulated analog drive signal 230 based on the oscillating reference signal 216. The dependent drive source 260 has a low output impedance, which provides the unregulated analog drive signal 230 to the sensor. The op amp or comparator 262, which has a high input impedance, compares the oscillating reference signal 216 with the unregulated analog drive signal 230 to detect the effect 232 the sensor has on the signal. The op amp or comparator 262 generates an analog sensed signal 234, which represents the effect 232. The gain feedback circuit is coupled to the output of the operational amplifier and the oscillating reference signal 216, in order to adjust the gain from the output to the input of the operational amplifier.

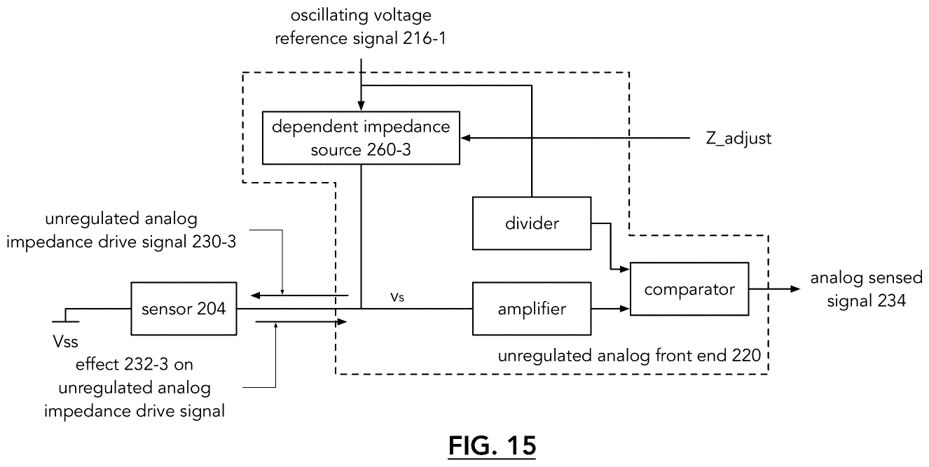

FIG. 20 is a schematic block diagram of another embodiment of an unregulated analog front end (AFE) of a drive sense circuit. In this embodiment, the analog front end 220 includes a dependent drive source 260, a comparator circuit, and a hysteresis circuit. The dependent drive source 260 is a dependent current source, a dependent voltage source, or a dependent impedance source.

A hysteresis circuit helps stabilize the switching nature of the comparator circuit by including a positive feedback loop from the output of the comparator to the input. While a comparator circuit switches, noise is created on the output line; introducing hysteric control, implements switching thresholds for the comparator and helps eliminate undesired switching noise on the comparator output.

The dependent drive source 260 generates the unregulated analog drive signal 230 based on the oscillating reference signal 216. The dependent drive source 260 has a low output impedance, which provides the unregulated analog drive signal 230 to the sensor. The comparator 262, which has a high input impedance, compares the oscillating reference signal 216 with the unregulated analog drive signal 230 to detect the effect 232 the sensor has on the signal. The comparator 262 generates an analog sensed signal 234, which represents the effect 232. The hysteresis circuit is coupled to the output of the comparator 262 and the input of the comparator 262 introducing hysteric control to the AFE.

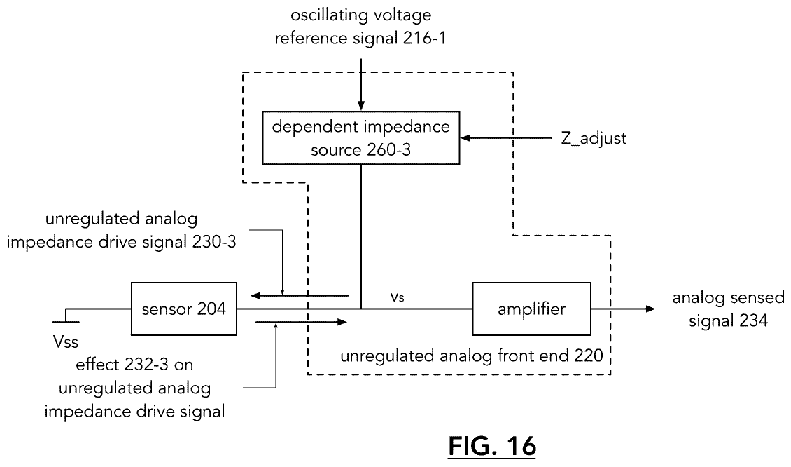

FIG. 21 is a schematic block diagram of another embodiment of an unregulated analog front end (AFE) of a drive sense circuit. In this embodiment, the analog front end 220 includes a dependent drive source 260, and a phase shift comparator, which is known. The phase shift comparator is operable to determine whether two signals are in or out of phase based on the phase angles of said signals. If the two signals are out of phase, the phase shift comparator will determine the extent of which the angles are out of phase. The dependent drive source 260 is a dependent current source, a dependent voltage source, or a dependent impedance source.

The dependent drive source 260 generates the unregulated analog drive signal 230 based on the oscillating reference signal 216. The dependent drive source 260 has a low output impedance, which provides the unregulated analog drive signal 230 to the sensor. The phase shift comparator, which has a high input impedance, compares the phase angle of the oscillating reference signal 216 with the phase angle of the unregulated analog drive signal 230 and generates an analog sensed signal 234 based on the difference.

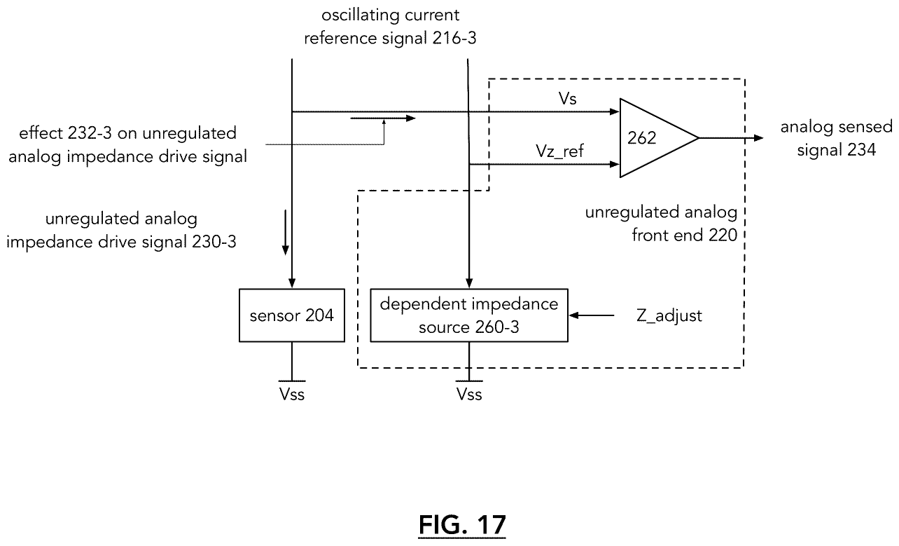

FIG. 22 is a schematic block diagram of another embodiment of an unregulated analog front end (AFE) of a drive sense circuit. In this embodiment, the analog front end 220 includes a dependent drive source 260, and a frequency shift comparator, which is known. A frequency shift comparator functions to compare the frequency at which two separate signals are operating at and output a signal with an operating frequency representing the frequency difference between the two signals.

The dependent drive source 260 generates the unregulated analog drive signal 230 based on the oscillating reference signal 216. The dependent drive source 260 has a low output impedance, which provides the unregulated analog drive signal 230 to the sensor. The frequency shift comparator, which has a high input impedance, compares the frequency that the oscillating reference signal 216 is operating at with the frequency that the unregulated analog drive signal 230 is operating at and generates an analog sensed signal 234 based on the difference.

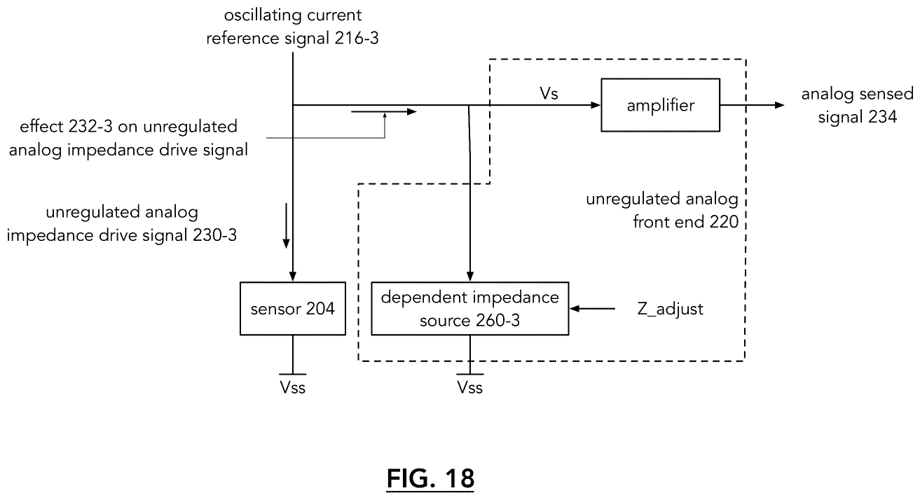

FIG. 23 is a schematic block diagram of another embodiment of an unregulated analog front end (AFE) of a drive sense circuit. In this embodiment, the analog front end 220 includes a dependent drive source 260, and a magnitude comparator. A magnitude comparator is operable to receive two signals with respective magnitudes and output a difference between the two signal magnitudes or determine which of the two signals magnitudes is greater. The dependent drive source 260 is a dependent current source, a dependent voltage source, or a dependent impedance source.

The dependent drive source 260 generates the unregulated analog drive signal 230 based on the oscillating reference signal 216. The dependent drive source 260 has a low output impedance, which provides the unregulated analog drive signal 230 to the sensor. The magnitude comparator, which has a high input impedance, compares the magnitude of the oscillating reference signal 216 with the magnitude of the unregulated analog drive signal 230 and generates an analog sensed signal 234 based on the difference.

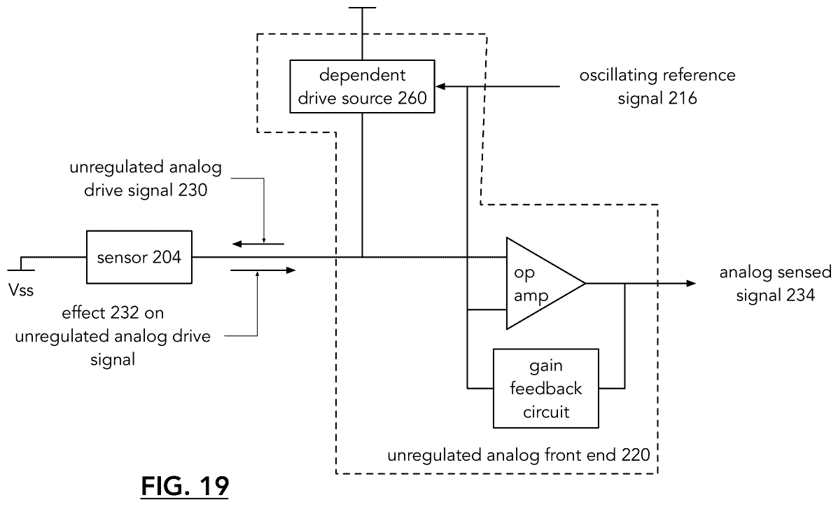

FIG. 24 is a schematic block diagram of another embodiment of an unregulated analog front end (AFE) of a drive sense circuit. In this embodiment, the analog front end 220 includes a dependent drive source 260, a frequency shift comparator, and a phase shift comparator. The dependent drive source 260 is a dependent current source, a dependent voltage source, or a dependent impedance source.

The dependent drive source 260 generates the unregulated analog drive signal 230 based on the oscillating reference signal 216. The dependent drive source 260 has a low output impedance, which provides the unregulated analog drive signal 230 to the sensor. The frequency shift comparator, which has a high input impedance, compares the frequency that the oscillating reference signal 216 is operating at with the frequency that the unregulated analog drive signal 230 is operating at and generates an analog sensed signal 234A at a frequency differing from that of the output of the phase shift comparator, based on the difference.

The phase shift comparator, which has a high input impedance, compares the phase angle of the oscillating reference signal 216 with the phase angle of the unregulated analog drive signal 230 and generates an analog sensed signal 234B at a frequency differing from that of the output of the frequency shift comparator, based on the difference.

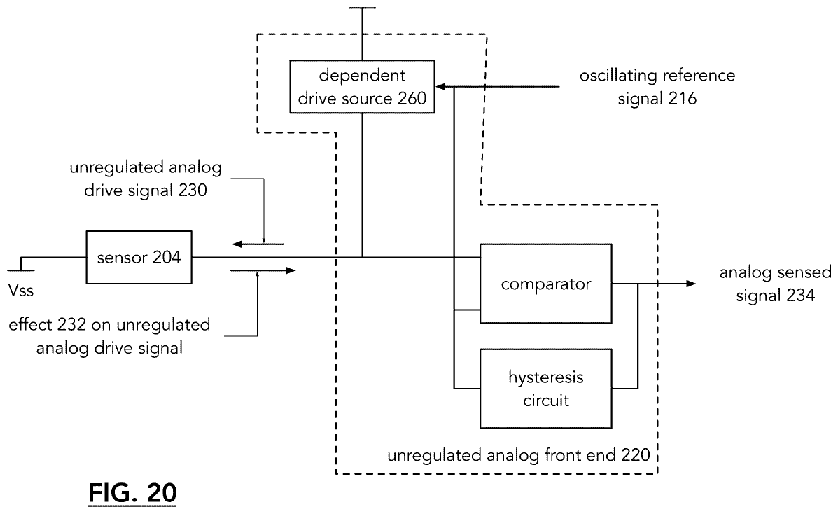

FIG. 25 is a schematic block diagram of another embodiment of an unregulated analog front end (AFE) of a drive sense circuit. In this embodiment, the analog front end 220 includes a dependent drive source 260, a frequency shift comparator and a magnitude comparator. The dependent drive source 260 is a dependent current source, a dependent voltage source, or a dependent impedance source.

The dependent drive source 260 generates the unregulated analog drive signal 230 based on the oscillating reference signal 216. The dependent drive source 260 has a low output impedance, which provides the unregulated analog drive signal 230 to the sensor. The frequency shift comparator, which has a high input impedance, compares the frequency that the oscillating reference signal 216 is operating at with the frequency that the unregulated analog drive signal 230 is operating at and generates an analog sensed signal 234A at a frequency differing from that of the output of the magnitude comparator, based on the difference

The magnitude comparator, which has a high input impedance, compares the magnitude of the oscillating reference signal 216 with the magnitude of the unregulated analog drive signal 230 and generates an analog sensed signal 234C at a frequency differing from that of the output of the frequency shift comparator, based on the difference.

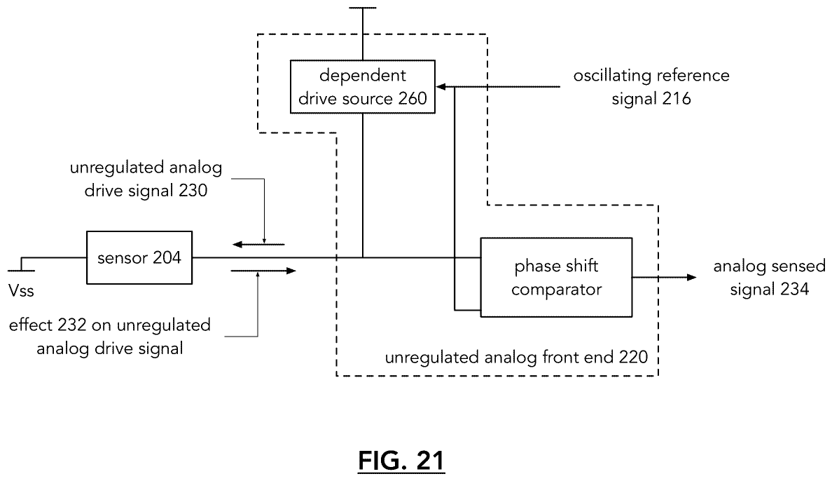

FIG. 26 is a schematic block diagram of another embodiment of an unregulated analog front end (AFE) of a drive sense circuit. In this embodiment, the analog front end 220 includes a dependent drive source 260, a phase shift comparator and a magnitude comparator. The dependent drive source 260 is a dependent current source, a dependent voltage source, or a dependent impedance source.

The dependent drive source 260 generates the unregulated analog drive signal 230 based on the oscillating reference signal 216. The dependent drive source 260 has a low output impedance, which provides the unregulated analog drive signal 230 to the sensor. The phase shift comparator, which has a high input impedance, compares the phase angle of the oscillating reference signal 216 with the phase angle of the unregulated analog drive signal 230 and generates an analog sensed signal 234B at a frequency differing from that of the output of the magnitude comparator, based on the difference.

The magnitude comparator, which has a high input impedance, compares the magnitude of the oscillating reference signal 216 with the magnitude of the unregulated analog drive signal 230 and generates an analog sensed signal 234C at a frequency differing from that of the output of the phase shift comparator, based on the difference.

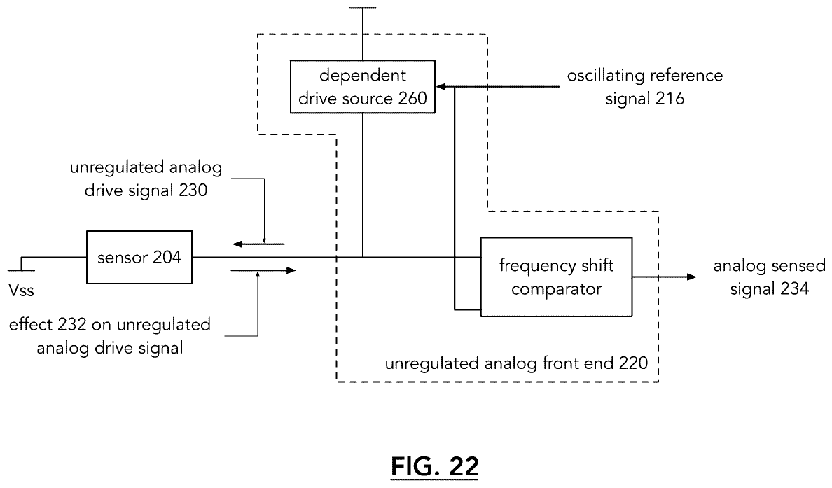

FIG. 27 is a schematic block diagram of another embodiment of an unregulated analog front end (AFE) of a drive sense circuit. In this embodiment, the analog front end 220 includes a dependent drive source 260, a phase shift comparator and a magnitude comparator. The dependent drive source 260 is a dependent current source, a dependent voltage source, or a dependent impedance source.

The dependent drive source 260 generates the unregulated analog drive signal 230 based on the oscillating reference signal 216. The dependent drive source 260 has a low output impedance, which provides the unregulated analog drive signal 230 to the sensor. The phase shift comparator, which has a high input impedance, compares the phase angle of the oscillating reference signal 216 with the phase angle of the unregulated analog drive signal 230 and generates an analog sensed signal 234B at a frequency differing from that of the output of the magnitude comparator and the output of the frequency shift comparator, based on the difference.

The magnitude comparator, which has a high input impedance, compares the magnitude of the oscillating reference signal 216 with the magnitude of the unregulated analog drive signal 230 and generates an analog sensed signal 234C at a frequency differing from that of the output of the phase shift comparator and the output of the frequency shift comparator, based on the difference.

The frequency shift comparator, which has a high input impedance, compares the frequency that the oscillating reference signal 216 is operating at with the frequency that the unregulated analog drive signal 230 is operating at and generates an analog sensed signal 234A at a frequency differing from that of the output of the phase shift comparator and the output of the magnitude comparator, based on the difference.

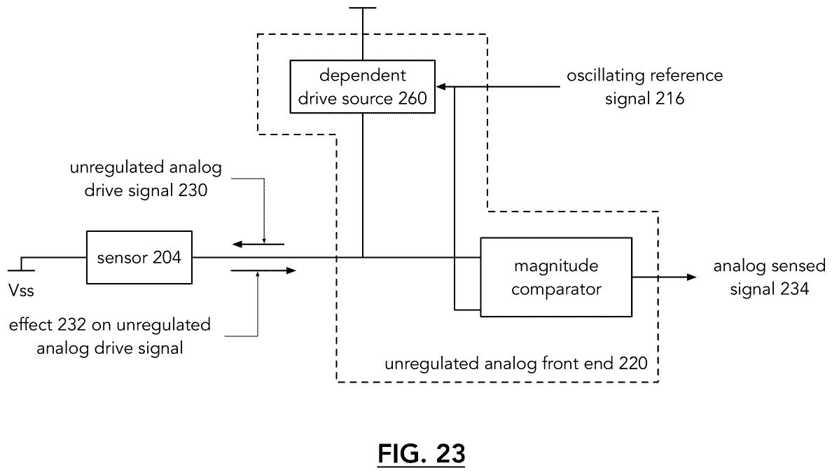

FIG. 28 is a schematic block diagram of another embodiment of an unregulated analog front end (AFE) of a drive sense circuit. In this embodiment, the analog front end 220 includes a dependent drive source 260, a transient suppression circuit and an op amp or comparator 262. The dependent drive source 260 is a dependent current source, a dependent voltage source, or a dependent impedance source.

The dependent drive source 260 generates the unregulated analog drive signal 230 based on the oscillating reference signal 216. The dependent drive source 260 has a low output impedance, which provides the unregulated analog drive signal 230 to the sensor. The transient suppression circuit operates to receive the unregulated analog drive signal 230 and produce a compensation signal to mitigate the effects that noise has on the unregulated analog drive signal 230. For example, the compensation signal will be negligible in comparison to the unregulated analog drive signal when noise is low (e.g., less than −100 dBm). As noise on the unregulated analog drive signal 230 increases, its effect increases to the point where transients are present on the unregulated analog drive signal 230. When the transients are of sufficient size, the compensation signal increases in value.

The comparator or operational amplifier, which has a high input impedance, compares the oscillating reference signal 216 with the unregulated analog drive signal 230 and generates an analog sensed signal 234 based on the difference.

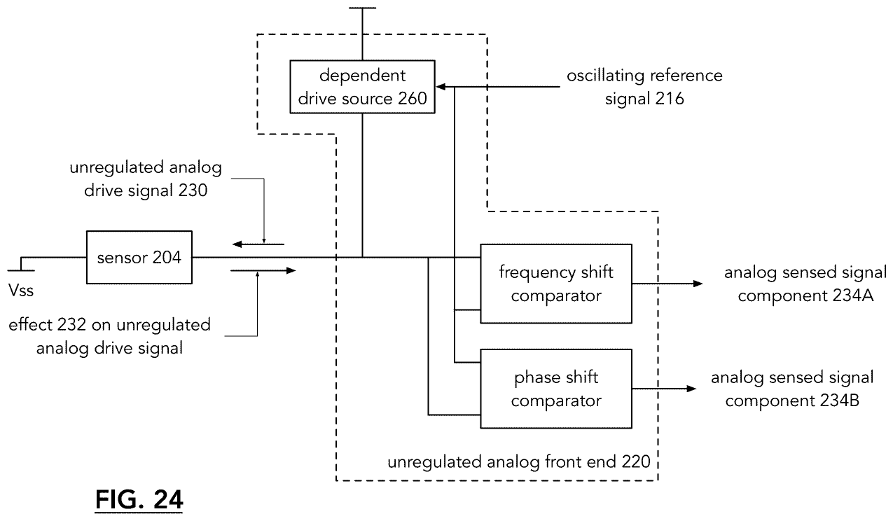

FIG. 29 is a schematic block diagram of another embodiment of an unregulated analog front end (AFE) of a drive sense circuit. In this embodiment, the analog front end 220 includes a dependent sink circuit 270, and an op amp or comparator 262. The dependent sink circuit 270 is a dependent current sink, a dependent voltage sink, or a dependent impedance sink.

The sensor 204 is connected to a positive voltage supply (Vdd, e.g., 0.5 volts to 5 volts) which allows the sensor 204 to sink an unregulated analog sink signal 274 into the dependent sink circuit 270. The sensor sinks the unregulated analog sink signal 274 based on an oscillating reference signal 216 received by the dependent sink circuit 270. The op amp or comparator 262, which has a high input impedance, compares the oscillating reference signal 216 with the unregulated analog sink signal 274 to detect the effect 272 the sensor has on the signal. The op amp or comparator 262 generates an analog sensed signal 234, which represents the effect 272.

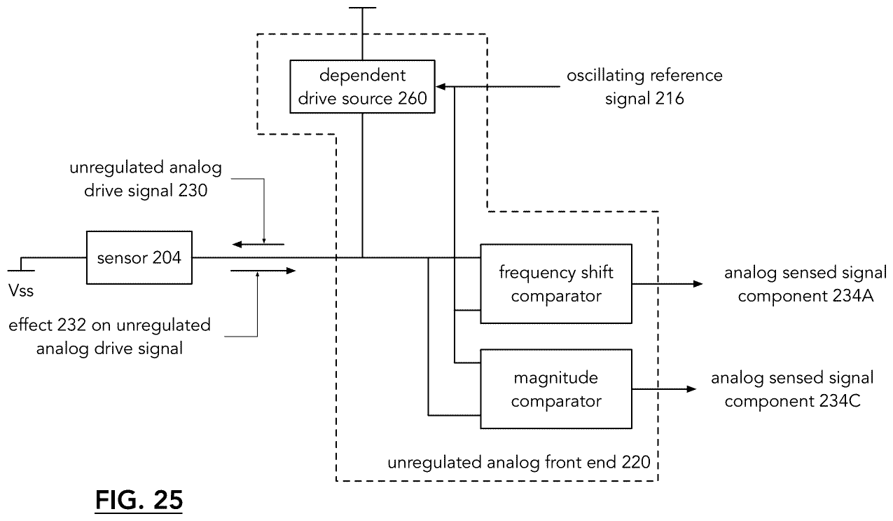

FIG. 30 is a schematic block diagram of another embodiment of an unregulated analog front end (AFE) of a drive sense circuit. In this embodiment, the analog front end 220 includes a dependent current sink circuit 270-1, and an op amp or comparator 262. The sensor 204 sinks an unregulated analog current sink signal 274-1 to a dependent current sink circuit 270-1 based on an oscillating voltage reference signal 216-1.

Based on the impedance (Zs) of the sensor 204 and the current sink signal 274-1, a sensor voltage (Vs) is created, which includes the effect 272-1 the sensor has on the unregulated analog current sink signal 272-1 (Vs=I*Zs). The operational amplifier or comparator generates the analog sensed signal 234 as a difference between the oscillating voltage reference signal 216-1 sensor voltage (Vs). As such, in this embodiment, the AFE 220 is configured to sink a current (I) based on a Voltage (V) to sense impedance of the sensor, where Z=V/I.

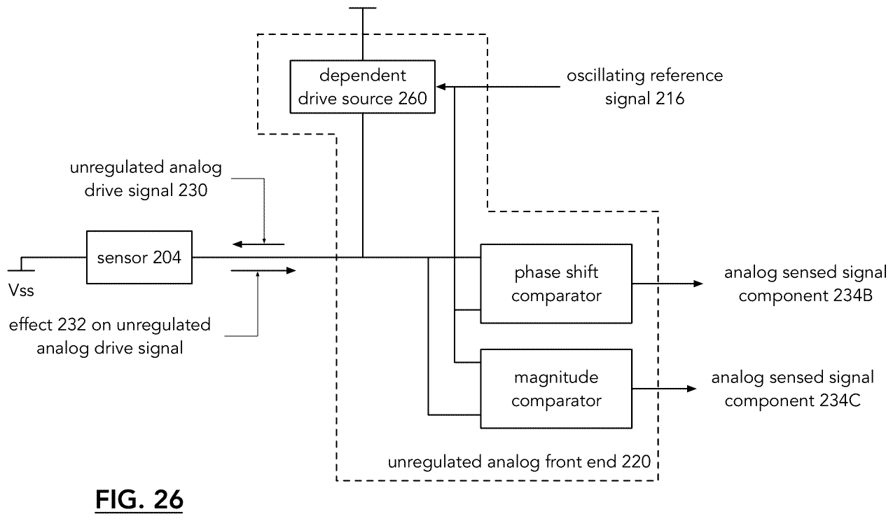

FIG. 31 is a schematic block diagram of another embodiment of an unregulated analog front end (AFE) of a drive sense circuit. In this embodiment, the analog front end 220 includes a dependent current sink circuit 270-1, and a non-inverting unity gain operational amplifier. The sensor 204 sinks an unregulated analog current sink signal 274-1 to a dependent current sink circuit 270-1 based on an oscillating voltage reference signal 216-1.

Based on the impedance (Zs) of the sensor 204 and the current sink signal 274-1, a sensor voltage (Vs) is created, which includes the effect 272-1 the sensor has on the unregulated analog current sink signal 272-1 (Vs=I*Zs). The non-inverting unity gain operational amplifier outputs the sensor voltage (Vs) as the analog sensed signal 234. As such, in this embodiment, the AFE 220 is configured to sink a current (I) based on a Voltage (V) to sense impedance of the sensor, where Z=V/I.

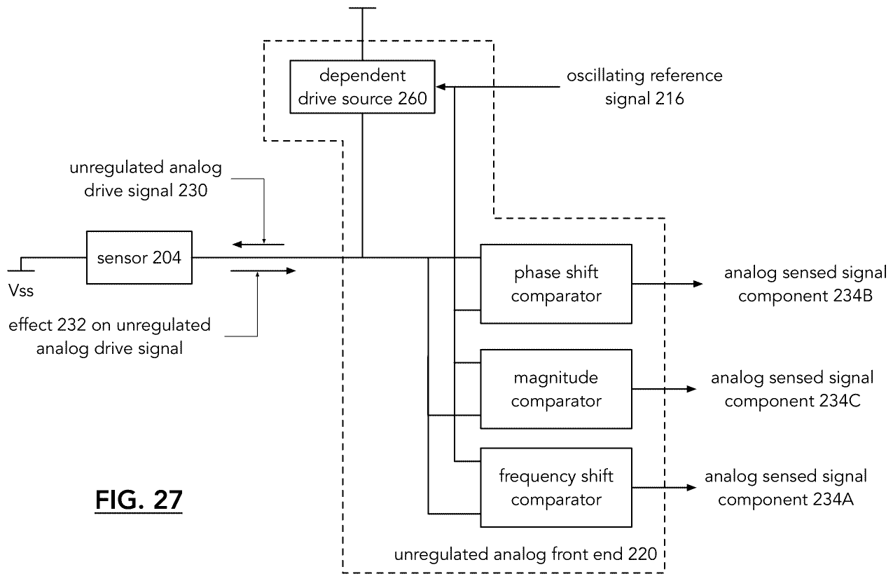

FIG. 32 is a schematic block diagram of another embodiment of an unregulated analog front end (AFE) of a drive sense circuit. In this embodiment, the analog front end 220 includes a dependent current sink circuit 270-1, and an operational amplifier or comparator 262. The sensor 204 sinks an unregulated analog current sink signal 274-1 to a dependent current sink circuit 270-1 based on an oscillating impedance reference signal 216-1.

Based on the impedance (Zs) of the sensor 204 and the current sink signal 274-1, a sensor voltage (Vs) is created, which includes the effect 272-1 the sensor has on the unregulated analog current sink signal 272-1. The operational amplifier or comparator generates the analog sensed signal 234 as a difference between the oscillating impedance reference signal 216-2 and the sensor voltage (Vs). As such, in this embodiment, the AFE 220 is configured to sink a current (I) based on an impedance (Z) to sense voltage of the sensor, where V=Z*I.

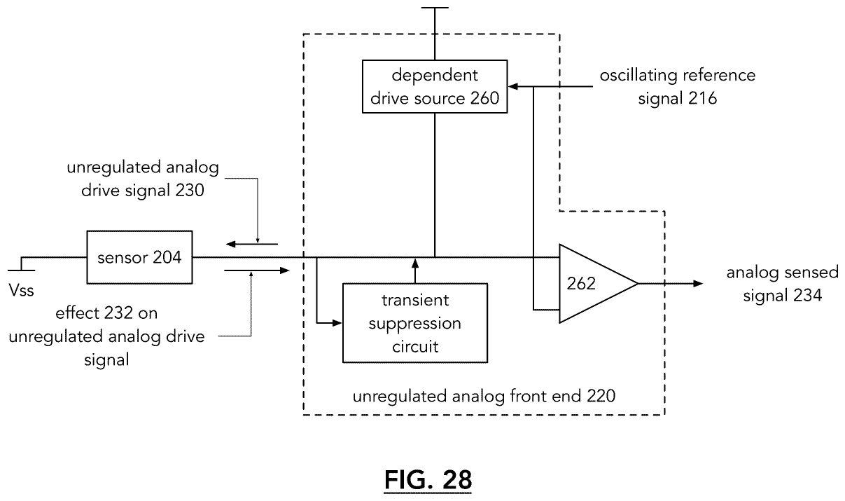

FIG. 33 is a schematic block diagram of another embodiment of an unregulated analog front end (AFE) of a drive sense circuit. In this embodiment, the analog front end 220 includes a dependent current sink circuit 270-1, and a non-inverting unity gain operational amplifier. The sensor 204 sinks an unregulated analog current sink signal 274-1 to a dependent current sink circuit 270-1 based on an oscillating impedance reference signal 216-2.

Based on the impedance (Zs) of the sensor 204 and the current sink signal 274-1, a sensor voltage (Vs) is created, which includes the effect 272-1 the sensor has on the unregulated analog current sink signal 272-1. The non-inverting unity gain operational amplifier outputs the sensor voltage (Vs) as the analog sensed signal 234. As such, in this embodiment, the AFE 220 is configured to sink a current (I) based on an impedance (Z) to sense voltage of the sensor, where V=I*Z.

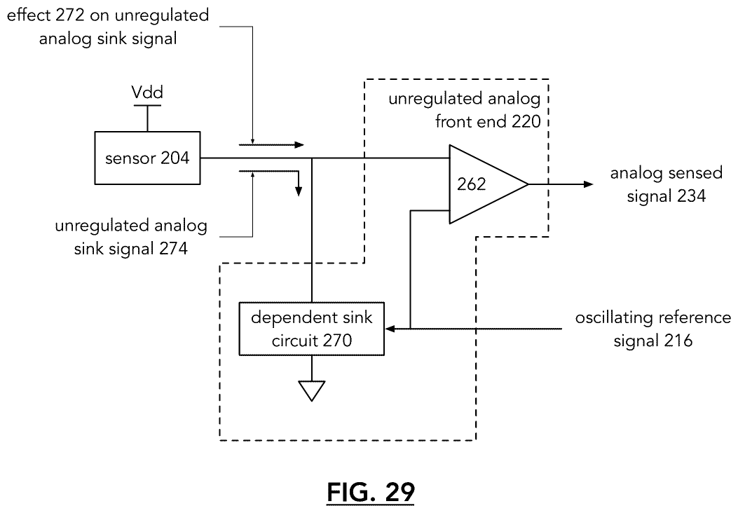

FIG. 34 is a schematic block diagram of another embodiment of an unregulated analog front end (AFE) of a drive sense circuit. In this embodiment, the analog front end 220 includes a dependent voltage sink circuit 270-2 a voltage to current converter 263 and a trans-impedance amplifier 264. The sensor 204 sinks an unregulated analog voltage sink signal 274-2 to a dependent voltage sink circuit 270-2 based on an oscillating current reference signal 216-3.

Based on the impedance (Zs) of the sensor 204 and the voltage sink signal 274-2, a sensor current (Is) is created, which includes the effect 272-2 the sensor has on the unregulated analog current sink signal (Is=V*Zs). The trans-impedance amplifier 264 generates the analog sensed signal 234 as a difference between the oscillating current reference signal 216-3 and the sensor current (Is). As such, in this embodiment, the AFE 220 is configured to sink a voltage (V) based on a current (I) to sense impedance of the sensor, where Z=V/I.

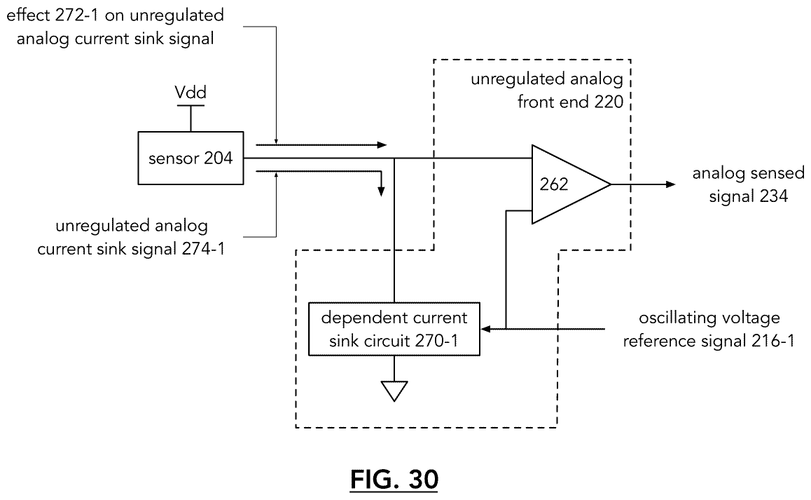

FIG. 35 is a schematic block diagram of another embodiment of an unregulated analog front end (AFE) of a drive sense circuit. In this embodiment, the analog front end 220 includes a dependent voltage sink circuit 270-2, a voltage to current converter 263 and a trans impedance non-inverting unity gain operational amplifier. The sensor 204 sinks an unregulated analog voltage sink signal 274-2 to a dependent voltage sink circuit 270-2 based on an oscillating impedance reference signal 216-2.

Based on the impedance (Zs) of the sensor 204 and the voltage sink signal 274-2, a sensor current (Is) is created, which includes the effect 272-2 the sensor has on the unregulated analog current sink signal (Is=V*Zs). The trans impedance non-inverting unity gain operational amplifier outputs the sensor current (Is) as the analog sensed signal 234 as a difference between the oscillating impedance reference signal 216-2 and the sensor current (Is). As such, in this embodiment, the AFE 220 is configured to sink a voltage (V) based on a current (I) to sense impedance (Z) of the sensor, where Z=V/I.

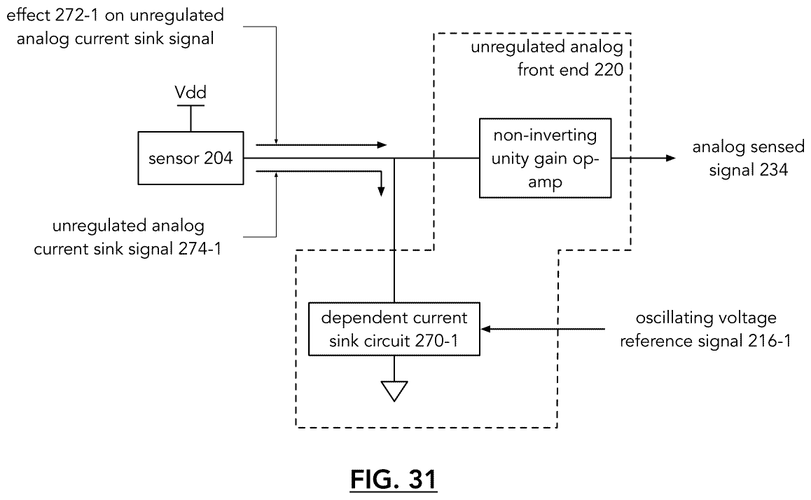

FIG. 36 is a schematic block diagram of another embodiment of an unregulated analog front end (AFE) of a drive sense circuit. In this embodiment, the analog front end 220 includes a dependent voltage sink circuit 270-2, a voltage to current converter 263 and a trans-impedance amplifier. The sensor 204 sinks an unregulated analog voltage sink signal 274-2 to a dependent voltage sink circuit 270-2 based on an oscillating impedance reference signal 216-2.

Based on the impedance (Zs) of the sensor 204 and the voltage sink signal 274-2, a sensor current (Is) is created, which includes the effect 272-2 the sensor has on the unregulated analog current sink signal). The trans-impedance amplifier outputs the sensor current (Is) as the analog sensed signal 234 as a difference between the oscillating impedance reference signal 216-2 converted from a voltage to a current by the voltage to current converter and the sensor current (Is). As such, in this embodiment, the AFE 220 is configured to sink a voltage (V) based on an impedance (Z) to sense current (I) of the sensor, where I=V/Z.

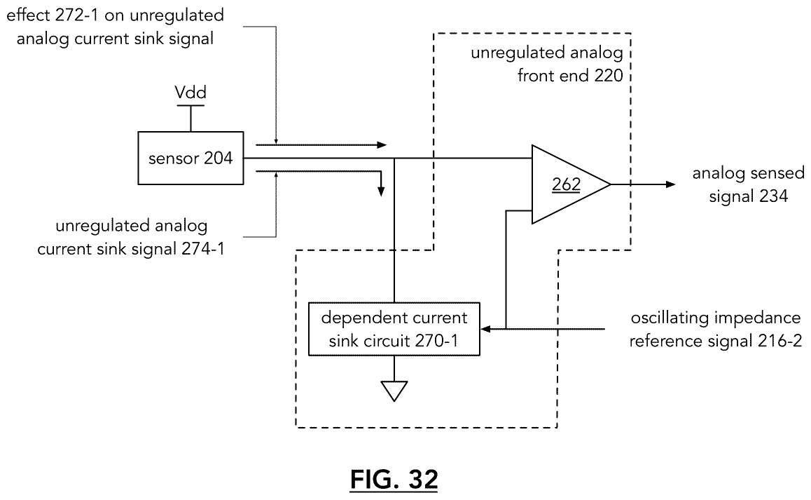

FIG. 37 is a schematic block diagram of another embodiment of an unregulated analog front end (AFE) of a drive sense circuit. In this embodiment, the analog front end 220 includes a dependent voltage sink circuit 270-2 and a trans-impedance non-inverting unity gain operational amplifier. The sensor 204 sinks an unregulated analog voltage sink signal 274-2 to a dependent voltage sink circuit 270-2 based on an oscillating impedance reference signal 216-2.

Based on the impedance (Zs) of the sensor 204 and the voltage sink signal 274-2, a sensor current (Is) is created, which includes the effect 272-2 the sensor has on the unregulated analog current sink signal). The trans impedance non-inverting unity gain operational amplifier outputs the sensor current (Is) as the analog sensed signal 234. As such, in this embodiment, the AFE 220 is configured to sink a voltage (V) based on an impedance (Z) to sense current (I) through the sensor, where I=V/Z.

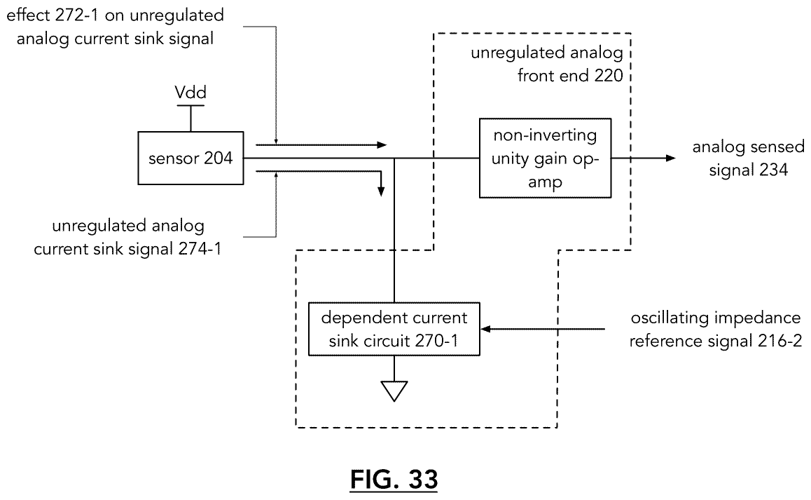

FIG. 38 is a schematic block diagram of another embodiment of an unregulated analog front end (AFE) of a drive sense circuit. In this embodiment, the analog front end 220 includes a dependent impedance sink circuit 270-2, an amplifier 262, a divider, and a comparator. The sensor 204 sinks an unregulated analog impedance sink signal 274-3 to a dependent impedance sink circuit 270-3 based on an oscillating voltage reference signal 216-1.

In this embodiment, the unregulated analog impedance sink signal 274-3 is divided between the sensor 204 and the dependent impedance sink circuit 270-3 (e.g., a variable impedance circuit). The divided voltage of the unregulated analog impedance sink signal 274-3 via the sensor and the impedance sink circuit 270-3 is compared with the divided voltage of the unregulated analog impedance sink signal 274-3 produced by the divider (e.g., a resistive divider). Based on this comparison, the comparator outputs the analog sensed signal 234.

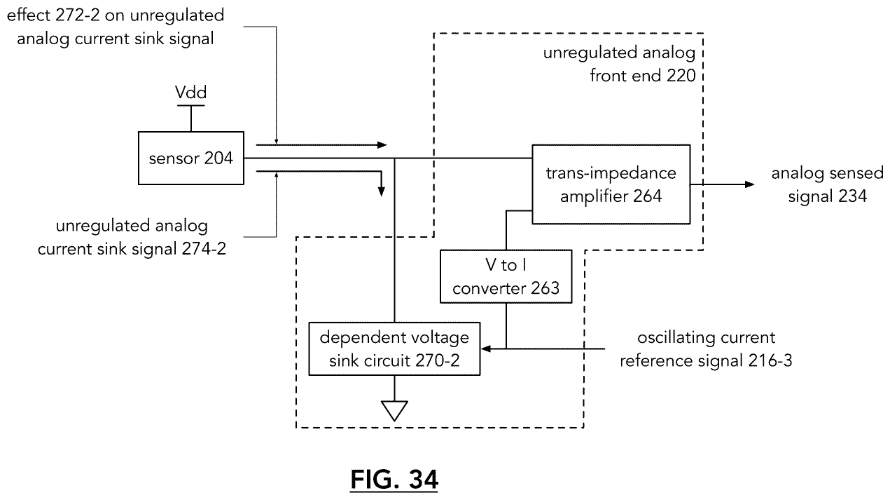

FIG. 39 is a schematic block diagram of another embodiment of an unregulated analog front end (AFE) of a drive sense circuit. In this embodiment, the analog front end 220 includes a dependent impedance sink circuit 270-3 and an amplifier or comparator 262. The sensor 204 sinks an unregulated analog impedance sink signal 274-3 to a dependent impedance sink circuit 270-3 based on an oscillating voltage reference signal 216-1.

Based on the impedance (Zs) of the sensor 204 and the impedance sink signal 274-3, a sensor voltage is created, which includes the effect 272-3 the sensor has on the unregulated analog impedance sink signal. The amplifier outputs the analog sensed signal 234.

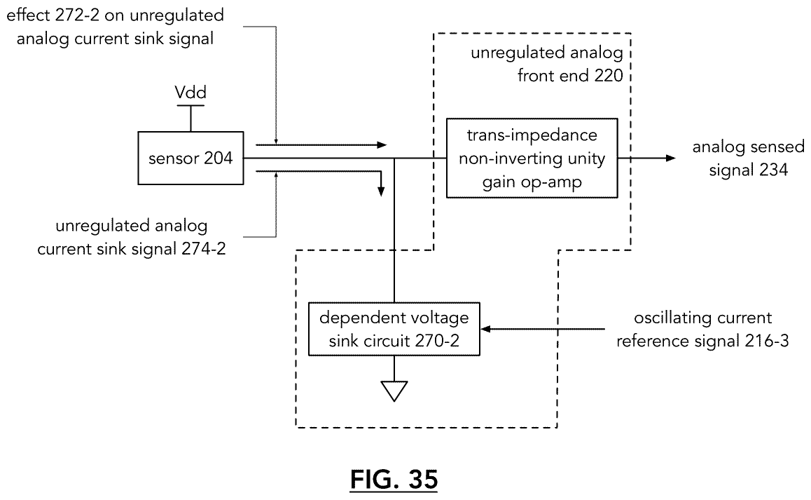

FIG. 40 is a schematic block diagram of another embodiment of an unregulated analog front end (AFE) of a drive sense circuit. In this embodiment, the analog front end 220 includes a dependent impedance sink circuit 270-3 and an amplifier or comparator 262. The sensor 204 sinks an oscillating current reference signal 216-3. The dependent impedance sink 270-3 also sinks the oscillating current reference signal 216-3.

The voltage of sensor is compared with the voltage of the dependent impedance sink 270-3, where the voltage of the sensor includes the effect on the drive signal. The amplifier or comparator 262 outputs the difference between the voltages as the analog sensed signal 234.

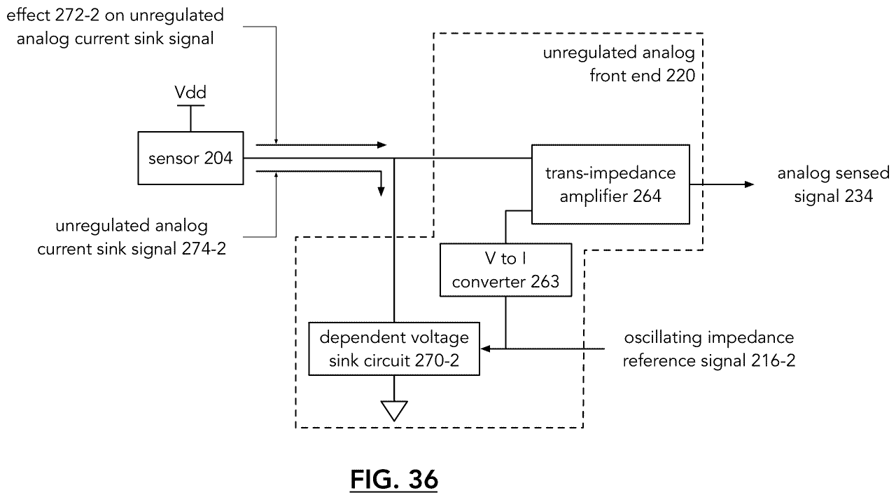

FIG. 41 is a schematic block diagram of another embodiment of an unregulated analog front end (AFE) of a drive sense circuit. In this embodiment, the analog front end 220 includes a dependent impedance sink circuit 270-3 and an amplifier or comparator 262. The parallel combination of the dependent impedance sink circuit and the sensor 204 sinks the oscillating current reference signal 216-3.

The voltage of the parallel combination of the dependent impedance sink circuit and the sensor 204 (Vs) is amplified (e.g., 1× to 10×) by the amplifier or comparator 262 to produce the analog sensed signal 234. In this embodiment, the impedance of the sensor is determined based on V=Z*I, where Z is the parallel combination of the sensor and the impedance reference. Since the impedance of the impedance reference is known, V is known, and I is known, the impedance of sensor is calculable.

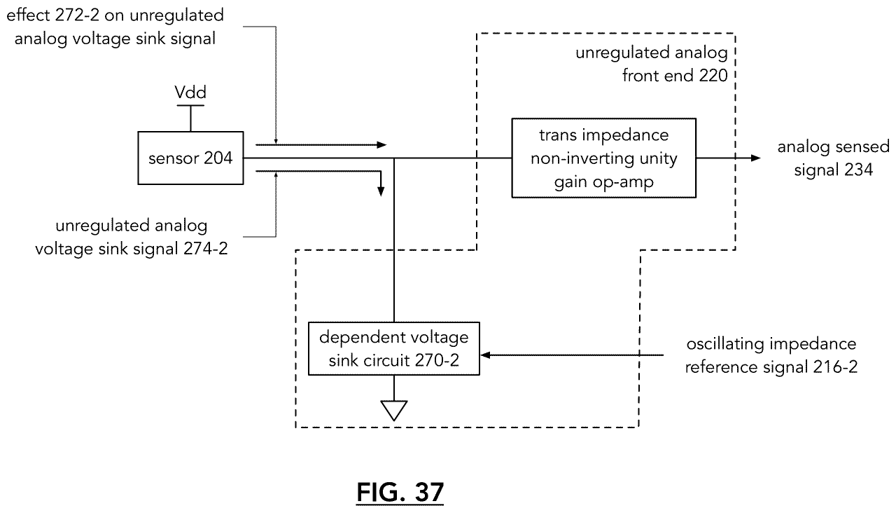

FIG. 42 is a schematic block diagram of an embodiment of a drive sense circuit 208 that includes a regulated analog front end 286, an analog to digital converter (ADC) 222, a digital filter circuit 224, and a data processing unit 226. The regulated analog front end 220 receives an oscillating reference signal 216 from the oscillating reference signal generator 214 and generates therefrom a regulated analog drive signal 280.

The regulated analog front end 286 provides the regulated analog drive signal 280 to the sensor 204 and senses, via the same connection, the effect 282 the sensor has on the drive signal 280 to produce an analog sensed signal 284. As discussed with reference to subsequent figures, there is a plurality of embodiments of the regulated analog drive signal 280 and a variety of effects on it, which include, but are not limited to, an effect on the AC magnitude of the drive signal, an effect on the DC magnitude of the drive signal, an effect on the phase of the drive signal, and an effect on the frequency of the drive signal.

The ADC converts the analog sensed signal 284 into a digital sensed signal 236. The digital filter circuit 224 digitally filters the digital sensed signal 236 to produce a filtered digital sensed signal 238. The data processing unit 226 generates a digital value 240 that represents a sensed characteristic of the sensor based on the filtered digital sensed signal 238. The characteristics include one or more of inductance, detected light, capacitance, reactance, resistance, phase response, frequency response, impedance, an environmental condition (e.g., temperature, moisture, humidity, etc.), and a physical condition (e.g., pressure, heat, expansion, contraction, etc.). Note that the digital filter circuit 224 and the data processing unit 226 will be described in greater detail with reference to one or more subsequent figures.

FIG. 43 is a schematic block diagram of another embodiment of a regulated analog front end 286 of a drive sense circuit. In this embodiment, the analog front end 286 includes a dependent drive source 260 and an operational amplifier (op amp) or comparator 262. The dependent drive source 260 is a dependent current source, a dependent voltage source, or a dependent impedance source; each of which will be discussed in greater detail with reference to one or more subsequent figures.

The dependent drive source 260 generates the regulated analog drive signal 280 based on the oscillating reference signal 216. The dependent drive source 260 has a low output impedance, which provides the regulated analog drive signal 280 to the sensor. Note that the analog drive signal 230 includes the “regulated” in its name. As used herein, regulated is in reference to the op amp or comparator being closed loop with reference to generating the analog drive signal 280 as compared to the open loop as shown in FIG. 4.

The op amp or comparator 262, which has a high input impedance, compares the oscillating reference signal 216 with the unregulated analog drive signal 282 to detect the effect 232 the sensor has on the signal. The op amp or comparator 262 generates an analog sensed signal 234, which represents the effect 282.

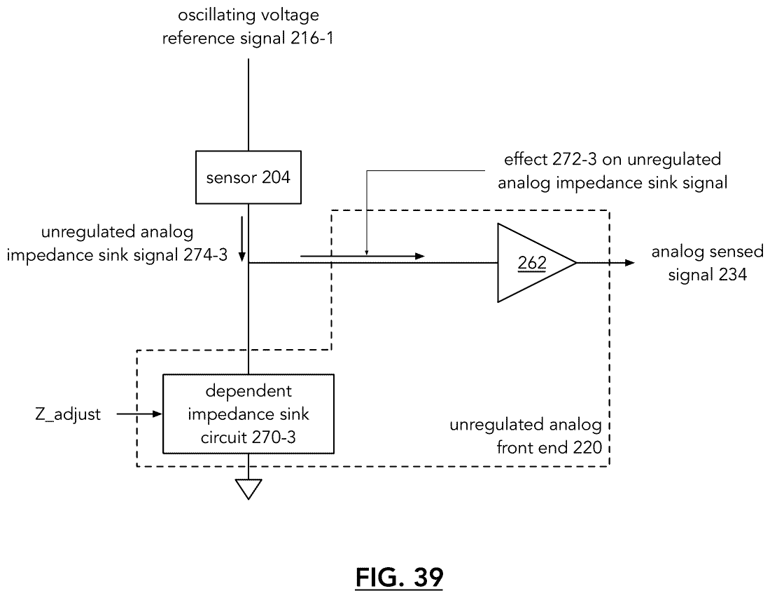

FIG. 44 is a schematic block diagram of another embodiment of a regulated analog front end (AFE) of a drive sense circuit. In this embodiment, the analog front end includes a dependent drive source 260, a feedback circuit, an operational amplifier or comparator 262 and a phase shift comparator.

The dependent drive source 260 generates the regulated analog drive signal 280 based on the output of the feedback circuit. The dependent drive source 260 has a low output impedance, which provides the unregulated analog drive signal 280 to the sensor 204. The operational amplifier or comparator 262 which has a high input impedance, compares an oscillating reference signal 216 with the regulated analog drive signal 280 to detect the effect 282 on the regulated analog drive signal. The operational amplifier generates an analog sensed signal 234 including two different components. An analog sense signal magnitude component 234C which is fed back into the feedback circuit in order to provide a closed loop feedback system.

The analog sense signal magnitude component 234C functions to regulate the regulated analog drive signal 280 via the dependent drive source 260. The phase shift comparator, which has a high input impedance, compares the phase angle of the oscillating reference signal 216 with the phase angle of the analog sensed signal 234 to generate an analog sensed signal phase component 234B based on the difference.

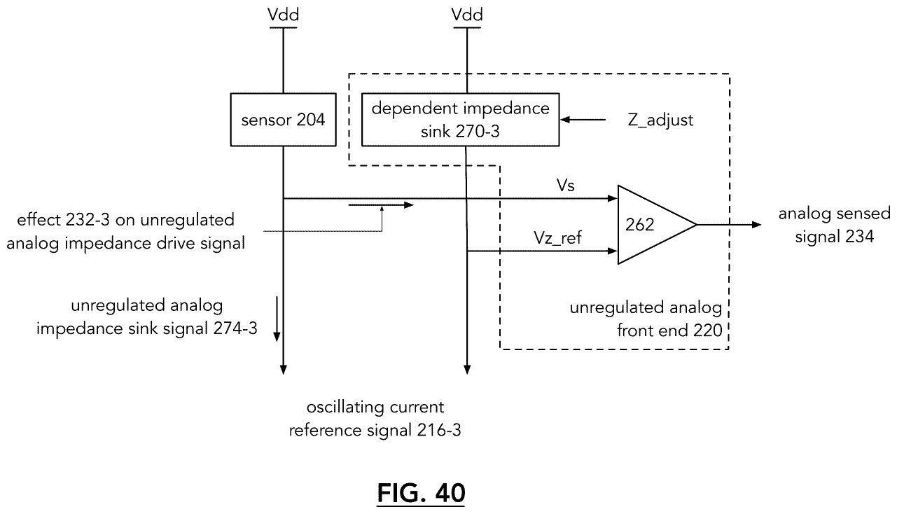

FIG. 45 is a schematic block diagram of another embodiment of a regulated analog front end (AFE) of a drive sense circuit. In this embodiment, the analog front end includes a dependent drive source 260, a feedback circuit, an operational amplifier or comparator 262 and a frequency shift comparator.

The dependent drive source 260 generates the regulated analog drive signal 280 based on the output of the feedback circuit. The dependent drive source 260 has a low output impedance, which provides the unregulated analog drive signal 280 to the sensor 204. The operational amplifier or comparator 262 which has a high input impedance, compares an oscillating reference signal 216 with the regulated analog drive signal 280 to detect the effect 282 on the regulated analog drive signal. The operational amplifier generates an analog sensed signal 234 including two different components. An analog sense signal magnitude component 234C which is fed back into the feedback circuit in order to provide a closed loop feedback system.

The analog sense signal magnitude component 234C functions to regulate the regulated analog drive signal 280 via the dependent drive source 260. The frequency shift comparator, which has a high input impedance, compares the frequency that the oscillating reference signal 216 is operating at with the frequency that the analog sensed signal 234 is operating at and generates an analog sensed signal frequency component 234A based on the difference.

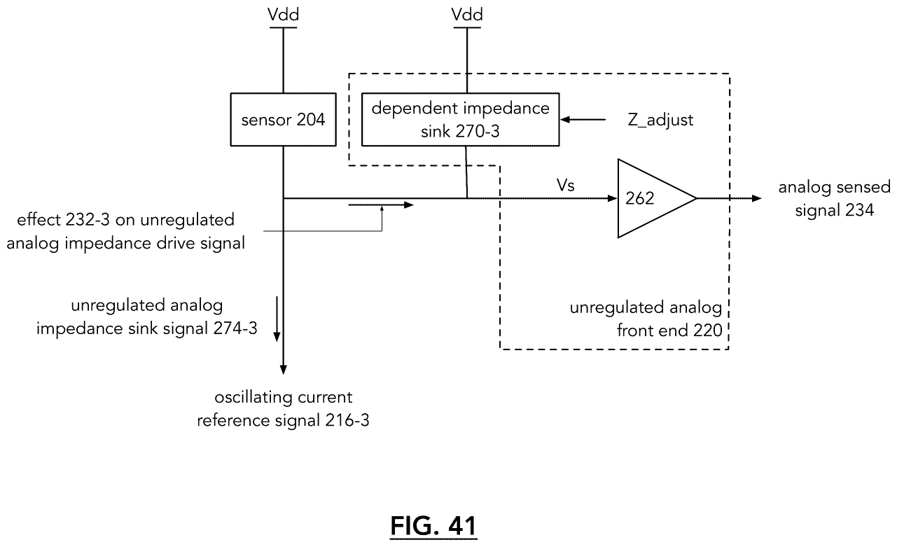

FIG. 46 is a schematic block diagram of another embodiment of a regulated analog front end (AFE) of a drive sense circuit. In this embodiment, the analog front end includes a dependent drive source 260, a feedback circuit, an operational amplifier or comparator 262 a frequency shift comparator, and a phase shift comparator.

The dependent drive source 260 generates the regulated analog drive signal 280 based on the output of the feedback circuit. The dependent drive source 260 has a low output impedance, which provides the unregulated analog drive signal 280 to the sensor 204. The operational amplifier or comparator 262 which has a high input impedance, compares an oscillating reference signal 216 with the regulated analog drive signal 280 to detect the effect 282 on the regulated analog drive signal. The operational amplifier generates an analog sensed signal 234 including three different components. An analog sense signal magnitude component 234C which is fed back into the feedback circuit in order to provide a closed loop feedback system.

The analog sense signal magnitude component 234C functions to regulate the regulated analog drive signal 280 via the dependent drive source 260. The frequency shift comparator, which has a high input impedance, compares the frequency that the oscillating reference signal 216 is operating at with the frequency that the analog sensed signal 234 is operating at and generates an analog sensed signal frequency component 234A based on the difference. The phase shift comparator, which has a high input impedance, compares the phase angle of the oscillating reference signal 216 with the phase angle of the analog sensed signal 234 to generate an analog sensed signal phase component 234B based on the difference.

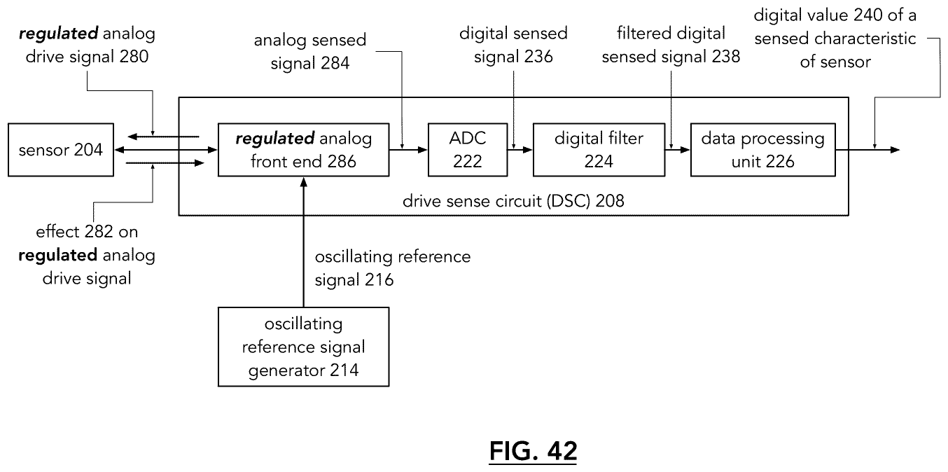

FIG. 47 is a schematic block diagram of another embodiment of a regulated analog front end (AFE) of a drive sense circuit. In this embodiment, the analog front end includes dependent sink circuit 270, a feedback circuit 80, and a comparator or operational amplifier 262. The dependent sink circuit 270 is a dependent current sink, a dependent voltage sink, or a dependent impedance sink.

The sensor 204 is connected to positive voltage supply (Vdd) which allows the sensor 204 to sink a regulated analog sink signal 290 into the dependent sink circuit 270. The operational amplifier or comparator 262, which has a high input impedance, compares an oscillating reference signal 216 with the regulated analog sink signal 290 to detect the effect 288 that the sensor has on the regulated analog sink signal. The operational amplifier or comparator generates an analog sensed signal 234 which represents the effect 272 and provides the analog sensed signal 234 to the feedback circuit to provide a closed loop feedback system.

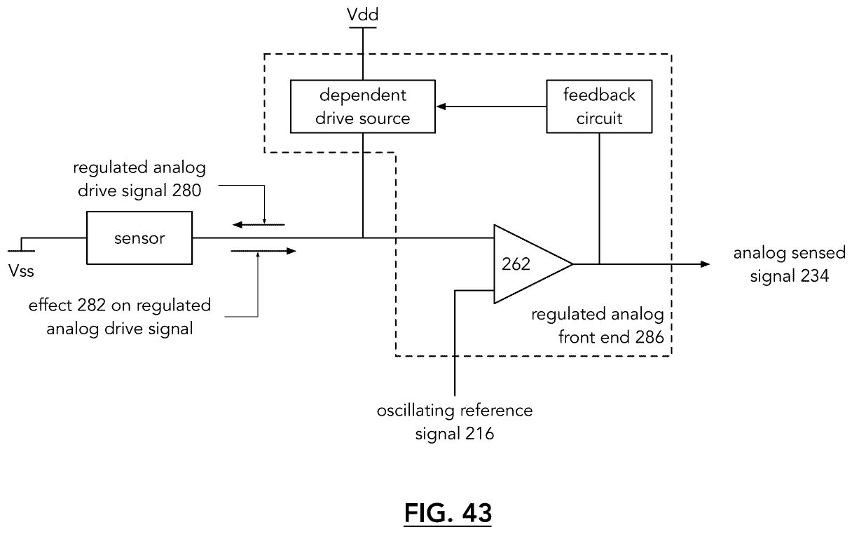

FIG. 48 is a schematic block diagram of another embodiment of a regulated analog front end of a drive sense circuit. In this embodiment, the analog front end includes a dependent current sink circuit 270-1, a feedback circuit and an operational amplifier or comparator 262. The sensor 204 sinks a regulated analog current sink signal 290-1 into the dependent current sink circuit 270-1.

Based on the impedance of sensor 204 and the current sink signal 290-1, a sensor voltage is created (Vs), which represents the effect 288-1 the sensor has on the regulated analog current sink signal. The operational amplifier or comparator 262 generates the analog sensed signal 234 as a difference between the oscillating voltage reference signal 216-1 and the sensor voltage (Vs). As such, in this embodiment, the AFE is configured to sink a current (I) based on a voltage (V) to sense the impedance of the sensor, where Z=V/I.

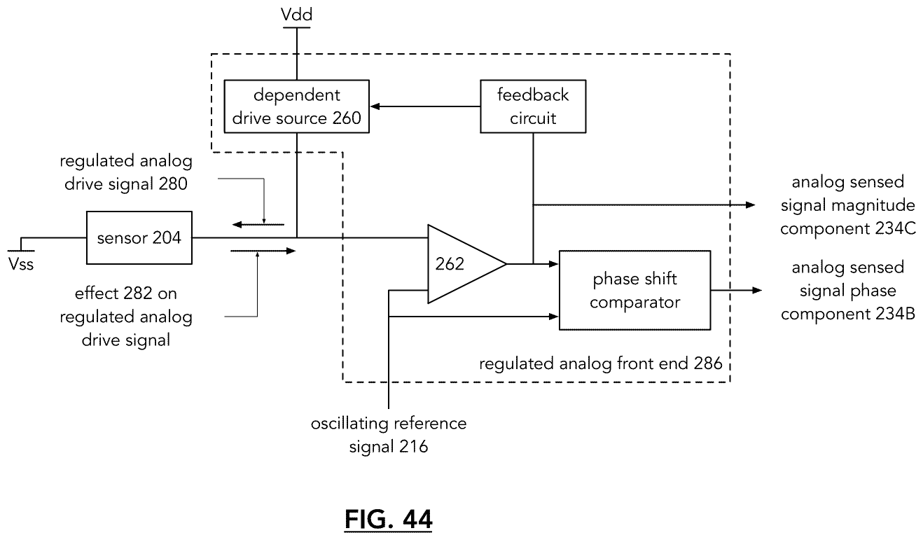

FIG. 49 is a schematic block diagram of another embodiment of a regulated analog front end of a drive sense circuit. In this embodiment, the analog front end includes a dependent current sink circuit 270-1, a feedback circuit and an operational amplifier or comparator 262. The sensor 204 sinks a regulated analog current sink signal 290-1 into the dependent current sink circuit 270-1.

Based on the impedance of sensor 204 and the current sink signal 290-1, a sensor voltage is created (Vs), which represents the effect 288-1 the sensor has on the regulated analog current sink signal. The operational amplifier or comparator 262 generates the analog sensed signal 234 as a difference between the oscillating impedance reference signal 216-1 and the sensor voltage (Vs). As such, in this embodiment, the AFE is configured to sink a current (I) based on an impedance (Z) to sense the voltage across the sensor, where V=I*Z.

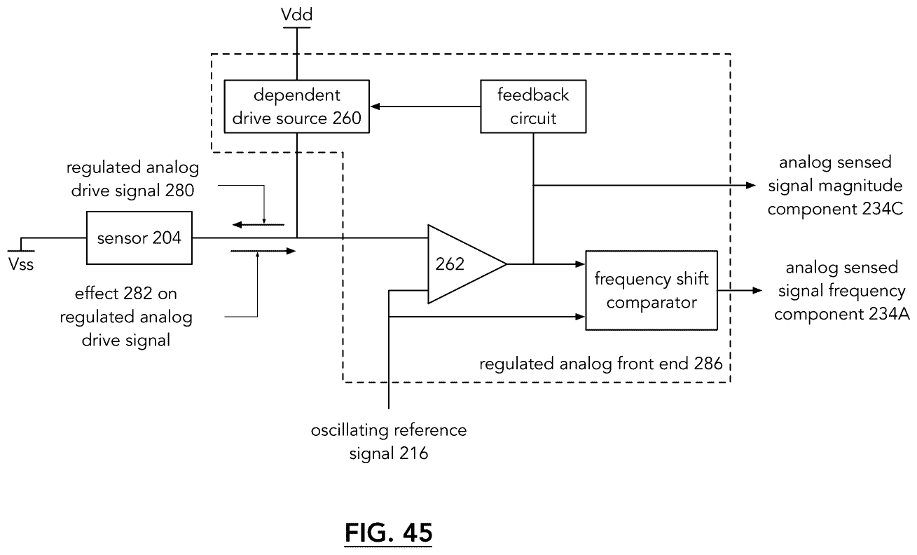

FIG. 50 is a schematic block diagram of another embodiment of a regulated analog front end of a drive sense circuit. In this embodiment, the analog front end includes a dependent voltage sink circuit 270-2, a feedback circuit and an operational amplifier or comparator 262. The sensor 204 sinks a regulated analog voltage sink signal 290-2 into the dependent voltage sink circuit 270-2.

Based on the impedance of sensor 204 and the voltage sink signal 290-2, a sensor current is created (Is), which represents the effect 288-2 the sensor has on the regulated analog voltage sink signal. The operational amplifier or comparator 262 generates the analog sensed signal 234 as a difference between the oscillating current reference signal 216-3 and the sensor current (Is). As such, in this embodiment, the AFE is configured to sink a voltage (V) based on a current (I) to sense the impedance of the sensor, where Z=V/I.

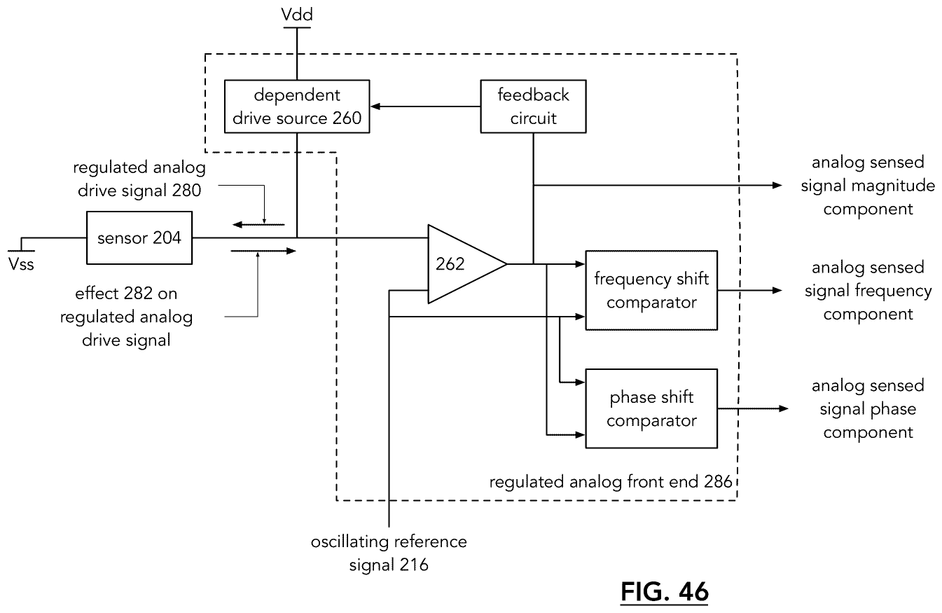

FIG. 51 is a schematic block diagram of another embodiment of a regulated analog front end of a drive sense circuit. In this embodiment, the analog front end includes a dependent voltage sink circuit 270-2, a feedback circuit and an operational amplifier or comparator 262. The sensor 204 sinks a regulated analog voltage sink signal 290-2 into the dependent voltage sink circuit 270-2.

Based on the impedance of sensor 204 and the voltage sink signal 290-2, a sensor current is created (Is), which represents the effect 288-2 the sensor has on the regulated analog voltage sink signal. The operational amplifier or comparator 262 generates the analog sensed signal 234 as a difference between the oscillating impedance reference signal 216-2 and the sensor current (Is). As such, in this embodiment, the AFE is configured to sink a voltage (V) based on an impedance (Z) to sense the current through the sensor, where I=V/Z.

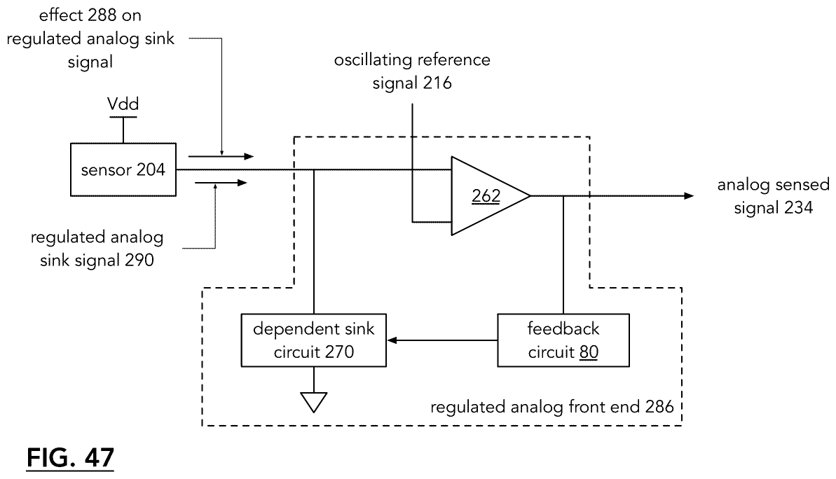

FIG. 52 is a schematic block diagram of another embodiment of a regulated analog front end of a drive sense circuit. In this embodiment, the analog front end includes a dependent impedance sink circuit 270-3, a feedback circuit and an operational amplifier or comparator 262. The sensor 204 sinks a regulated analog impedance sink signal 290-3 into the dependent impedance sink circuit 270-3.

Based on the impedance of sensor 204 and the impedance sink signal 290-3, a sensor current is created, which represents the effect 288-2 the sensor has on the regulated analog voltage sink signal. The operational amplifier or comparator 262 generates the analog sensed signal 234 as a difference between the oscillating voltage reference signal 216-1 converted to a current by the voltage to current converter and the sensor current. As such, in this embodiment, the AFE is configured to sink an impedance (Z) based on a voltage (V) to sense the current through the sensor, where I=V/Z.

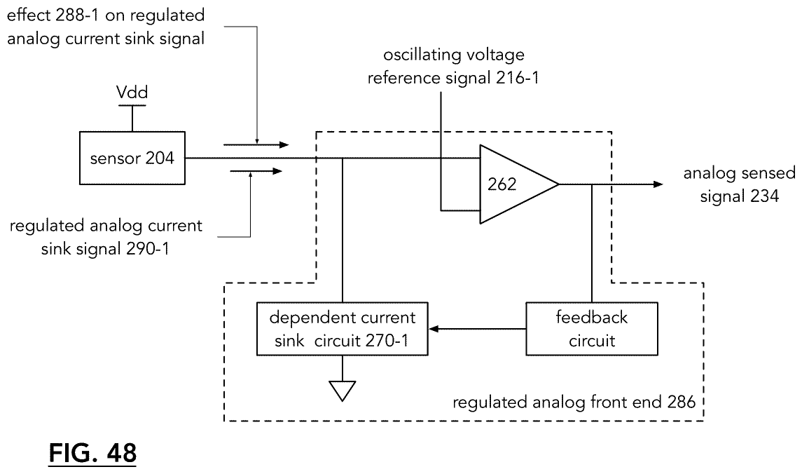

FIG. 53 is a schematic block diagram of another embodiment of a regulated analog front end of a drive sense circuit. In this embodiment, the analog front end includes a dependent impedance sink circuit 270-3, a feedback circuit and an operational amplifier or comparator 262. The sensor 204 sinks a regulated analog impedance sink signal 290-3 into the dependent impedance sink circuit 270-3.

Based on the impedance of sensor 204 and the impedance sink signal 290-3, a sensor voltage is created which represents the effect 288-3 the sensor has on the regulated analog impedance sink signal. The operational amplifier or comparator 262 generates the analog sensed signal 234 as a difference between the oscillating current reference signal 216-3 converted to a voltage by the current to voltage converter 263-1 and the sensor voltage. As such, in this embodiment, the AFE is configured to sink an impedance (Z) based on a current (I) to sense the voltage across the sensor, where V=I*Z.

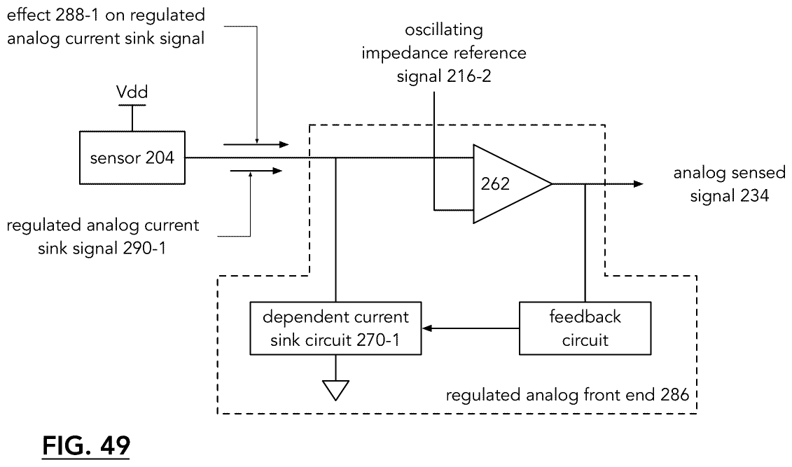

FIG. 54 is a functional diagram of an embodiment of a digital filter circuit 224 of a drive sense circuit. The digital filter circuit 224 filters a digital sensed signal 236 to produce a filtered digital sensed signal 238. The digital sensed signal 236 includes one or more signal components, where each signal component is at a different frequency. For example, the digital sensed signal 236 includes a DC component and an oscillating component at frequency fs1, which may range from KHz to GHz.

Each signal component contains unique information about the effect on the drive signal. For example, the DC signal component provides information regarding the sensor's resistance affected the drive signal. As another example, an oscillating component at frequency fs1 provides information regarding the sensor's self-capacitance with respect to a ground reference. As yet another example, an oscillating component at frequency fs2 provides information regarding the sensor's mutual-capacitance with respect to another sensor (e.g., an electrode in a touch screen device).

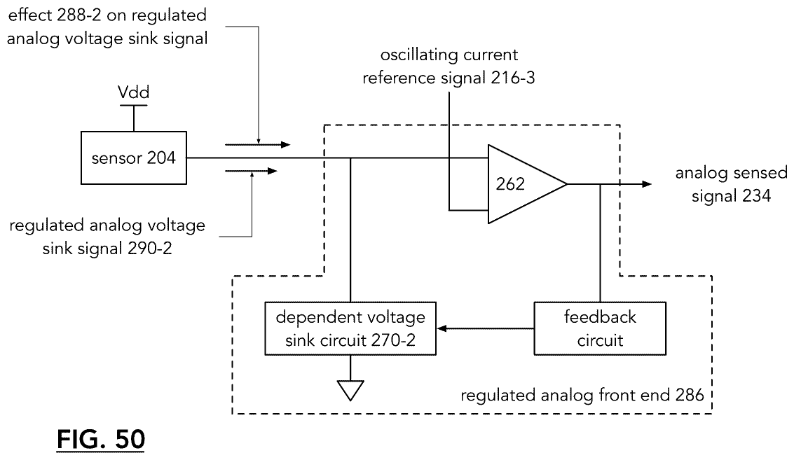

The digital filter circuit 224 low pass filters the DC component (if included in the digital sensed signal) and individually bandpass filters each of the oscillating components at the different frequencies. When the oscillating signal components are sinusoidal signals, the bandpass region of a bandpass filter can be narrow (e.g., single digital Hertz to a few hundred Hertz) and the roll-off rate can be steep (e.g., 20 dB or more per decade). Various embodiments of the digital filter circuit are discussed in greater detail with reference to one or more of FIGS. 55-60.

FIG. 55 is a schematic block diagram of another embodiment of a digital filter circuit 224 of a drive sense circuit. In this embodiment, the digital filter circuit 224 includes a digital low pass filter near DC and a plurality of digital bandpass filters centered at fs1, fs2, fs3, . . . , fsn. Each of the digital filters receives the digital sensed signal 236.

The various signal components of the digital sensed signal 236 represent different effects on the drive signal. For example, the DC signal component of the digital sensed signal 236 represents a DC magnitude effect on the drive signal. As another example, the fs1 signal component of the digital sensed signal 236 represents an AC magnitude effect on the drive signal. As yet another example, the fs2 signal component of the digital sensed signal 236 represents a frequency effect on the drive signal. As yet another example, the fs3 signal component of the digital sensed signal 236 represents a phase effect on the drive signal.

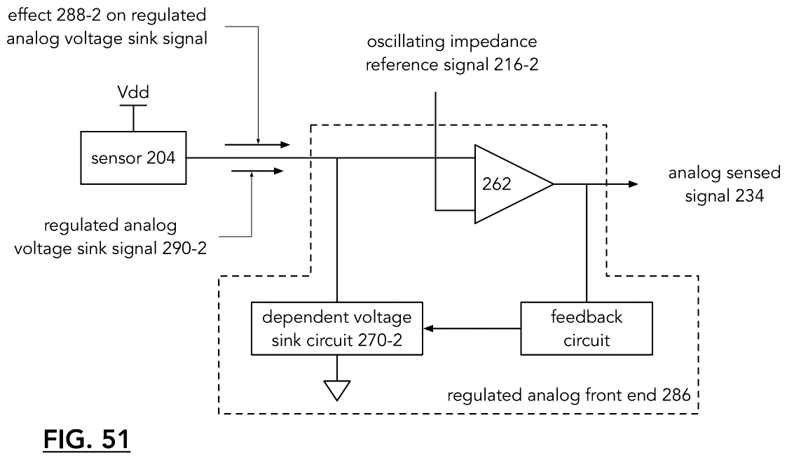

FIG. 56 is a schematic block diagram of another embodiment of a digital filter circuit 224 of a drive sense circuit. In this embodiment, the digital filter circuit 224 includes a digital low pass filter near DC and a plurality of digital bandpass filters centered at fs1, fs2, fs3, . . . , fsn. Each of the digital filters receives the digital sensed signal 236.

The various signal components of the digital sensed signal 236 represent different effects on the drive signal. For example, the DC signal component of the digital sensed signal 236 represents a DC magnitude effect on the drive signal. As another example, the fs1 signal component of the digital sensed signal 236 represents an AC magnitude effect of self-capacitance on the drive signal. As yet another example, the fs2 signal component of the digital sensed signal 236 represents an AC magnitude effect of a first mutual-capacitance on the drive signal. As yet another example, the fs3 signal component of the digital sensed signal 236 represents an AC magnitude effect of a second mutual-capacitance on the drive signal. As yet another example, the fsn signal component of the digital sensed signal 236 represents an AC magnitude effect of an “n”th mutual-capacitance on the drive signal.

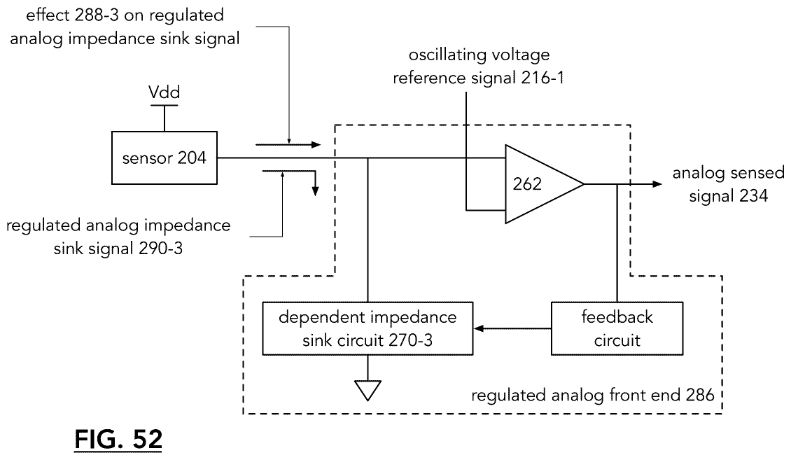

FIG. 57 is a schematic block diagram of another embodiment of a digital filter circuit 224 of a drive sense circuit. The digital figure circuit 224 includes a decimation filter, a filter controller circuit, and a plurality of finite impulse response (FIR) filters. The decimation filter, which, in an embodiment, is a Discrete Fourier Transform (DFT) filter, converts the low-bit high data rate digital sensed signal 236 into a higher-bit lower rate data signal. For example, the digital sensed signal 236 is a 1-bit digital value at 39.32 MHz rate and the decimation filter outputs an 18-bit digital value at 1.23 MHz. One or more embodiments of the decimation filter are described in U.S. Pat. No. 10,554,215.

The filter controller circuit, which is a stand-alone processing module, a shared processing module, or part of the touch sense controller processing module, is operable to configure the FIR filters based on the sensor effects being sensed. Configuring of an FIR filter includes one or more of setting a center frequency, setting a bandpass region, setting roll-off rates, setting a first corner frequency, and setting a second corner frequency based on enabling a number of stages and establishing coefficients for the enabled stages.

As an example, the filter controller circuit configures an FIR filter to be a lowpass filter near DC for resistance of a sensor's effect on the DC magnitude of the drive signal. As another example, the filter controller circuit configures an FIR filter to be a bandpass filter at fs1 and a second FIR filter to be a bandpass filter at fs2.

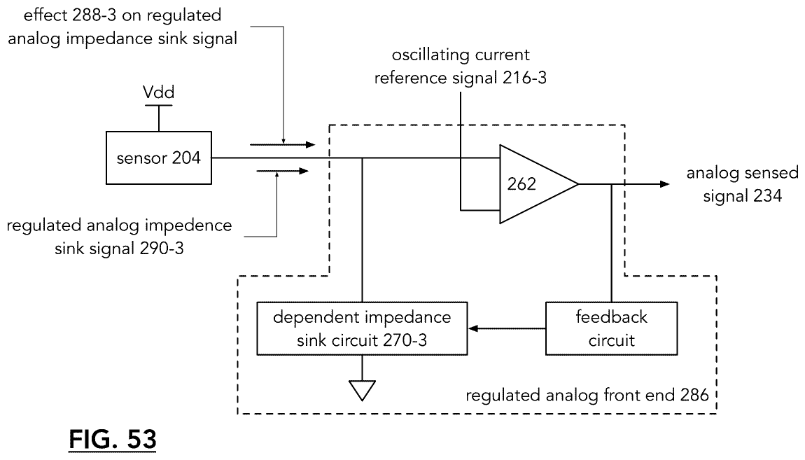

FIG. 58 is a schematic block diagram of another embodiment of an FIR filter of the digital filter circuit. The FIR filter includes a plurality of stages (e.g., 0-7). Each stage includes a corresponding coefficient (e.g., ho to h₇). The number of stages and their coefficients can be programmed via the filter controller circuit to produce a desired filter response. A further discussion of FIR filters is provided in U.S. Pat. No. 10,554,215.

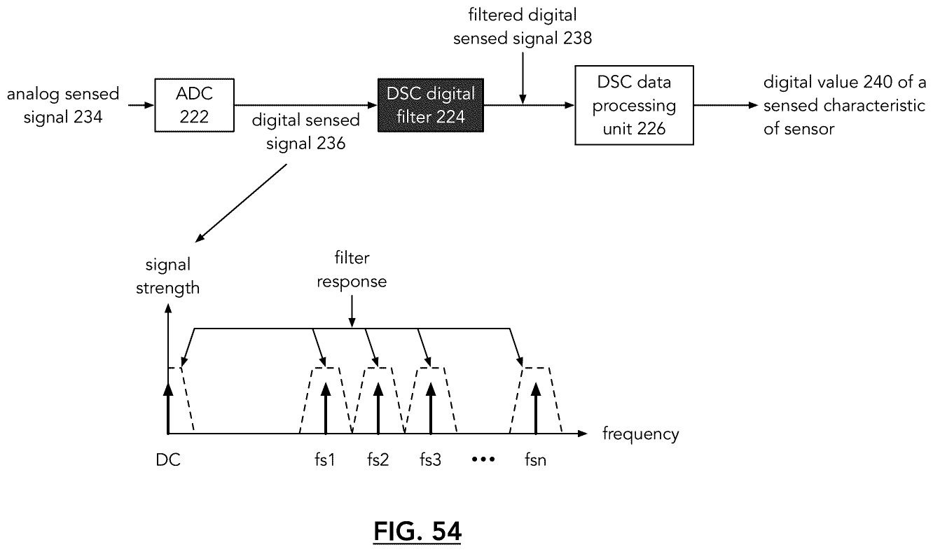

FIG. 59 is a schematic block diagram of another embodiment of a digital filter 224 of a drive sense circuit. The digital figure circuit 224 includes a decimation filter, a filter controller circuit, and a plurality of infinite impulse response (IIR) filters. The decimation filter, which, in an embodiment, is a Discrete Fourier Transform (DFT) filter, converts the low-bit high data rate digital sensed signal 236 into a higher-bit lower rate data signal.

The filter controller circuit, which is a stand-alone processing module, a shared processing module, or part of the touch sense controller processing module, is operable to configure the IIR filters based on the sensor effects being sensed. Configuring of an IIR filter includes one or more of setting a center frequency, setting a bandpass region, setting roll-off rates, setting a first corner frequency, and setting a second corner frequency based on enabling a number of stages and establishing coefficients for the enabled stages.

As an example, the filter controller circuit configures an IIR filter to be a lowpass filter near DC for resistance of a sensor's effect on the DC magnitude of the drive signal. As another example, the filter controller circuit configures an IIR filter to be a bandpass filter at fs1 and a second IIR filter to be a bandpass filter at fs2.

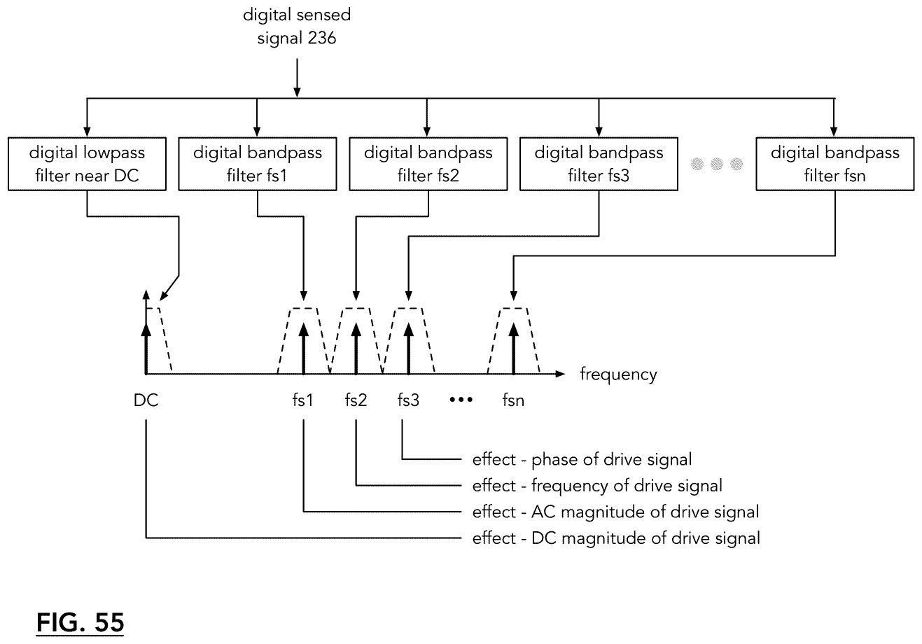

FIG. 60 is a schematic block diagram of another embodiment of an IIR filter of the digital filter circuit 224. The IIR includes a first stage section (e.g., stage 0-stage 3) and a second stage section (e.g., stage a0-stage a3). The operation and adjusting of stages and/or coefficients of an IIR filter are known.

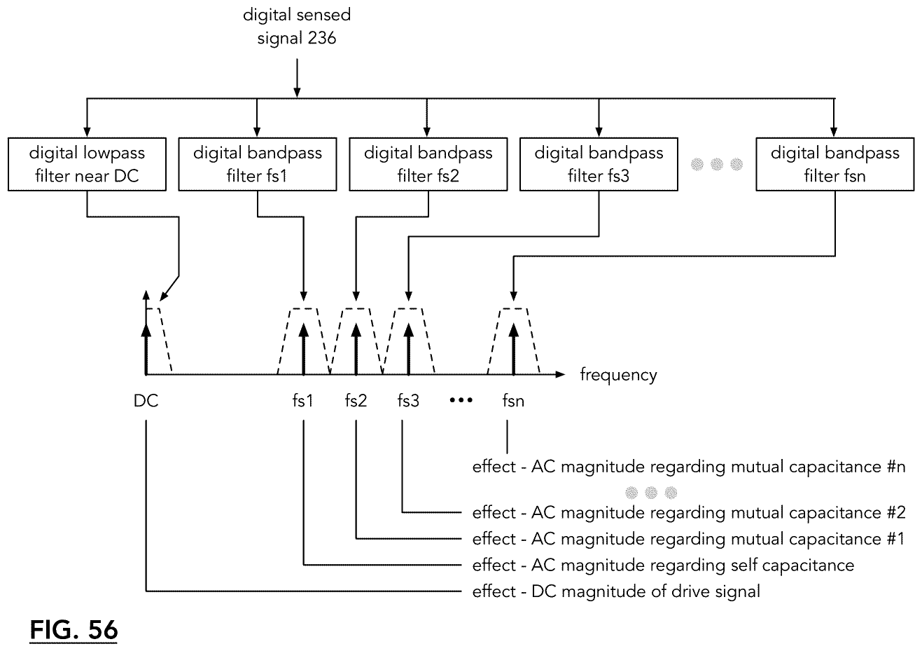

FIG. 61 is a functional diagram of an embodiment of a data processing unit 226 of a drive sense circuit. The drive processing unit 226 processes the filtered digital sensed signal 238 to produce a digital value 240 of a sensed characteristic of a sensor. If the filtered digital sensed signal 238 includes multiple signal components (e.g., DC, fs1, fs2, . . . ), then the data processing unit 226 produces multiple digital values; one for each signal component.

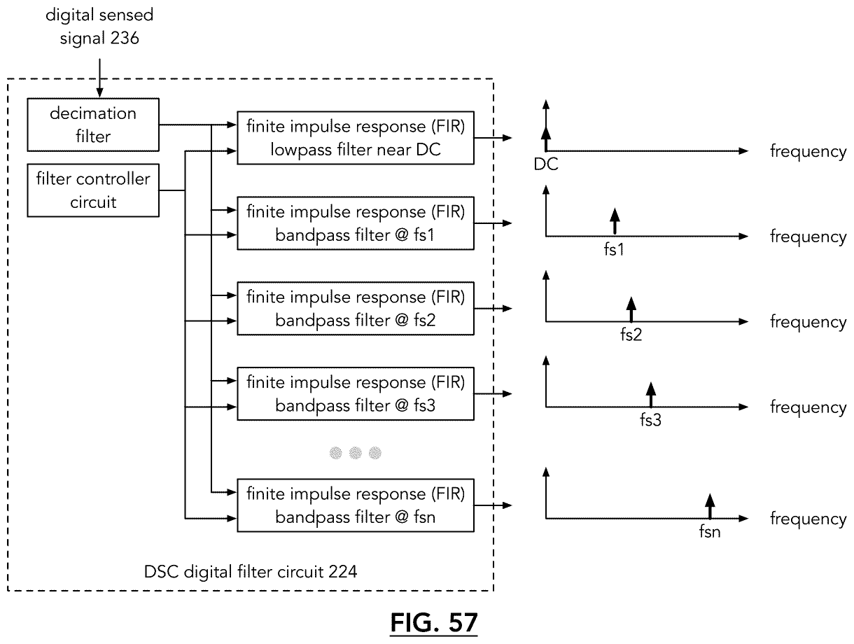

The data processing unit processes the filtered digital sensed signal 238 based on an equation; an example of which is shown in FIG. 62. The equation is dependent on the effect the sensor had on the drive signal and the particular characteristic of the sensor being sought. The data processing unit 226 executes the equation in a variety of ways. For example, the data processing unit executes the equation via a series of operational instructions. As another example, the data processing unit executes the equation via a lookup table. As yet another example, the data processing unit executes the equation via logic circuitry.

The effects on the drive signal includes affecting DC magnitude, AC magnitude, phase, and/or frequency of an analog current signal, an analog voltage signal, or an analog signal representing impedance. The characteristic of a sensor includes, but is not limited to, resistance, reactance, capacitance, inductance, impedance, detected light, phase response, frequency response, an environmental condition (e.g., temperature, humidity, altitude, etc.), and a physical condition (e.g., pressure, force, distance, flow rate, etc.).

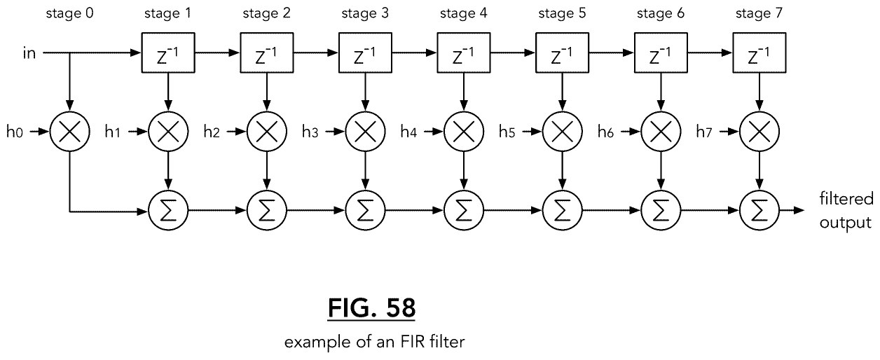

FIG. 63 is a logic diagram of an example of a method for determining capacitance of a sensor. The method begins at step 300 where the data processing unit receives a filtered digital signal, which represents the effect(s) of a sensor on a regulated analog drive signal. The method continues at step 302 where the data processing unit calculates a current value (iₛ) based on the output voltage (vₛ) of the regulated analog front end and an i/v ratio of the dependent current source. For example, iₛ=vₒ*(i/v ratio).

The method continues at step 304 where the data processing unit calculates an impedance (z) based on the reference voltage (v_{ref}) and the current (iₛ). For example, z=v_{ref}/iₛ. The method continues at step 306 where the data processing unit calculates the capacitance (C) of the sensor based on the impedance and the frequency (f) of the oscillating reference voltage signal. For example, C=1/(2*π*f*z).

As a specific example, the reference voltage is chosen to 0.5 sin (2*π*100,000) volts, where f=100 KHz. The i/v ratio of the dependent current source is chosen to be 10 μA/1 volt, where μA is micro-Amps. The output of the analog front end is chosen to range from 0.1 volts to 0.9 volts. As such, is ranges from 1.0 sin (2*π*100,000) μA to 9.0 sin (2*π*100,000) μA.

From these equations, the range of impedance that can be sensed based on v_{ref}/iₛ is 55.6 KΩ to 500 KΩ (kilo-Ohms). Accordingly, the range of capacitance that can be sensed is 2.8 pF to 31.8 pF (pico-Farads).

Continuing with this example, the data processing unit receives a filtered digital signal that has a value corresponding to the output voltage of the analog front end of 0.4 volts. From this value, the data processing unit generates a digital value representing the current, which is 4 μA. The data processing unit then calculates an impedance based on v_{ref}/iₛ, which is (0.5 volts)/(0.4 μA), which equals 125 KΩ. The data processing unit then calculates the capacitance of the sensor based on C=1/(2*π*f*z), which equals 12.7 pF.

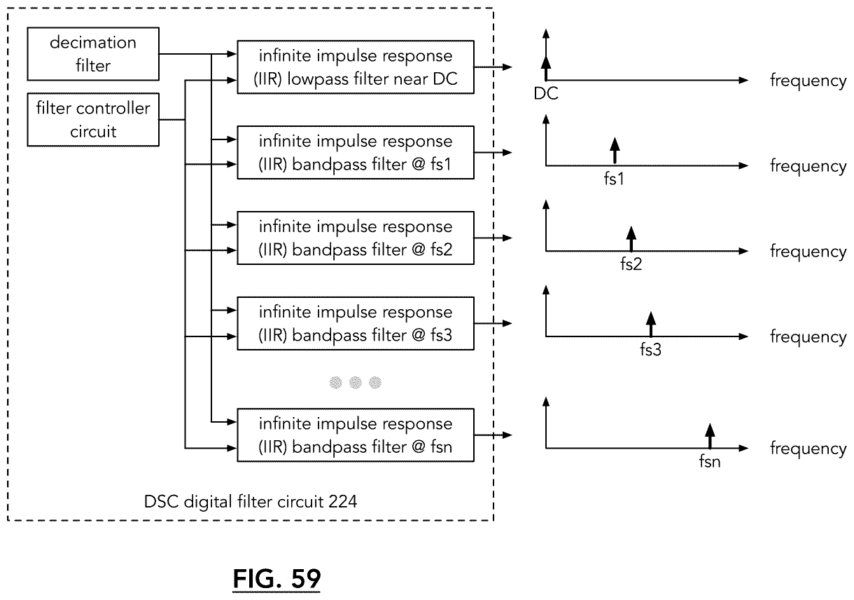

FIG. 64 is a schematic block diagram of an embodiment of a data processing unit of a drive sense circuit. This embodiment of the data processing unit is a logic circuit implementation of the method of FIG. 63. As shown, the dependent current source produces a current i(t) based on the output voltage vₒ(t) of the op amp 262. The op amp 262 generates vo(t) such that the capacitance voltage v(t) equals the reference voltage (v_{ref}).

The data processing unit calculates the impedance (Z) of the capacitor V by determining the magnitude of vo and multiplying it with i/v ratio of the dependent current source to determine the magnitude of i(t). The magnitude of i(t) is multiplied by the magnitude of v_{ref} to determine the impedance (Z).

The capacitance of C is calculated by determining the frequency (f) of v_{ref}. The frequency (f) is multiplied by 2*π. The product of which is multiplied by the impedance (Z) and inverted to produce the capacitance.

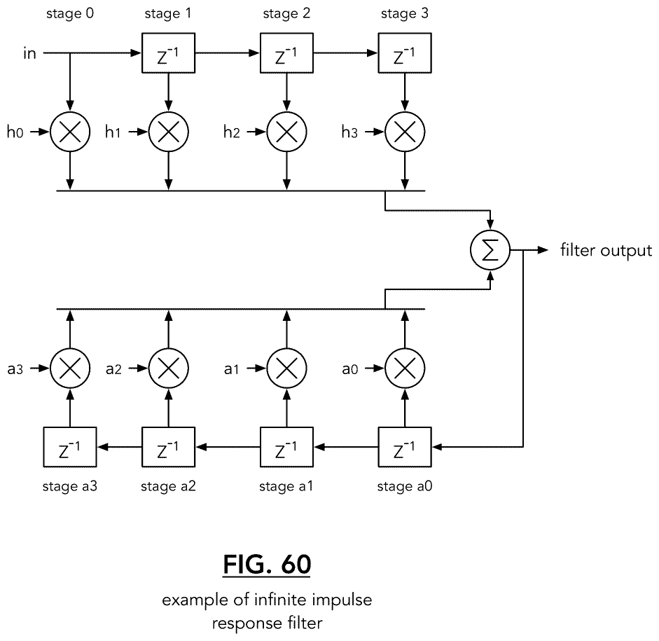

FIG. 65 is a logic diagram of another example of a method for determining capacitance of a sensor. The method begins at step 310 where the data processing unit receives a filtered digital signal, which represents the voltage of the sensor (vs). The method continues at step 312 where the data processing unit calculates a current value (iₛ) based on the reference voltage (v_{ref}) and an i/v ratio of the dependent current source. For example, iₛ=v_{ref}*(i/v ratio).

The method continues at step 314 where the data processing unit calculates an impedance (z) based on the sensor voltage (vₛ) and the current (iₛ). For example, z=vₛ/iₛ. The method continues at step 316 where the data processing unit calculates the capacitance (C) of the sensor based on the impedance and the frequency (f) of the oscillating reference voltage signal. For example, C=1/(2*π*f*z).

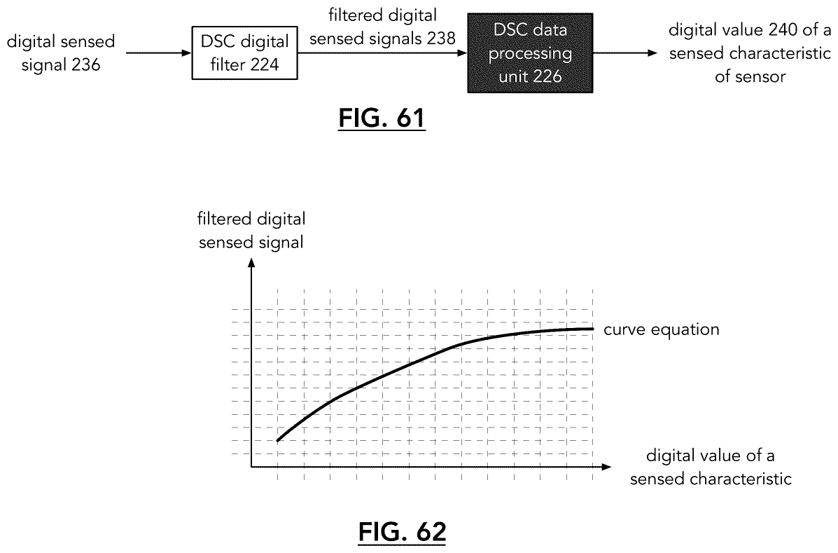

FIG. 66 is a schematic block diagram of another embodiment of a data processing unit of a drive sense circuit. This embodiment of the data processing unit is a logic circuit implementation of the method of FIG. 65. As shown, the dependent current source produces a current i(t) based on the reference voltage v_{ref}(t). The op amp 262 generates vo(t) based on a difference between the reference voltage (v_{ref}) and the capacitance voltage v(t).

The data processing unit determines the magnitude of the reference voltage v_{ref} and the frequency (f) of v_{ref}. The data processing unit determines the magnitude of the op amp output voltage vₒ and subtracts from it the magnitude of v_{ref} to produce a magnitude of v(t). The magnitude of v_{ref} is multiplied by i/v ratio of the dependent current source to produce a magnitude of i(t). The magnitude of v(t) is divided by the magnitude of i(t), to produce the impedance (z). Note that magnitude may be a peak-to-peak value, a peak value, an RMS value, or other measure of magnitude of an oscillating signal.

The frequency (f) of v_{ref} is multiplied by 2*π. The product of which is multiplied by the impedance (Z) and inverted to produce the capacitance.

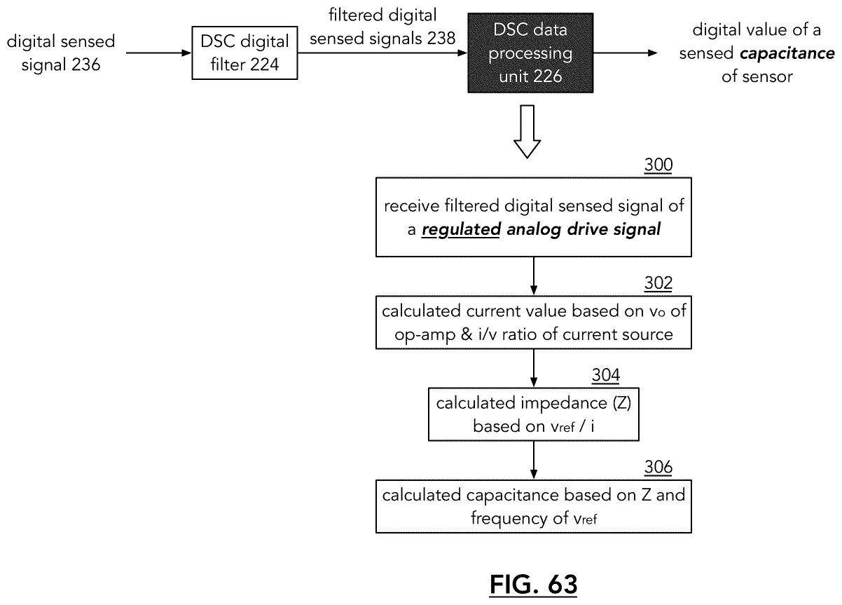

FIG. 67 is a schematic block diagram of another embodiment of a data processing unit of a drive sense circuit. This embodiment of the data processing unit is an alternate logic circuit implementation of the method of FIG. 65. As shown, the dependent current source produces a current i(t) based on the reference voltage v_{ref}(t). The op amp 262 outputs the capacitance voltage v(t).

The data processing unit determines the magnitude of the reference voltage v_{ref}, the frequency (f) of v_{ref}, and the magnitude of v(t). The magnitude of v_{ref} is multiplied by i/v ratio of the dependent current source to produce a magnitude of i(t). The magnitude of v(t) is divided by the magnitude of i(t), to produce the impedance (z). The frequency (f) of v_{ref} is multiplied by 2*π. The product of which is multiplied by the impedance (Z) and inverted to produce the capacitance.

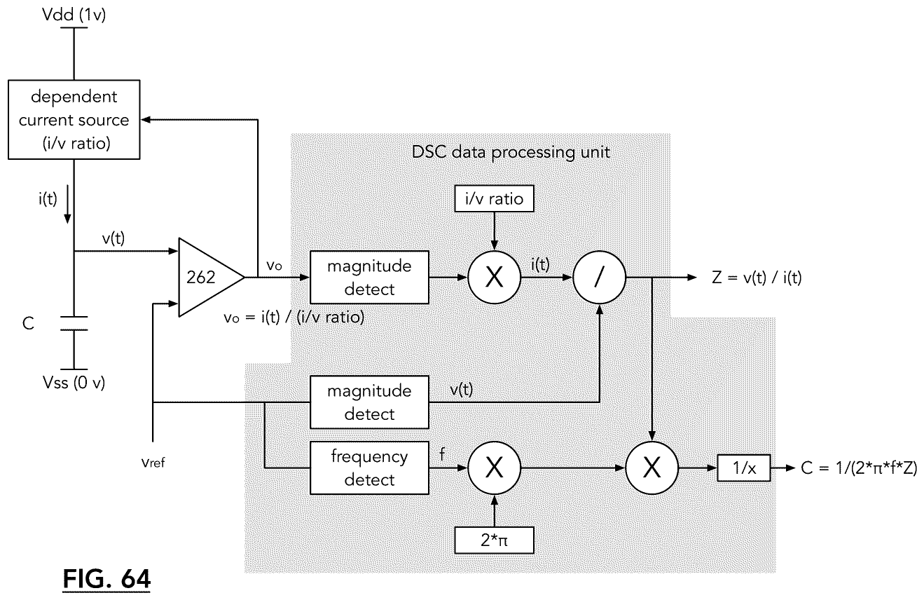

FIG. 68 is a logic diagram of another example of a method for determining capacitance of a sensor. The method begins at step 320 where the data processing unit receives a filtered digital signal, which represents the effect(s) of a sensor on a regulated analog drive signal. The method continues at step 322 where the data processing unit calculates a current value (iₛ) based on the output voltage (vₒ) of the regulated analog front end and an i/v ratio of the dependent current source. For example, iₛ=vₒ*(i/v ratio).

The method continues at step 324 where the data processing unit calculates the capacitance of the sensor based on i(t) and v(t), which is the capacitance voltage and is equal to the reference voltage. For example, v(t)=1∫f i(t) dt and i(t)=C(dv/dt), where i(t) represents an imaginary component of the capacitance and v(t) represents the real component of the capacitance. Utilizing an I-Q (real-imaginary) function, the capacitance is the magnitude of i(t) as the y-component and v(t) as the x-component. Note that the capacitance may be calculated using one or more other methods.

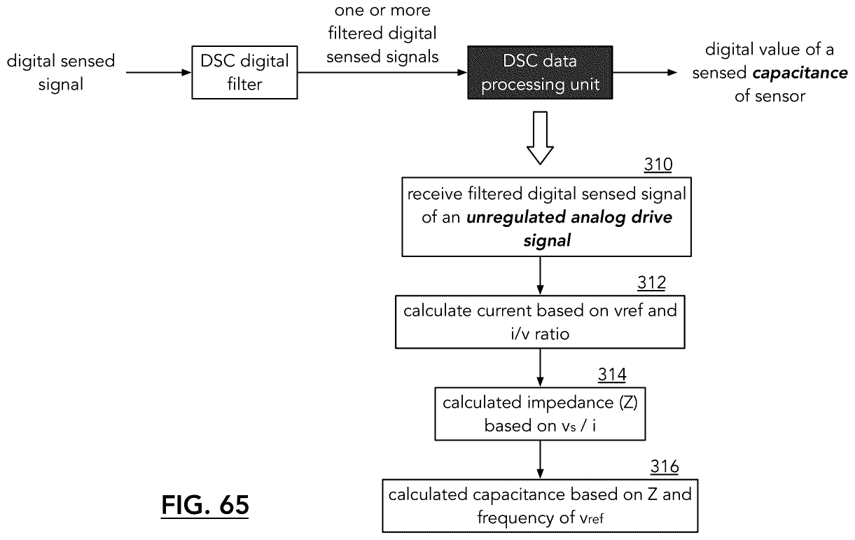

FIG. 69 is a schematic block diagram of another embodiment of a data processing unit of a drive sense circuit. This embodiment of the data processing unit is a logic circuit implementation of the method of FIG. 68. As shown, the dependent current source produces a current i(t) based on the output voltage vₒ(t) of the op-amp 262. The op amp 262 generates vₒ(t) by regulating v(t) to substantially match the reference voltage (v_{ref}).

The current produced by the dependent current source i(t) is equal to vₒ(t)*the i/v ratio of the dependent current source. The current i(t) is produced by multiplying vₒ(t) by i/v ratio, where i(t)=C (dv/dt). The current is integrated to produce f i(t).

The reference voltage v_{ref} equals the capacitor voltage v(t), which in turn equals 1/C∫i(t) dt. The capacitor voltage v(t) is differentiated to produce dv/dt. The digital value processing circuit can determine the capacitance C in a variety of ways. For example, the digital value processing circuit outputs the integral of (t) divided by v(t), where C=1/v(t)∫i(t) dt. As another example, the digital value processing circuit outputs the current i(t) divided by the differentiation of v(t), where C=i(t)/(dv/dt).

As a still further example, the digital value processing circuit executes an I-Q function on the current i(t) and the voltage (t) to determine the capacitance. As another example, the digital value processing circuit receives C=1/v(t)∫i(t) dt and C=i(t)/(dv/dt). The digital value processing circuit compares the two C values. If they are similar (e.g., within a few percent of each other), the digital value processing circuit outputs one of the capacitance values or a combination of both capacitance values.

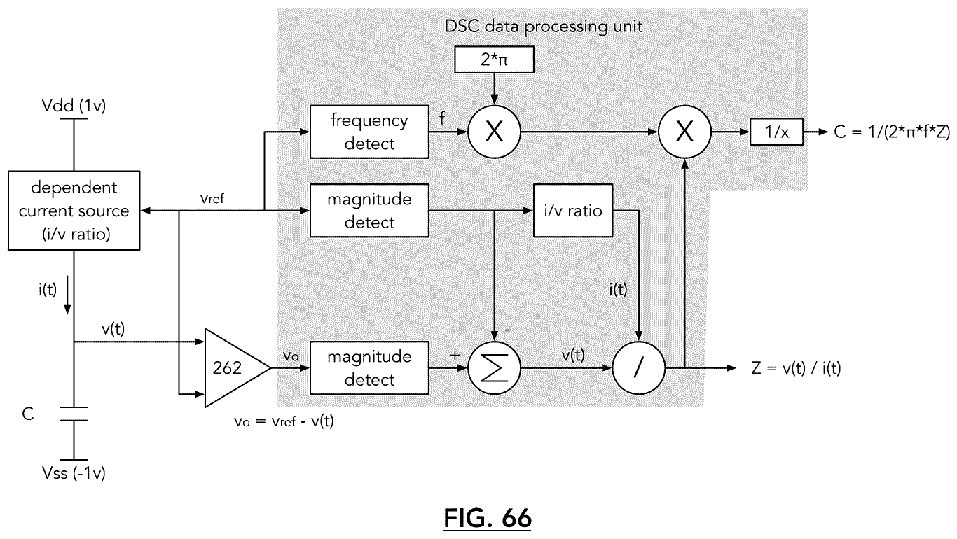

FIG. 70 is a logic diagram of another example of a method for determining capacitance of a sensor. The method begins at step 330 where the data processing unit receives a filtered digital signal, which represents the effect(s) of a sensor on an unregulated analog drive signal. The method continues at step 332 where the data processing unit calculates a current i(t) based on the reference voltage (v_{ref}) and an i/v ratio of the dependent current source. For example, i(t)=v_{ref}*(i/v ratio).

The method continues at step 334 where the data processing unit calculates the capacitance of the sensor based on i(t) and v(t), where v(t)=vₒ(t)−v_{ref}. For example, v(t)=1/C∫i(t) dt and i(t)=C(dv/dt), where i(t) represents an imaginary component of the capacitance and v(t) represents the real component of the capacitance. Utilizing an I-Q (real-imaginary) function, the capacitance is the magnitude of i(t) as the y-component and v(t) as the x-component. Note that the capacitance may be calculated using one or more other methods.

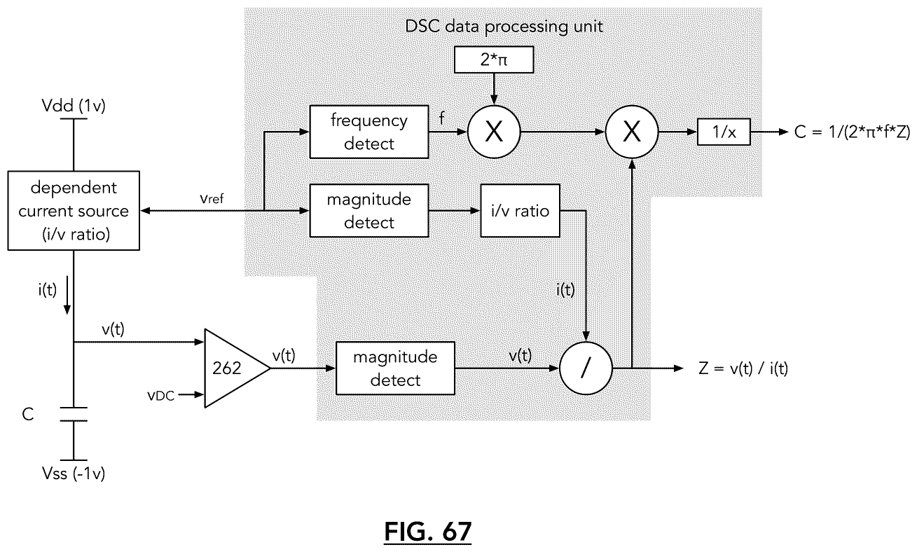

FIG. 71 is a schematic block diagram of another embodiment of a data processing unit of a drive sense circuit. This embodiment of the data processing unit is a logic circuit implementation of the method of FIG. 70. As shown, the dependent current source produces a current i(t) based on the reference voltage v_{ref}(t). The op amp 262 generates vₒ(t) based on a difference between the capacitance voltage v(t) and the reference voltage (v_{ref}).

The current produced by the dependent current source i(t) is equal to v_{ref})*the i/v ratio of the dependent current source. The current i(t) is produced by multiplying v_{ref}(t) by i/v ratio, where i(t)=C (dv/dt). The current is integrated to produce ∫i(t).

The capacitor voltage v(t) is equal to v_{ref}(t)−vo(t), which in turn equals 1/C∫i(t) dt. The capacitor voltage v(t) is differentiated to produce dv/dt. The digital value processing circuit can determine the capacitance C in a variety of ways. For example, the digital value processing circuit outputs the integral of (t) divided by v(t), where C=1/v(t)∫i(t) dt. As another example, the digital value processing circuit outputs the current i(t) divided by the differentiation of v(t), where C=i(t)/(dv/dt).

As a still further example, the digital value processing circuit executes an I-Q function on the current i(t) and the voltage (t) to determine the capacitance. As another example, the digital value processing circuit receives C=1/v(t)∫i(t) dt and C=i(t)/(dv/dt). The digital value processing circuit compares the two C values. If they are similar (e.g., within a few percent of each other), the digital value processing circuit outputs one of the capacitance values or a combination of both capacitance values.

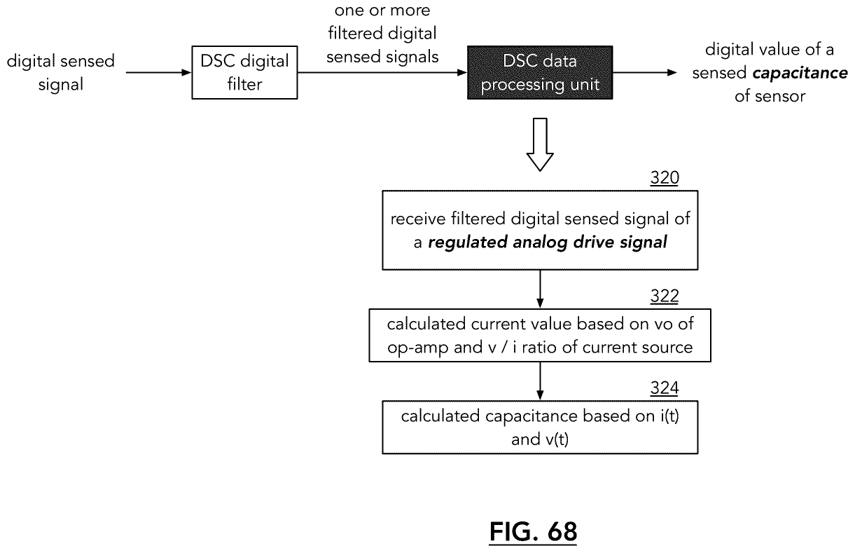

FIG. 72 is a schematic block diagram of another embodiment of a data processing unit of a drive sense circuit. This embodiment of the data processing unit is another logic circuit implementation of the method of FIG. 70. As shown, the dependent current source produces a current i(t) based on the reference voltage v_{ref}(t). The op amp 262 generates vₒ(t) based on a DC reference voltage (v_{DC}).

The current produced by the dependent current source i(t) is equal to v_{ref}(t)*the i/v ratio of the dependent current source. The current i(t) is produced by multiplying v_{ref}(t) by i/v ratio, where i(t)=C (dv/dt). The current is integrated to produce ∫i(t).

The capacitor voltage v(t) equals 1/C∫i(t) dt. The capacitor voltage v(t) is differentiated to produce dv/dt. The digital value processing circuit can determine the capacitance C in a variety of ways. For example, the digital value processing circuit outputs the integral of (t) divided by v(t), where C=1/v(t)∫i(t) dt. As another example, the digital value processing circuit outputs the current i(t) divided by the differentiation of v(t), where C=i(t)/(dv/dt).

As a still further example, the digital value processing circuit executes an I-Q function on the current i(t) and the voltage (t) to determine the capacitance. As another example, the digital value processing circuit receives C=1/v(t)∫i(t) dt and C=i(t)/(dv/dt). The digital value processing circuit compares the two C values. If they are similar (e.g., within a few percent of each other), the digital value processing circuit outputs one of the capacitance values or a combination of both capacitance values.

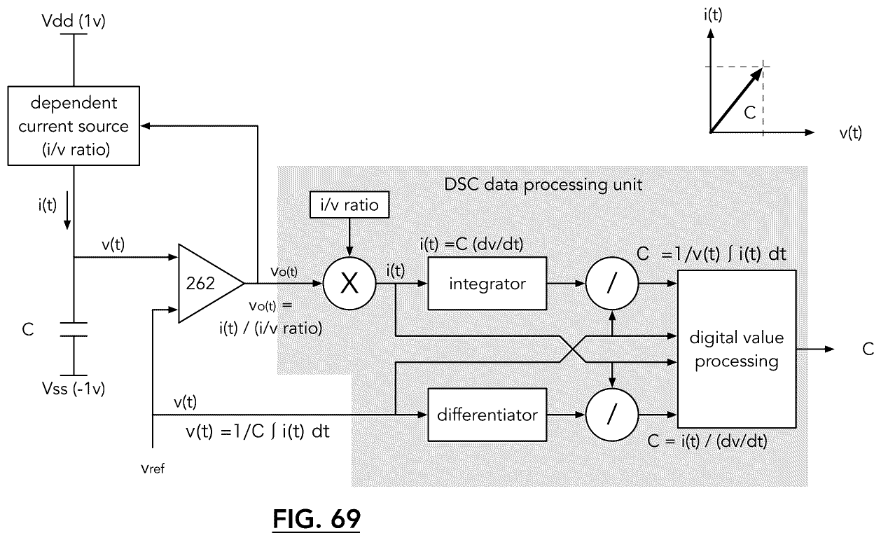

FIG. 73 is a logic diagram of another example of a method for determining inductance of a sensor. The method begins at step 340 where the data processing unit receives a filtered digital signal, which represents the effect(s) of a sensor on a regulated analog drive signal. The method continues at step 342 where the data processing unit calculates a current value (iₛ) based on the output voltage (vₒ) of the regulated analog front end and an i/v ratio of the dependent current source. For example, iₛ=vₒ*(i/v ratio).

The method continues at step 344 where the data processing unit calculates an impedance (z) based on the reference voltage (v_{ref}) and the current (iₛ). For example, z=v_{ref}/iₛ. The method continues at step 346 where the data processing unit calculates the inductance (L) of the sensor based on the impedance and the frequency (f) of the oscillating reference voltage signal. For example, L=2*π*f/z.

Note that the calculations may be done in a variety of ways. For example, the calculations are done via one or more lookup tables. As another example, the calculations are done via logic circuitry. As another example, the calculations are done by executing operational instructions of a software program.

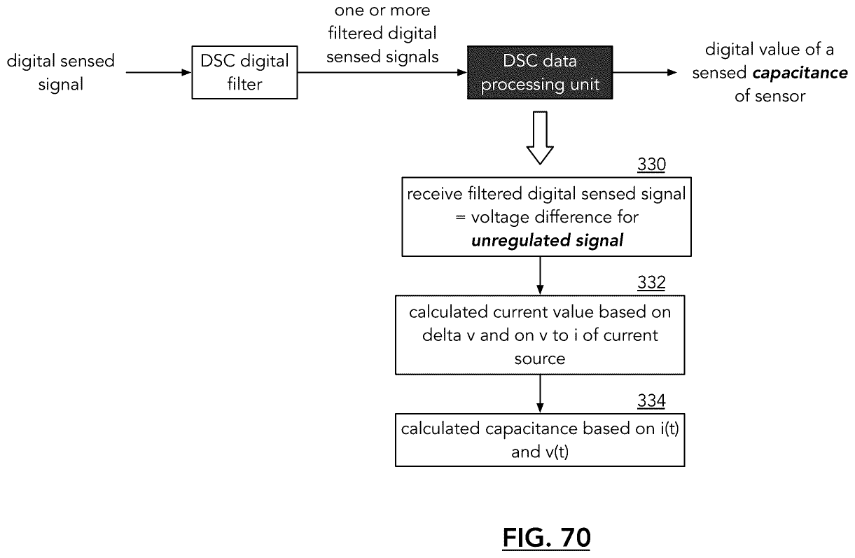

FIG. 74 is a logic diagram of another example of a method for determining inductance of a sensor. The method begins at step 350 where the data processing unit receives a filtered digital signal, which represents the effect(s) of a sensor on an unregulated analog drive signal. The method continues at step 352 where the data processing unit measures a voltage (vₛ) of the sensor and calculates (iₛ) of the sensor based on the reference voltage (v_{ref}) and an i/v ratio of the dependent current source. For example, iₛ=v_{ref}*(i/v ratio).

The method continues at step 354 where the data processing unit calculates an impedance (z) based on the reference voltage (v_{ref}) and the current (iₛ). For example, z=v_{ref}/iₛ. The method continues at step 356 where the data processing unit calculates the inductance (L) of the sensor based on the impedance and the frequency (f) of the oscillating reference voltage signal. For example, L=2*π*f/z.

Note that the calculations may be done in a variety of ways. For example, the calculations are done via one or more lookup tables. As another example, the calculations are done via logic circuitry. As another example, the calculations are done by executing operational instructions of a software program.

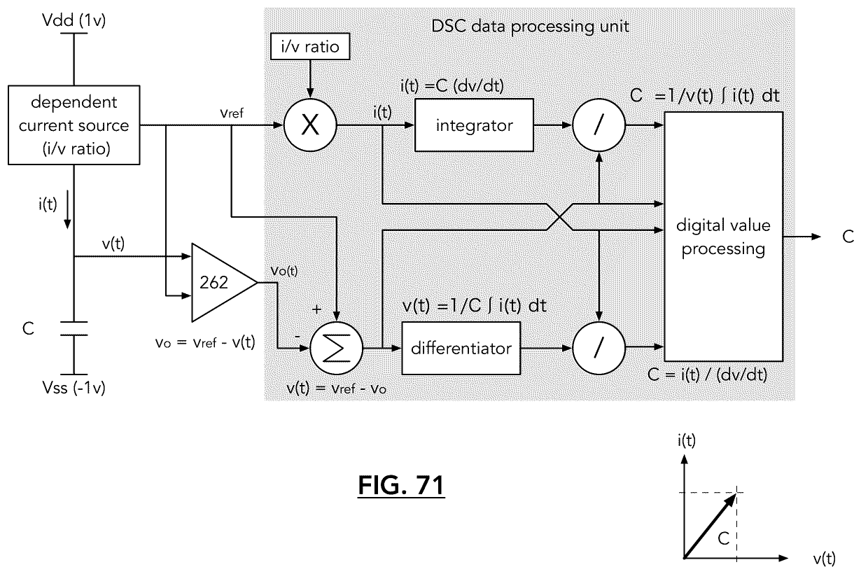

FIG. 75 is a logic diagram of another example of a method for determining inductance of a sensor. The method begins at step 360 where the data processing unit receives a filtered digital signal, which represents the effect(s) of a sensor on an unregulated analog drive signal. The method continues at step 362 where the data processing unit calculates a current value (iₛ) based on the reference voltage (v_{ref}) and an i/v ratio of the dependent current source. For example, iₛ=v_{ref}*(i/v ratio).

The method continues at step 364 where the data processing unit calculates the voltage v(t) of the sensor based on the difference between the op-amp output voltage vₒ(t) and the reference voltage v_{ref}. The method continues at step 366 where the data processing unit calculates the inductance of the sensor based on i(t) and v(t). For example, i(t)=1/L∫v(t) dt and v(t)=L(di/dt), where v(t) represents an imaginary component of the inductance and i(t) represents the real component of the inductance. Utilizing an I-Q (real-imaginary) function, the inductance is the magnitude of v(t) as the y-component and i(t) as the x-component. Note that the inductance may be calculated using one or more other methods.

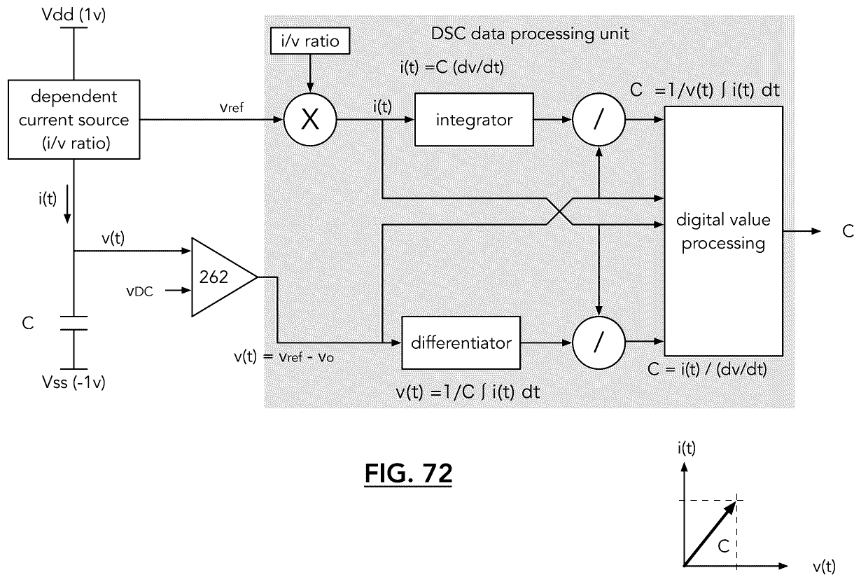

FIG. 76 is a logic diagram of another example of another method for determining inductance of a sensor. The method begins at step 370 where the data processing unit receives a filtered digital signal, which represents the effect(s) of a sensor on an unregulated analog drive signal. The method continues at step 372 where the data processing unit calculates a current value (iₛ) based on the reference voltage (v_{ref}) and an i/v ratio of the dependent current source. For example, iₛ=v_{ref}*(i/v ratio).

The method continues at step 374 where the data processing unit receives the voltage v(t) of the sensor. The method continues at step 376 where the data processing unit calculates the inductance of the sensor based on i(t) and v(t). For example, i(t)=1/L∫v(t) dt and v(t)=L(di/dt), where v(t) represents an imaginary component of the inductance and i(t) represents the real component of the inductance. Utilizing an I-Q (real-imaginary) function, the inductance is the magnitude of v(t) as the y-component and i(t) as the x-component. Note that the inductance may be calculated using one or more other methods.

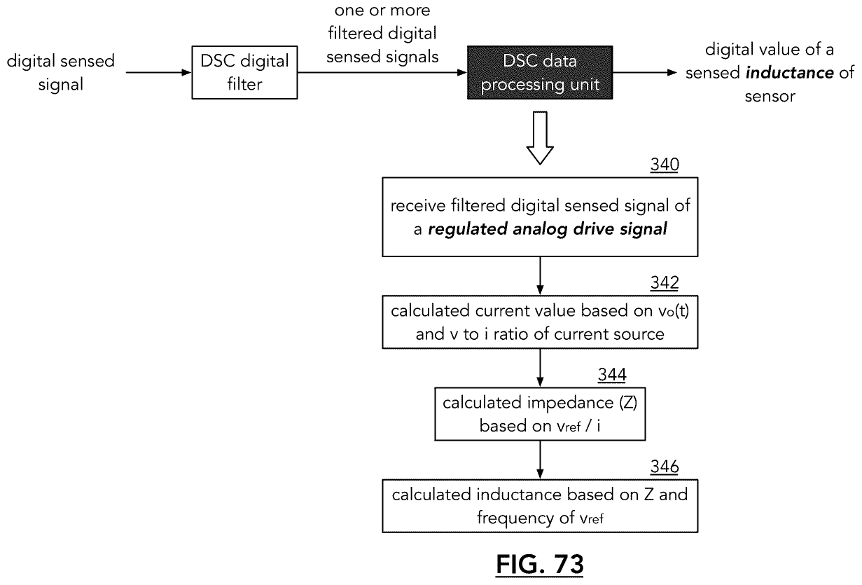

FIG. 77 is a functional diagram of another embodiment of a data processing unit of a drive sense circuit. In this embodiment, the data processing unit 226 calculates a resistance value from the filtered digital sensed signal. For example, the data processing unit receives and/or calculates the current and voltage of the sensor, where resistance of the sensor equals v/i.

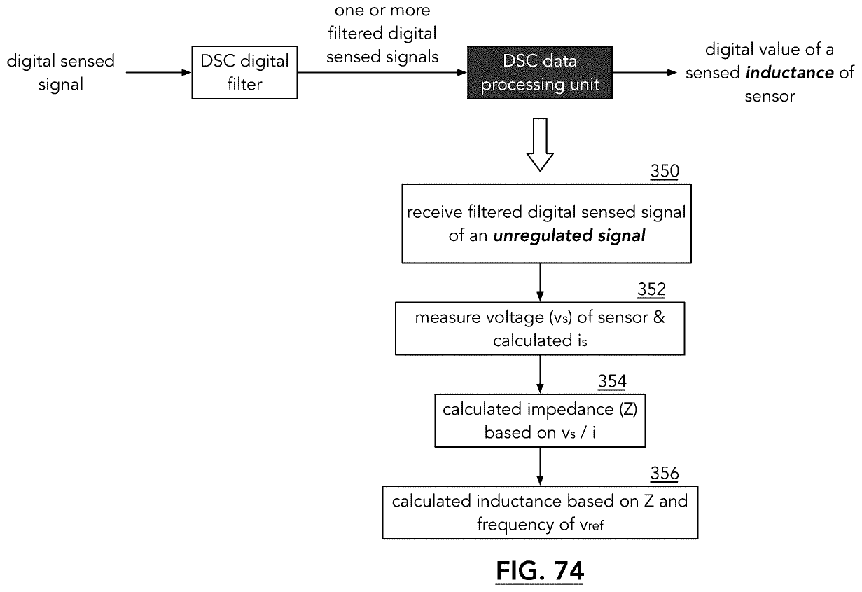

FIG. 78 is a functional diagram of another embodiment of a data processing unit of a drive sense circuit. In this embodiment, the data processing unit 226 calculates a reactance value from the filtered digital sensed signal. For example, the data processing unit calculates resistance, inductance, and/or capacitance as previously described and then, based on two or more of these values calculates the reactance of the sensor.

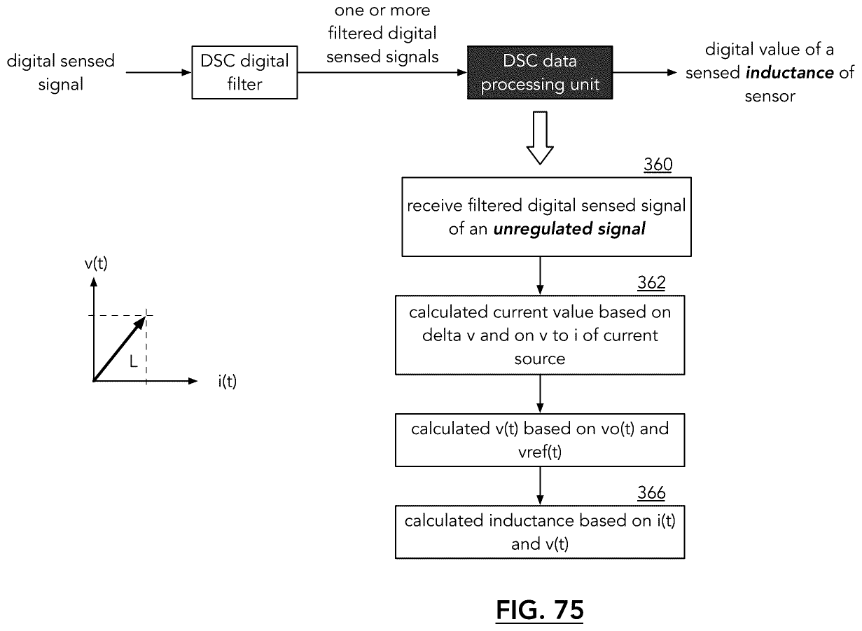

FIG. 79 is a functional diagram of another embodiment of a data processing unit of a drive sense circuit. In this embodiment, the data processing unit 226 calculates an environmental condition value from the filtered digital sensed signal. For example, the data processing unit calculates resistance, inductance, and/or capacitance as previously described and then, based on one or more of these values calculates an environmental condition (e.g., temperature, humidity, altitude, etc.).

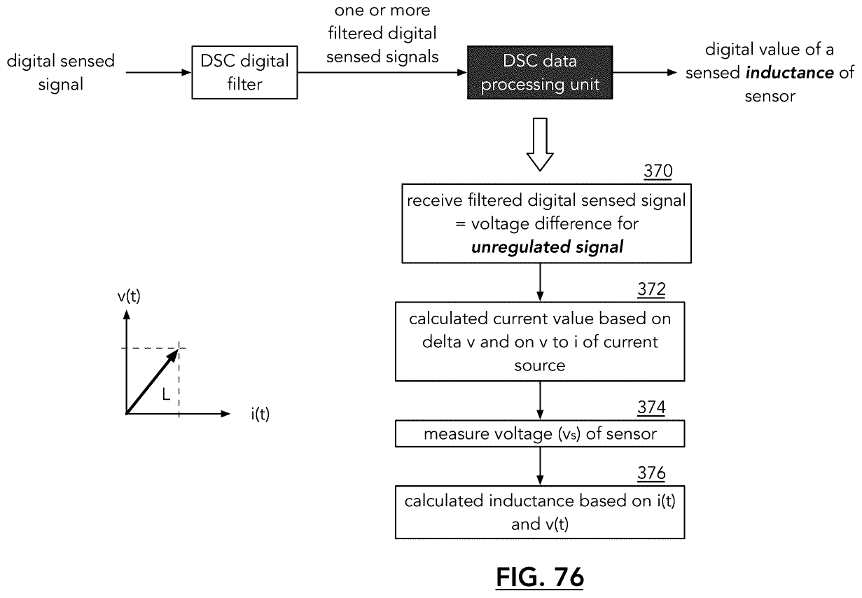

FIG. 80 is a functional diagram of another embodiment of a data processing unit of a drive sense circuit. In this embodiment, the data processing unit 226 calculates a physical condition value from the filtered digital sensed signal. For example, the data processing unit calculates resistance, inductance, and/or capacitance as previously described and then, based on one or more of these values calculates a physical condition (e.g., pressure, flow rate, dimension, expansion, etc.).

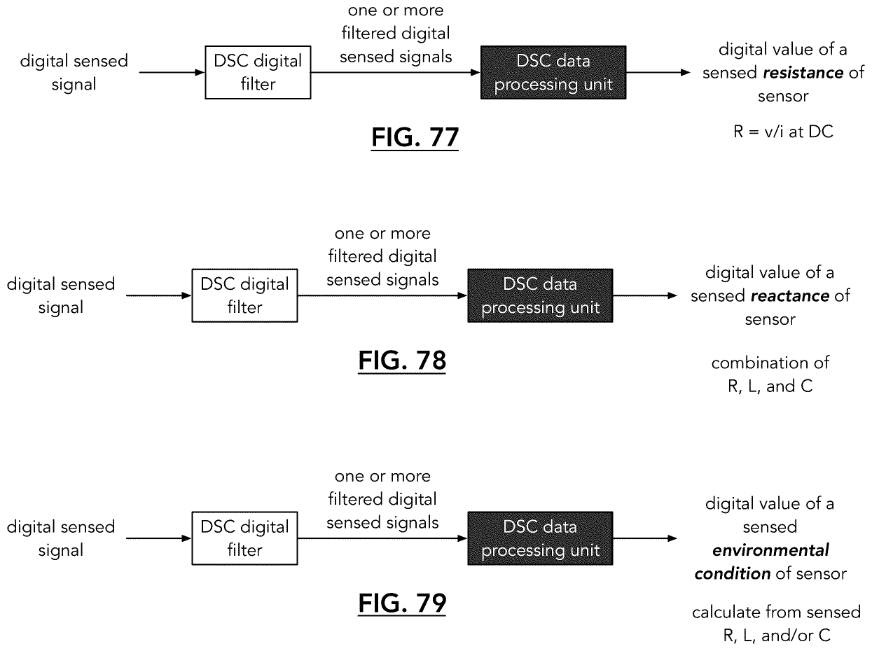

FIG. 81 is a functional diagram of another embodiment of a data processing unit of a drive sense circuit. In this embodiment, the data processing unit 226 calculates a phase response of the sensor from the filtered digital sensed signal. For example, the data processing unit calculates a phase shift value as previously described and then calculates a phase response (e.g., time delay in the time domain and a phase delay in the frequency domain).

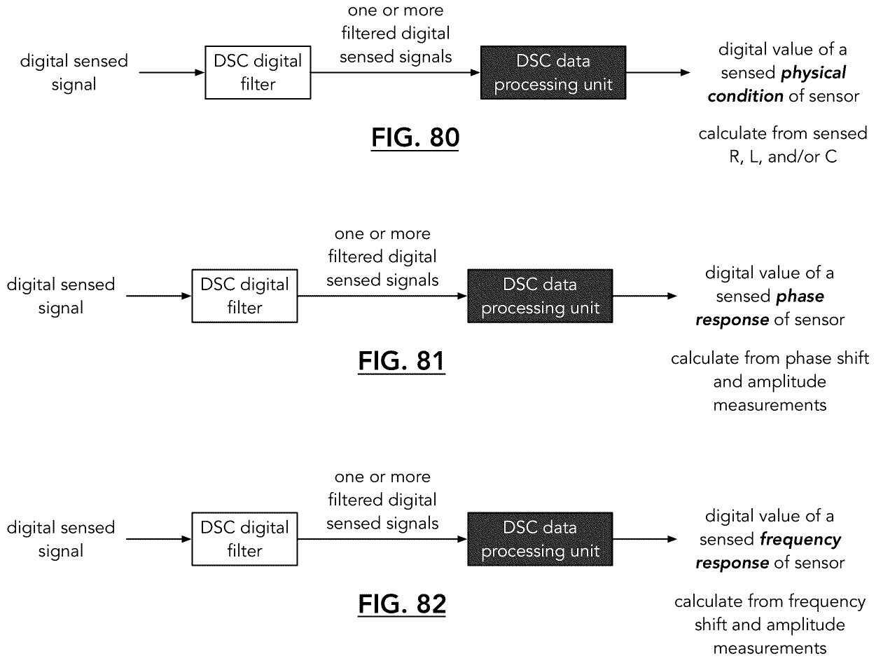

FIG. 82 is a functional diagram of another embodiment of a data processing unit of a drive sense circuit. In this embodiment, the data processing unit 226 calculates a frequency response of the sensor from the filtered digital sensed signal. For example, the data processing unit calculates a frequency shift value as previously described and then calculates a frequency response (e.g., input to output relationship over frequency).

It is noted that terminologies as may be used herein such as bit stream, stream, signal sequence, etc. (or their equivalents) have been used interchangeably to describe digital information whose content corresponds to any of a number of desired types (e.g., data, video, speech, text, graphics, audio, etc. any of which may generally be referred to as ‘data’).

As may be used herein, the terms “substantially” and “approximately” provide an industry-accepted tolerance for its corresponding term and/or relativity between items. For some industries, an industry-accepted tolerance is less than one percent and, for other industries, the industry-accepted tolerance is 10 percent or more. Other examples of industry-accepted tolerance range from less than one percent to fifty percent. Industry-accepted tolerances correspond to, but are not limited to, component values, integrated circuit process variations, temperature variations, rise and fall times, thermal noise, dimensions, signaling errors, dropped packets, temperatures, pressures, material compositions, and/or performance metrics. Within an industry, tolerance variances of accepted tolerances may be more or less than a percentage level (e.g., dimension tolerance of less than +/−1%). Some relativity between items may range from a difference of less than a percentage level to a few percent. Other relativity between items may range from a difference of a few percent to magnitude of differences.

As may also be used herein, the term(s) “configured to”, “operably coupled to”, “coupled to”, and/or “coupling” includes direct coupling between items and/or indirect coupling between items via an intervening item (e.g., an item includes, but is not limited to, a component, an element, a circuit, and/or a module) where, for an example of indirect coupling, the intervening item does not modify the information of a signal but may adjust its current level, voltage level, and/or power level. As may further be used herein, inferred coupling (i.e., where one element is coupled to another element by inference) includes direct and indirect coupling between two items in the same manner as “coupled to”.

As may even further be used herein, the term “configured to”, “operable to”, “coupled to”, or “operably coupled to” indicates that an item includes one or more of power connections, input(s), output(s), etc., to perform, when activated, one or more its corresponding functions and may further include inferred coupling to one or more other items. As may still further be used herein, the term “associated with”, includes direct and/or indirect coupling of separate items and/or one item being embedded within another item.

As may be used herein, the term “compares favorably”, indicates that a comparison between two or more items, signals, etc., provides a desired relationship. For example, when the desired relationship is that signal 1 has a greater magnitude than signal 2, a favorable comparison may be achieved when the magnitude of signal 1 is greater than that of signal 2 or when the magnitude of signal 2 is less than that of signal 1. As may be used herein, the term “compares unfavorably”, indicates that a comparison between two or more items, signals, etc., fails to provide the desired relationship.

As may be used herein, one or more claims may include, in a specific form of this generic form, the phrase “at least one of a, b, and c” or of this generic form “at least one of a, b, or c”, with more or less elements than “a”, “b”, and “c”. In either phrasing, the phrases are to be interpreted identically. In particular, “at least one of a, b, and c” is equivalent to “at least one of a, b, or c” and shall mean a, b, and/or c. As an example, it means: “a” only, “b” only, “c” only, “a” and “b”, “a” and “c”, “b” and “c”, and/or “a”, “b”, and “c”.

As may also be used herein, the terms “processing module”, “processing circuit”, “processor”, “processing circuitry”, and/or “processing unit” may be a single processing device or a plurality of processing devices. Such a processing device may be a microprocessor, micro-controller, digital signal processor, microcomputer, central processing unit, field programmable gate array, programmable logic device, state machine, logic circuitry, analog circuitry, digital circuitry, and/or any device that manipulates signals (analog and/or digital) based on hard coding of the circuitry and/or operational instructions. The processing module, module, processing circuit, processing circuitry, and/or processing unit may be, or further include, memory and/or an integrated memory element, which may be a single memory device, a plurality of memory devices, and/or embedded circuitry of another processing module, module, processing circuit, processing circuitry, and/or processing unit. Such a memory device may be a read-only memory, random access memory, volatile memory, non-volatile memory, static memory, dynamic memory, flash memory, cache memory, and/or any device that stores digital information. Note that if the processing module, module, processing circuit, processing circuitry, and/or processing unit includes more than one processing device, the processing devices may be centrally located (e.g., directly coupled together via a wired and/or wireless bus structure) or may be distributedly located (e.g., cloud computing via indirect coupling via a local area network and/or a wide area network). Further note that if the processing module, module, processing circuit, processing circuitry and/or processing unit implements one or more of its functions via a state machine, analog circuitry, digital circuitry, and/or logic circuitry, the memory and/or memory element storing the corresponding operational instructions may be embedded within, or external to, the circuitry comprising the state machine, analog circuitry, digital circuitry, and/or logic circuitry. Still further note that, the memory element may store, and the processing module, module, processing circuit, processing circuitry and/or processing unit executes, hard coded and/or operational instructions corresponding to at least some of the steps and/or functions illustrated in one or more of the Figures. Such a memory device or memory element can be included in an article of manufacture.

One or more embodiments have been described above with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

In addition, a flow diagram may include a “start” and/or “continue” indication. The “start” and “continue” indications reflect that the steps presented can optionally be incorporated in or otherwise used in conjunction with one or more other routines. In addition, a flow diagram may include an “end” and/or “continue” indication. The “end” and/or “continue” indications reflect that the steps presented can end as described and shown or optionally be incorporated in or otherwise used in conjunction with one or more other routines. In this context, “start” indicates the beginning of the first step presented and may be preceded by other activities not specifically shown. Further, the “continue” indication reflects that the steps presented may be performed multiple times and/or may be succeeded by other activities not specifically shown. Further, while a flow diagram indicates a particular ordering of steps, other orderings are likewise possible provided that the principles of causality are maintained.

The one or more embodiments are used herein to illustrate one or more aspects, one or more features, one or more concepts, and/or one or more examples. A physical embodiment of an apparatus, an article of manufacture, a machine, and/or of a process may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

While transistors may be shown in one or more of the above-described figure(s) as field effect transistors (FETs), as one of ordinary skill in the art will appreciate, the transistors may be implemented using any type of transistor structure including, but not limited to, bipolar, metal oxide semiconductor field effect transistors (MOSFET), N-well transistors, P-well transistors, enhancement mode, depletion mode, and zero voltage threshold (VT) transistors.

Unless specifically stated to the contra, signals to, from, and/or between elements in a figure of any of the figures presented herein may be analog or digital, continuous time or discrete time, and single-ended or differential. For instance, if a signal path is shown as a single-ended path, it also represents a differential signal path. Similarly, if a signal path is shown as a differential path, it also represents a single-ended signal path. While one or more particular architectures are described herein, other architectures can likewise be implemented that use one or more data buses not expressly shown, direct connectivity between elements, and/or indirect coupling between other elements as recognized by one of average skill in the art.

The term “module” is used in the description of one or more of the embodiments. A module implements one or more functions via a device such as a processor or other processing device or other hardware that may include or operate in association with a memory that stores operational instructions. A module may operate independently and/or in conjunction with software and/or firmware. As also used herein, a module may contain one or more sub-modules, each of which may be one or more modules.

As may further be used herein, a computer readable memory includes one or more memory elements. A memory element may be a separate memory device, multiple memory devices, or a set of memory locations within a memory device. Such a memory device may be a read-only memory, random access memory, volatile memory, non-volatile memory, static memory, dynamic memory, flash memory, cache memory, and/or any device that stores digital information. The memory device may be in a form a solid-state memory, a hard drive memory, cloud memory, thumb drive, server memory, computing device memory, and/or other physical medium for storing digital information.

As applicable, one or more functions associated with the methods and/or processes described herein can be implemented via a processing module that operates via the non-human “artificial” intelligence (AI) of a machine. Examples of such AI include machines that operate via anomaly detection techniques, decision trees, association rules, expert systems and other knowledge-based systems, computer vision models, artificial neural networks, convolutional neural networks, support vector machines (SVMs), Bayesian networks, genetic algorithms, feature learning, sparse dictionary learning, preference learning, deep learning and other machine learning techniques that are trained using training data via unsupervised, semi-supervised, supervised and/or reinforcement learning, and/or other AI. The human mind is not equipped to perform such AI techniques, not only due to the complexity of these techniques, but also due to the fact that artificial intelligence, by its very definition—requires “artificial” intelligence—i.e., machine/non-human intelligence.

As applicable, one or more functions associated with the methods and/or processes described herein can be implemented as a large-scale system that is operable to receive, transmit and/or process data on a large-scale. As used herein, a large-scale refers to a large number of data, such as one or more kilobytes, megabytes, gigabytes, terabytes or more of data that are received, transmitted and/or processed. Such receiving, transmitting and/or processing of data cannot practically be performed by the human mind on a large-scale within a reasonable period of time, such as within a second, a millisecond, microsecond, a real-time basis or other high speed required by the machines that generate the data, receive the data, convey the data, store the data and/or use the data.

As applicable, one or more functions associated with the methods and/or processes described herein can require data to be manipulated in different ways within overlapping time spans. The human mind is not equipped to perform such different data manipulations independently, contemporaneously, in parallel, and/or on a coordinated basis within a reasonable period of time, such as within a second, a millisecond, microsecond, a real-time basis or other high speed required by the machines that generate the data, receive the data, convey the data, store the data and/or use the data.

As applicable, one or more functions associated with the methods and/or processes described herein can be implemented in a system that is operable to electronically receive digital data via a wired or wireless communication network and/or to electronically transmit digital data via a wired or wireless communication network. Such receiving and transmitting cannot practically be performed by the human mind because the human mind is not equipped to electronically transmit or receive digital data, let alone to transmit and receive digital data via a wired or wireless communication network.

As applicable, one or more functions associated with the methods and/or processes described herein can be implemented in a system that is operable to electronically store digital data in a memory device. Such storage cannot practically be performed by the human mind because the human mind is not equipped to electronically store digital data.

While particular combinations of various functions and features of the one or more embodiments have been expressly described herein, other combinations of these features and functions are likewise possible. The present disclosure is not limited by the particular examples disclosed herein and expressly incorporates these other combinations.

What is claimed is:

1. A drive sense circuit (DSC) comprises:
an analog front end (AFE) circuit that includes:
a signal source circuit that, when enabled and coupled to a sensor, provides an analog drive signal to the sensor, wherein, the sensor affects an electrical property of the analog drive signal, and wherein the analog drive signal includes at least one of: a DC (direct current) component and an oscillating component; and
a comparison circuit operably coupled to:
compare the analog drive signal as effected by the sensor to a reference signal; and
produce an analog sensed signal that represents the effected electrical property of the analog drive signal;
a filter circuit operably coupled to filter the analog sensed signal to produce a filtered sensed signal; and
a data processing circuit operably coupled to generate a digital value representative of sensed characteristic of the sensor based on the filtered sensed signal.

2. The drive sense circuit of claim 1, wherein the electrical property of the analog drive signal comprises one of:
AC magnitude of current;
DC magnitude of current;
AC magnitude of voltage;
DC magnitude of voltage;
phase; and
frequency.

3. The drive sense circuit of claim 1, wherein the sensed characteristic comprises one of:
inductance;
capacitance;
resistance;
reactance;
detected light;
phase response;
frequency response;
impedance;
an environmental condition; and
pressure.

4. The drive sense circuit of claim 3, wherein the environmental condition comprises one of:
temperature;
moisture;
humidity; and
altitude.

5. The drive sense circuit of claim 1, wherein the reference signal comprises one of:
an oscillating voltage reference signal;
an oscillating current reference signal; and
an oscillating impedance reference signal.

6. The drive sense circuit of claim 1, wherein the signal source circuit comprises one of:
a dependent current source that generates the analog drive signal as an analog current drive signal based on the oscillating voltage reference signal;
a second dependent current source that generates the analog drive signal as the analog current drive signal based on the oscillating impedance reference signal;
a dependent voltage source that generates the analog drive signal as an analog voltage drive signal based on the oscillating current reference signal;
a second dependent voltage source that generates the analog drive signal as the analog voltage drive signal based on the oscillating impedance reference signal;
a dependent impedance source that generates the analog drive signal as an analog impedance drive signal based on the oscillating voltage reference signal; and
a second dependent impedance source that generates the analog drive signal as the analog impedance drive signal based on the oscillating current reference signal.

7. The drive sense circuit of claim 1, wherein the comparison circuit comprises one or more of:
a comparator;
a unity-gain amplifier;
an operation amplifier;
a trans-impedance operational amplifier;
a trans-impedance unity gain amplifier;
a phase shift comparator;
a frequency shift comparator; and
a magnitude comparator.

8. The drive sense circuit of claim 1 further comprises:
an analog to digital converter operably coupled to convert the analog sensed signal into a digital sensed signal.

9. The drive sense circuit of claim 1, wherein the oscillating component of the analog drive signal comprises one of:
a sinusoidal signal;
a square wave signal;
a triangular wave signal;
a multiple level signal; and
a polygonal signal.

10. The drive sense circuit of claim 1, wherein the signal source circuit is further operable to perform one or more of:
varying frequency of the oscillating component of the analog drive signal;
varying magnitude of the oscillating component of the analog drive signal; and
varying magnitude of the DC component of the analog drive signal.

11. An analog front end (AFE) circuit comprises:
a signal source circuit that, when enabled and coupled to a sensor, provides an analog drive signal to the sensor, wherein, the sensor affects an electrical characteristic of the analog drive signal, and wherein the analog drive signal includes at least one of: a DC (direct current) component and an oscillating component; and
a comparison circuit operably coupled to:
compare the analog drive signal as effected by the sensor to a reference signal; and
produce an analog sensed signal that represents the effected electrical characteristic of the analog drive signal.

12. The analog front end circuit of claim 11, wherein the reference signal comprises one of:
an oscillating voltage reference signal;
an oscillating current reference signal; and
an oscillating impedance reference signal.

13. The analog front end circuit of claim 11, wherein the signal source circuit comprises one of:
a dependent current source that generates the analog drive signal as an analog current drive signal based on the oscillating voltage reference signal;
a second dependent current source that generates the analog drive signal as the analog current drive signal based on the oscillating impedance reference signal;
a dependent voltage source that generates the analog drive signal as an analog voltage drive signal based on the oscillating current reference signal;
a second dependent voltage source that generates the analog drive signal as the analog voltage drive signal based on the oscillating impedance reference signal;
a dependent impedance source that generates the analog drive signal as an analog impedance drive signal based on the oscillating voltage reference signal; and
a second dependent impedance source that generates the analog drive signal as the analog impedance drive signal based on the oscillating current reference signal.

14. The analog front end circuit of claim 11, wherein the comparison circuit comprises one or more of:
a comparator;
a unity-gain amplifier;
an operation amplifier;
a trans-impedance operational amplifier;
a trans-impedance unity gain amplifier;
a phase shift comparator;
a frequency shift comparator; and
a magnitude comparator.

15. The analog front end circuit of claim 11, wherein the electrical property of the analog drive signal comprises one of:
AC magnitude of current;
DC magnitude of current;
AC magnitude of voltage;
DC magnitude of voltage;
phase; and
frequency.

16. The analog front end of claim 11, wherein the oscillating component of the analog drive signal comprises one of:
a sinusoidal signal;
a square wave signal;
a triangular wave signal;
a multiple level signal; and
a polygonal signal.

17. The analog front end of claim 11, wherein signal source circuit is further operable to perform one or more of:
varying frequency of the oscillating component of the analog drive signal;
varying magnitude of the oscillating component of the analog drive signal; and
varying magnitude of the DC component of the analog drive signal.
